(19) United States
(12) Patent Application Publication
(10) Pub. No.: US 2016/0340792 A1
(43) Pub. Date: Nov. 24, 2016

(54) PROCESS FOR MAKING AN IRIDIUM LAYER

(71) Applicants: SANG HYUN AHN, GAITHERSBRUG, MD (US); NATIONAL INSTITUTE OF STANDARDS AND TECHNOLOGY, GAITHERSBURG, MD (US)

(72) Inventors: THOMAS P. MOFFAT, GAITHERSBURG, MD (US); YIHUA LIU, DARIEN, IL (US); SANG HYUN AHN, SEOUL (KR)

(21) Appl. No.: 15/146,888

(22) Filed: May 4, 2016

Related U.S. Application Data
(60) Provisional application No. 62/165,360, filed on May 22, 2015.

(51) Int. Cl. C25D 21/12; C25D 3/50; C25D 5/10; H01L 21/288

(52) U.S. Cl. CPC C25D 21/12; H01L 21/2885; C25D 3/50; C25D 5/10

(57) ABSTRACT

A process for depositing a plurality of layers of iridium on a substrate includes: contacting the substrate with an electrolyte composition including: iridium cations protons; biasing the substrate at a first potential; forming iridium on the substrate at the first potential of the substrate; disposing hydrogen on the substrate; self-terminating the forming of iridium on the substrate in response to increasing a coverage of hydrogen on the substrate; oxidizing hydrogen on the substrate by changing a potential of the substrate from the first potential to a second potential; and changing the potential of the substrate from the second potential to a third potential for forming additional iridium on the substrate to deposit a plurality of layers of iridium on the substrate, such that forming the additional iridium on the substrate occurs at the third potential in response to oxidizing the hydrogen on the substrate at the second potential.

### CROSS REFERENCE TO RELATED APPLICATIONS

This application claims the benefit of U.S. Provisional Patent Application Ser. No. 62/165,360, filed May 22, 2015, the disclosure of which is incorporated herein by reference in its entirety.

### STATEMENT REGARDING FEDERALLY SPONSORED RESEARCH

This invention was made with United States Government support from the National Institute of Standards and Technology. The Government has certain rights in the invention.

### BRIEF DESCRIPTION

Disclosed is a process for depositing a plurality of layers of iridium on a substrate, the process comprising: contacting the substrate with an electrolyte composition comprising: a plurality of iridium cations; and a plurality of protons; biasing the substrate at a first potential; forming iridium on the substrate by electrochemically reducing iridium cations from the electrolyte composition at the first potential of the substrate; disposing hydrogen on the substrate from protons in the electrolyte composition; increasing a coverage of hydrogen on the substrate; self-terminating the forming of iridium on the substrate in response to increasing the coverage of hydrogen on the substrate; oxidizing hydrogen on the substrate by changing a potential of the substrate from the first potential to a second potential; and changing the potential of the substrate from the second potential to a third potential for forming additional iridium on the substrate by electrochemically reducing iridium cations from the electrolyte composition to deposit a plurality of layers of iridium on the substrate, such that forming the additional iridium on the substrate occurs at the third potential in response to oxidizing the hydrogen on the substrate at the second potential.

Further disclosed is a process for performing an electrochemical reaction, the process comprising: providing an electrode that comprises a substrate and a plurality of layers of iridium disposed on the substrate and deposited thereon according to the process of the previous paragraph; contacting the electrode with a second electrolyte composition comprising an electrochemically active reagent; and biasing the electrode at a potential effective to catalyze: an oxygen evolution reaction, wherein the second electrolyte composition is an acid environment; a hydrogen evolution reaction, wherein the second electrolyte composition is an alkaline environment or an acid environment; a hydrogen oxidation reaction wherein the second electrolyte composition is an alkaline environment or acid environment; or an organic fuel oxidation reaction wherein the second electrolyte composition is an acid or alkaline environment, to perform the electrochemical reaction.

### BRIEF DESCRIPTION OF THE DRAWINGS

The following descriptions should not be considered limiting in any way. With reference to the accompanying drawings, like elements are numbered alike.

FIG. 1 shows an article that includes iridium disposed on a substrate;

FIG. 2 shows an article that includes iridium disposed on a substrate;

FIG. 3 shows an article that includes iridium disposed on a substrate;

FIG. 4 shows an article that includes iridium disposed on a substrate;

FIG. 5 shows a flow chart that includes a process for depositing a plurality of layers of iridium on a substrate;

FIG. 6 shows an electrolyte composition disposed on a substrate to form a catalytic article;

FIG. 7 shows an electrolyte composition disposed on a substrate to form a catalytic article;

FIG. 8 shows an electrolyte composition disposed on a substrate to form a catalytic article;

FIG. 9 shows an electrolyte composition disposed on a substrate to form a catalytic article;

FIG. 10 shows an electrolyte composition disposed on a substrate to form a catalytic article;

FIG. 11 shows an electrolyte composition disposed on a substrate to form a catalytic article;

FIG. 12 shows an electrolyte composition disposed on a substrate to form a catalytic article;

FIG. 13 shows an electrolyte composition disposed on a substrate to form a catalytic article;

FIG. 14 shows an electrolyte composition disposed on a substrate to form a catalytic article;

FIG. 15 shows an electrolyte composition disposed on a substrate to form a catalytic article;

FIG. 16 shows a catalytic article;

FIG. 17 shows a waveform to bias a substrate for depositing iridium on a substrate;

FIG. 18 shows a waveform to bias a substrate for depositing iridium on a substrate;

FIG. 19 shows a waveform to bias a substrate for depositing iridium on a substrate;

FIG. 20 shows a waveform to bias a substrate for depositing iridium on a substrate;

FIG. 21 shows a waveform to bias a substrate for depositing iridium on a substrate;

FIG. 22 shows a waveform to bias a substrate for depositing iridium on a substrate;

FIG. 23 shows a waveform to bias a substrate for depositing iridium on a substrate;

FIG. 24 shows a waveform to bias a substrate for depositing iridium on a substrate;

FIG. 25 shows a waveform to bias a substrate for depositing iridium on a substrate;

FIG. 26 shows a waveform to bias a substrate for depositing iridium on a substrate;

FIG. 27 shows a waveform to bias a substrate for depositing iridium on a substrate;

FIG. 28 shows a waveform to bias a substrate for depositing iridium on a substrate;

FIG. 29 shows a waveform to bias a substrate for depositing iridium on a substrate;

FIG. 30 shows a graph of current density versus potential; of thermally activated Ir deposition followed by self-termination at more negative potentials.

FIG. 31 shows a graph of current density versus potential, wherein the peak current corresponds to Ir deposition that is quenched at the onset of hydrogen evolution;

FIG. 32 shows a graph of current density versus potential, wherein the potential for Ir deposition and its quenching depends on pH;

FIG. 33 shows a graph of current density versus potential, wherein the Ir deposition characteristics are also dependent on hydrodynamics;

FIG. 34 shows a graph of absorbance versus pH, wherein the shift of the UV-VIS peaks occurred due to aquation of the IrCl₆³⁻ precursor complex;

FIG. 35 shows a graph of current density versus potential, which corresponds to the UV-VIS spectra shown in FIG. 34 that shows that aquo-chloro speciation does not control deposition process;

FIG. 36 shows a graph of current density versus potential in which self-terminated Ir electrodeposition occurred on Au rotating disc electrode (RDE) in x mmol/L K₃IrCl6—0.5 mol/L Na₂SO₄—x mol/L H₂SO₄ electrolyte, and data show that voltammetric Ir deposition was quenched at the onset of hydrogen evolution in pH 6.5 electrolyte, and H_{UPD} on an Ir electrode is shown in the inset graph;

FIG. 37 shows a graph of current density versus potential in which self-terminated Ir electrodeposition occurred on Au RDE in x mmol/L K₃IrCl6—0.5 mol/L Na₂SO₄—x mol/L H₂SO₄ electrolyte, and data show that Ir nucleation, i.e. the onset potential for metal deposition, depended on scan rate;

FIG. 38 shows a graph of current density versus potential in which self-terminated Ir electrodeposition occurred on Au RDE in x mmol/L K₃IrCl6—0.5 mol/L Na₂SO₄—x mol/L H₂SO₄ electrolyte, and data show peak deposition current saturated for RDE rotation rates above 1600 rpm in the pH 4.0 electrolyte;

FIG. 39 shows a graph of current density versus potential in which self-terminated Ir electrodeposition occurred on Au RDE in x mmol/L K₃IrCl6—0.5 mol/L Na₂SO₄—x mol/L H₂SO₄ electrolyte, and data show that reactivation of Ir deposition process occurred during the positive voltammetric sweep (bold); the negative going sweep is shown in the background;

FIG. 40 shows a graph of current density versus time in which data were acquired for current transients during Ir deposition on Au RDE in 3 mmol/L K₃IrCl₆—0.5 mol/L Na₂SO₄—x mol/L H₂SO₄ pH 4.0 electrolyte, wherein chronoamperometry was for deposition potentials from 0 V_{SSE} to −0.75 V_{SSE};

FIG. 41 shows a graph of current density versus in which data were acquired for current transients during Ir deposition on Au RDE in 3 mmol/L K₃IrCl₆—0.5 mol/L Na₂SO₄—x mol/L H₂SO₄ pH 4.0 electrolyte, wherein chronoamperometry was for deposition potentials from −0.75 V_{SSE} to −0.85 V_{SSE};

FIG. 42 shows a graph of current density versus in which data were acquired for current transients during Ir deposition on Au RDE in 3 mmol/L K₃IrCl₆—0.5 mol/L Na₂SO₄—x mol/L H₂SO₄ pH 4.0 electrolyte, wherein chronoamperometry was for deposition potentials from −0.85 V_{SSE} to −1.25 V_{SSE};

FIG. 43 shows a graph of current density versus potential in which data were acquired for sampled current (300 s) voltammetry (scatter) compared to cyclic voltammetry (black line) for Ir deposition;

FIG. 44 shows a graph of current density versus time in which data were acquired for current transients during Ir deposition on Au RDE in 3 mmol/L K₃IrCl₆—0.5 mol/L Na₂SO₄—x mol/L H₂SO₄ pH 6.5 electrolyte, wherein chronoamperometry was for deposition potentials from 0 V_{SSE} to −0.85 V_{SSE};

FIG. 45 shows a graph of current density versus in which data were acquired for current transients during Ir deposition on Au RDE in 3 mmol/L K₃IrCl₆—0.5 mol/L Na₂SO₄—x mol/L H₂SO₄ pH 6.5 electrolyte, wherein chronoamperometry was for deposition potentials from −0.85 V_{SSE} to −0.95 V_{SSE};

FIG. 46 shows a graph of current density versus in which data were acquired for current transients during Ir deposition on Au RDE in 3 mmol/L K₃IrCl₆—0.5 mol/L Na₂SO₄—x mol/L H₂SO₄ pH 6.5 electrolyte, wherein chronoamperometry was for deposition potentials from −0.95 V_{SSE} to −1.25 V_{SSE};

FIG. 47 shows a graph of current density versus potential in which data were acquired for sampled current (300 s) voltammetry (scatter) compared to cyclic voltammetry (black line) for Ir deposition;

FIG. 48 shows a graph of current density versus potential for evolution of IrCl₆-xH₂Oₓ voltammetry in 1 mmol/L K₃IrCl₆—0.5 mol/L Na₂SO₄—x mol/L H₂SO₄ electrolyte at room temperature in which data were acquired for cyclic voltammetry of the Ir³⁺/Ir⁴⁺ redox reaction on a glassy carbon electrode at pH 4.0, t=0 h;

FIG. 49 shows a graph of current density versus potential for evolution of IrCl₆-xH₂Oₓ voltammetry in 1 mmol/L K₃IrCl₆—0.5 mol/L Na₂SO₄—x mol/L H₂SO₄ electrolyte at room temperature in which data were acquired for cyclic voltammetry of Ir³⁺/Ir⁴⁺ redox reaction on glassy carbon electrode at pH 3.0 from 1 h to 25 h;

FIG. 50 shows a graph of potential versus pH for various redox reactions;

FIG. 51 shows photographs of a plurality of 3 mmol/L K₃IrCl₆—0.5 mol/L Na₂SO₄—x mol/L H₂SO₄ electrolyte compositions for evolution of Ir³⁺ solutions as a function of pH, dissolved gases, temperature, and time;

FIG. 52 shows photographs of a plurality of 3 mmol/L K₂IrCl₆—0.5 mol/L Na₂SO₄—x mol/L H₂SO₄ electrolyte compositions for evolution of Ir⁴⁺ solutions as a function of pH, dissolved gases, temperature, and time;

FIG. 53 shows a graph of absorbance versus wavelength for evolution of Ir³⁺ solutions at pH 6.5, dissolved gases, temperature, and time, wherein data was acquired for room temperature UV-vis spectra of aged solutions (3 days) for 3 mmol/L K₃IrCl₆—0.5 mol/L Na₂SO₄—x mol/L H₂SO₄ electrolyte;

FIG. 54 shows a graph of absorbance versus wavelength for evolution of Ir⁴⁺ solutions at pH 6.5, dissolved gases, temperature, and time, wherein data was acquired for room temperature UV-vis spectra of aged solutions (3 days) for 3 mmol/L K₂IrCl₆—0.5 mol/L Na₂SO₄—x mol/L H₂SO₄ electrolyte;

FIG. 55 shows a graph of absorbance versus wavelength for evolution of Ir³⁺ solutions at pH 4.0, dissolved gases, temperature, and time, wherein data was acquired for room temperature UV-vis spectra of aged solutions (3 days) for 3 mmol/L K₃IrCl₆—0.5 mol/L Na₂SO₄—x mol/L H₂SO₄ electrolyte;

FIG. 56 shows a graph of absorbance versus wavelength for evolution of Ir⁴⁺ solutions at pH 4.0, dissolved gases, temperature, and time, wherein data was acquired for room temperature UV-vis spectra of aged solutions (3 days) for 3 mmol/L K₂IrCl₆—0.5 mol/L Na₂SO₄—x mol/L H₂SO₄ electrolyte;

FIG. 57 shows a graph of absorbance versus wavelength for evolution of Ir³⁺ solutions at pH 1.5, dissolved gases, temperature, and time, wherein data was acquired for room temperature UV-vis spectra of aged solutions (3 days) for 3 mmol/L K₃IrCl₆—0.5 mol/L Na₂SO₄—x mol/L H₂SO₄ electrolyte;

FIG. 58 shows a graph of absorbance versus wavelength for evolution of Ir⁴⁺ solutions at pH 1.5, dissolved gases, temperature, and time, wherein data was acquired for room temperature UV-vis spectra of aged solutions (3 days) for 3 mmol/L K₂IrCl₆—0.5 mol/L Na₂SO₄—x mol/L H₂SO₄ electrolyte;

FIG. 59 shows a graph of absorbance versus wavelength for comparison of UV-vis spectra after aging of Ir³⁺ and Ir⁴⁺ solutions in which in freshly prepared pH 1.5 solution of IrCl₆³⁻ residual dissolved oxygen formed some Ir⁴⁺ species, wherein after extended aging the Ir⁴⁺ species were reduced such that the solution included mostly of [IrCl₅(H2O)]²⁻;

FIG. 60 shows a graph of absorbance versus wavelength for comparison of UV-vis spectra after aging of Ir³⁺ solutions in which extended aging at 70° C. resulted in conversion IrCl₆³⁻ to IrCl₅(H2O)²⁻;

FIG. 61 shows a graph of current density versus potential for self-terminated Ir electrodeposition on Au RDE in 1 mmol/L K₂IrCl₆—0.5 mol/L Na₂SO₄—x mol/L H₂SO₄ pH 6.5 electrolyte, wherein Ir deposition decreased monotonically with time while an increase in a diffusion limited proton reduction reaction occurred due to hydrolysis of the Ir⁴⁺ species;

FIG. 62 shows a graph of current density versus potential in which data was acquired that showed an effect of anions on Ir electrodeposition on Au RDE in 3 mmol/L K₃IrCl₆ pH 6.5 electrolyte;

FIG. 63 shows a graph of absorbance versus wavelength for thermal activation of Ir electrodeposition on Au RDE in x mmol/L K₃IrCl₆—0.5 mol/L Na₂SO₄—x mol/L H₂SO₄ electrolyte in which data was acquired for thermal cycling the electrolyte at 20° C., 70° C., and 20° C.;

FIG. 64 shows a graph of current density versus potential for thermal activation of Ir electrodeposition on Au RDE in x mmol/L K₃IrCl₆—0.5 mol/L Na₂SO₄—x mol/L H₂SO₄ electrolyte;

FIG. 65 shows a graph of current density versus potential for thermal activation of Ir electrodeposition on Au RDE in x mmol/L K₃IrCl₆—0.5 mol/L Na₂SO₄—x mol/L H₂SO₄ electrolyte in which data was acquired for the positive-going voltammetric scan;

FIG. 66 shows a graph of activation energy for Ir electrodeposition as a function of potential. The inset shows an Arrhenius plot for thermal activation of Ir electrodeposition on Au RDE in x mmol/L K₃IrCl₆—0.5 mol/L Na₂SO₄—x mol/L H₂SO₄ electrolyte;

FIG. 67 shows a field emission scanning electron microscopy (FESEM) image of the Au substrate used for bulk Ir deposition;

FIG. 68 shows a FESEM micrograph of an iridium film disposed on a Au substrate by deposition at −0.75 V_{SSE} for 500 s in 3 mmol/L K₃IrCl₆—0.5 mol/L Na₂SO₄—x mol/L H₂SO₄ pH 6.5 electrolyte;

FIG. 69 shows an X-ray diffractogram, X-ray intensity versus scattering angle (two theta), of the bulk Ir deposit grown on Au-seeded wafer at −0.75 V_{SSE} for 500 s in 3 mmol/L K₃IrCl₆—0.5 mol/L Na₂SO₄—x mol/L H₂SO₄ pH 6.5 electrolyte;

FIG. 70 shows an X-ray photoelectron spectroscopy (XPS) intensity versus binding energy spectrum, for a bulk Ir deposit grown at −0.75 V_{SSE} for 500 s on Au-seeded wafer in 3 mmol/L K₃IrCl₆—0.5 mol/L Na₂SO₄—x mol/L H₂SO₄ pH 6.5 electrolyte;

FIG. 71 shows a graph of iridium overlayer thickness versus deposition time at the stated potentials, and the iridium overlayer thickness as a function of the number pulsed deposition cycles;

FIG. 72 shows a graph of XPS intensity for Au 4f and Ir 4f versus the number of deposition cycles;

FIG. 73 shows a graph of current density versus potential where the voltammetric peaks corresponded to H adsorption and desorption.

FIG. 74 shows a graph of Ir overlayer thickness versus deposition time for films grown on Au-seeded Si wafer in x mmol/L K₃IrCl₆—0.5 mol/L Na₂SO₄—x mol/L H₂SO₄ electrolyte at 70° C. The data points are averaged from at least 3 different regions of individual specimens and the error bars represent the standard deviation of the measurements;

FIG. 75 shows a graph of iridium overlayer thickness versus deposition potential for Ir on Au-seeded Si wafer deposited by a single-pulse at the specified potential in x mmol/L K₃IrCl₆—0.5 mol/L Na₂SO₄—x mol/L H₂SO₄ electrolyte at 70° C. The XPS-derived Ir overlayer thickness was dependent on deposition potential, and data points are averaged from at least 3 different regions of individual specimens and the error bars represent the standard deviation of the measurements;

FIG. 76 shows a graph of iridium overlayer thickness versus versus K₃IrCl₆ concentration for Ir on Au-seeded Si wafer deposited by multi-pulse deposition in x mmol/L K₃IrCl₆—0.5 mol/L Na₂SO₄—x mol/L H₂SO₄ electrolyte at 70° C., wherein XPS-derived Ir overlayer thickness was dependent on (c) K₃IrCl₆ concentration, and data points are averaged from at least 3 different regions of individual specimens and the error bars represent the standard deviation of the measurements;

FIG. 77 shows a graph of XPS spectra, intensity versus binding energy, for iridium grown on nickel covered gold-seeded Si wafer by pulse deposition in x mmol/L K₃IrCl₆—0.5 mol/L Na₂SO₄—x mol/L H₂SO₄ electrolyte at 70° C., wherein after one deposition pulse XPS revealed an Ir overlayer with a nominal thickness of 0.29±0.02 nm. Data were acquired for Au 4f, Ir 4f, and Ni 3p XPS spectra for Ir films grown on Au and on Ni deposited Au using 1 pulse deposition from a pH 6.5 electrolyte;

FIG. 78 shows an XPS graph of intensity versus binding energy for iridium grown on nickel covered gold-seeded Si wafer by multi-pulse deposition in x mmol/L K₃IrCl₆—0.5 mol/L Na₂SO₄—x mol/L H₂SO₄ electrolyte at 70° C., wherein peak fitting was performed to deconvolve the Ir 4f and Ni 3p peaks;

FIG. 79 shows a graph of sequential ion scattering spectroscopy (ISS) spectra for scattered He intensity, in counts per second (CPS), versus kinetic energy for iridium grown on nickel covered gold-seeded Si wafer by pulse deposition in x mmol/L K₃IrCl₆—0.5 mol/L Na₂SO₄—x mol/L H₂SO₄ electrolyte at 70° C., after 1 pulse Ir deposition;

FIG. 80 shows iridium surface coverage on nickel as determined bu ISS for a series of different spots the surface of iridium grown on nickel covered gold-seeded Si wafer by pulse deposition in x mmol/L K₃IrCl₆—0.5 mol/L Na₂SO₄—x mol/L H₂SO₄ electrolyte at 70° C., analysis of the intergated area normalized for a sensitivity factor of f_{Ni/Ir}=2 indicated an Ir surface coverage of 25%;

FIG. 81 shows a graph of current density versus time for multi-pulse iridium deposition on a static Au-seeded silicon wafer, wherein data was acquired for current transients for seven pulses of iridium electrodeposition in 3 mol/L K₃IrCl₆—0.5 mol/L Na₂SO₄—x mol/L H₂SO₄ pH 4.0 electrolyte at 70° C.;

FIG. 82 shows a graph of current density versus time for multi-pulse iridium deposition on a Au RDE rotated at 400 rpm, wherein data was acquired for current transients for seven pulses of iridium electrodeposition in 3 mol/L K₃IrCl₆—0.5 mol/L Na₂SO₄—x mol/L H₂SO₄ pH 4.0 electrolyte at 70° C.;

FIG. 83 shows a graph of current density versus potential for cyclic voltametric characterization in sulfuric acid of ultrathin iridium films grown on Au-seeded silicon wafer by multipulse deposition in 3 mmol/L K₃IrCl₆—0.5 mol/L Na₂SO₄—x mol/L H₂SO₄ pH 4.0 electrolyte at 70° C.; The number 1-7 corresponds to the number of Ir deposition pulses.

FIG. 84 shows a graph of current density versus potential for cyclic voltametric characterization in sulfuric acid of ultrathin iridium films grown on Au RDE in 3 mmol/L K₃IrCl₆—0.5 mol/L Na₂SO₄—x mol/L H₂SO₄ pH 4.0 electrolyte at 70° C.; The number 1-7 corresponds to the number of Ir deposition pulses.

FIG. 85 shows a graph of current density versus potential in sulfuric acid solution for characterizing the electroactive area of ultrathin iridium films grown on Au-seeded silicon wafer in 3 mol/L K₃IrCl₆—0.5 mol/L Na₂SO₄—x mol/L H₂SO₄ pH 4.0 electrolyte at 70° C., wherein a scheme of area calculation for H_{UPD} and Au oxide reduction in 0.5 mol/L H₂SO₄ are shown;

FIG. 86 shows hydrogen underpotential deposition (H_{UPD}) charge density versus number of iridium deposition pulses for ultrathin iridium films grown on Au-seeded silicon wafer in 3 mol/L K₃IrCl₆—0.5 mol/L Na₂SO₄—x mol/L H₂SO₄ pH 4.0 electrolyte at 70° C., wherein the data show calculated Ir coverage as determined by integration of the Hupd and Au oxide waves as a function of number of deposition pulses;

FIG. 87 shows a plurality of graphs of current density versus potential for cyclic voltammetry of multi-pulse Ir films in 0.5 mol/L H₂SO₄ for a scan rate of 10 mV/s in (a-e) potential range: 0.05 V_{RHE} to 0.70 V_{RHE} and (f-j) potential range: 0.05 V_{RHE} to 1.50 V_{RHE} for a series of Ir film. The number 1-7 corresponds to the number of Ir deposition pulses.

FIG. 88 shows a plurality of graphs of current density versus potential for Pb_{UPD} and Cu_{UPD} on Ir films grown on a Au-seeded Si wafer by multi-pulse deposition in 3 mmol/L K₃IrCl₆—0.5 mol/L Na₂SO₄—x mol/L H₂SO₄ pH 4.0 electrolyte at 70° C., wherein cyclic voltammetry data was acquired with a scan rate of 10 mV/s at room temperature (al) in 0.01 mol/L Pb(C104)₂—0.1 mol/L HClO₄ electrolyte and (g-l) 0.05 mol/L CuSO₄—0.05 mol/L H₂SO₄ electrolyte;

FIG. 89 shows a graph of charge density for Pb_{UPD} and Cu_{UPD} versus the number deposition pulses for Ir films grown on a Au-seeded Si wafer in 3 mmol/L K₃IrCl₆—0.5 mol/L Na₂SO₄—x mol/L H₂SO₄ pH 4.0 electrolyte at 70° C., wherein calculated charge density represented half of the highlighted voltammetric region shown in the immediate prior figure;

FIG. 90 shows a cross-sectional scanning transmission electron microscope (STEM) image of iridium deposited on gold using seven deposition pulses. film showing that the in-plane grain size of Au was similar to its film thickness;

FIG. 91 shows an scanning tunneling microscopy (STM) image for 111 textured Au substrate showing distribution and arrangement of steps in a height image;

FIG. 92 shows an image of a gold substrate, wherein the image of the immediate prior figure was subjected to contrast enhanced (color equalization) tunnel current error signal imaging over the same area;

FIG. 93 shows an STM image of a Au thin film substrate;

FIG. 94 shows an STM image of iridium disposed using a two pulse deposition on the Au thin film substrate;

FIG. 95 shows an high-angle annular dark-field (HAADF)-STEM image of iridium disposed on the substrate using seven deposition pulses in 3 mmol/l K₃IrCl₆—0.5 mol/L Na₂SO₄—x mol/L H₂SO₄ pH 4.0 electrolyte at 70° C.;

FIG. 96 shows an higher resolution HAADF-STEM image of iridium disposed using seven deposition pulses on the Au substrate, 110 zone axis image;

FIG. 97 shows an higher resolution HAADF-STEM image of iridium disposed using seven deposition pulses on the Au substrate, 110 zone axis image;

FIG. 98 shows an higher resolution HAADF-STEM image of iridium disposed using seven deposition pulses on the Au substrate, 110 zone axis image with an inset STEM energy dispersive spectrosocpy elemental (XEDS) map of the Ir deposit and Au substrate.

FIG. 99 shows a fast fourier transform along the [112] direction of each layer in the image of iridium disposed on the substrate shown in FIG. 98, the abrupt semicoherent interface between the Ir film and Au substrate is demonstrated;

FIG. 100 shows an HAADF-STEM image of a cross-section of an Ir film grown on Au-seeded Si wafer by 7 deposition pulses in 3 mmol/L K₃IrCl₆—0.5 mol/L Na₂SO₄—x mol/L H₂SO₄ pH 4.0 electrolyte at 70° C., wherein data was acquired for the 112 zone axis;

FIG. 101 shows a cross-sectional image of iridium on a gold substrate an HAADF-STEM image of a cross-section of an Ir film grown on Au-seeded Si wafer by 7 deposition pulses in 3 mmol/L K₃IrCl₆—0.5 mol/L Na₂SO₄—x mol/L H₂SO₄ pH 4.0 electrolyte at 70° C., wherein data was acquired for the 112 zone axis;

FIG. 102 shows an HAADF-STEM image of a cross-section of an Ir film grown on Au-seeded Si wafer by 7 deposition pulses in 3 mmol/L K₃IrCl₆—0.5 mol/L Na₂SO₄—x mol/L H₂SO₄ pH 4.0 electrolyte at 70° C., wherein data was acquired along [112];

FIG. 103 shows a resulting image of subjecting the image shown in FIG. 102 to a one-dimensional fast Fourier transform (1-d FFT) in which the resulting image shows an abrupt change in spacing between [1-10] atomic columns, reflecting semi-coherent nature of the interface;

FIG. 104 shows an HAADF-STEM image of an Ir overlayer grown on Au-seeded Si wafer by 7 deposition pulses in 3 mmol/L K₃IrCl₆—0.5 mol/L Na₂SO₄—x mol/L H₂SO₄ pH 4.0 electrolyte at 70° C., wherein the data was acquired along a 1-10 zone axis variation of the focus condition revealed the distribution of semi-coherent Ir islands on the Au(111) surface;

FIG. 105 shows an image of the same area of the image shown in FIG. 104 acquired under a different focus condition;

FIG. 106 shows an image of the same area of the image shown in FIG. 104 acquired under a focus condition different from FIG. 104 and FIG. 105;

FIG. 107 shows a graph of current density versus potential for water reduction and hydrogen oxidation on multipulse Ir films grown on Au. The number 1-10 corresponds to the number of Ir deposition pulses.

FIG. 108 shows a graph of geometric and specific activity for hydrogen oxidation (HOR) and hydrogen evolution (HER) versus iridium surface area;

FIG. 109 shows a graph of exchange current density for the HER/HOR versus number of deposition pulses for Pt and Ir on Au, Ir on Pt and Ir on a one pulse Pt film on Au;

FIG. 110 shows a graph of specific exchange current density for HER/HOR versus the electroactive platinum and iridium surface area;

FIG. 111 shows a graph of current density versus potential for self-terminated Ir electrodeposition from 3 mmol/L K₃IrCl₆—0.5 mol/L Na₂SO₄—x mol/L H2504 pH 4.0 on different substrates that included Au RDE, Pt RDE, glassy carbon (GC) RDE to a one pulse self-terminated Pt layer grown on a Au RDE;

FIG. 112 shows a graph of current density versus potential voltammograms in Ar-purged 0.5 mol/L H₂SO₄ wherein H_{UPD} and gold oxide reduction were used to determine the electrochemical active surface area of the Ir film as a function of the number of multi-pulse deposition cycles;

FIG. 113 shows a graph of current density versus potential for HER/HOR on multi-pulse deposited ultrathin Ir films on Au RDE;

FIG. 114 shows a graph of H_{UPD} charge density versus number of iridium deposition pulses for multi-pulse deposited of ultrathin Ir films on Au RDE;

FIG. 115 shows a graph of the area specific exchange current density for HER/HOR versus iridium surface area for multi-pulse deposited ultrathin Ir films on Au RDE;

FIG. 116 shows a graph of current density versus potential voltammograms in Ar-purged 0.5 mol/L H₂SO₄ wherein H_{UPD} and gold oxide reduction were used to determine the electrochemical active surface area of the multi-pulse deposited ultrathin Pt films on Au RDE;

FIG. 117 shows a graph of current density versus potential for HER/HOR on multi-pulse deposited ultrathin Pt films on Au RDE;

FIG. 118 shows a graph of H_{UPD} charge density versus number of platinum deposition pulses for growing ultrathin Ir films on Au RDE;

FIG. 119 shows a graph of the area specific exchange current density for HER/HOR versus Pt surface area for multi-pulse deposited ultrathin Pt films on Au RDE;

FIG. 120 shows a graph of current density versus potential voltammograms in Ar-purged 0.5 mol/L H₂SO₄ wherein H_{UPD} and gold oxide reduction were used to determine the electrochemical active surface area of the multi-pulse Ir deposits grown on a on Pt RDE;

FIG. 121 shows a graph of current density versus potential for HER/HOR on the multi-pulse Ir deposits grown on a Pt RDE;

FIG. 122 shows a graph of H_{UPD} charge density versus number of deposition pulses for growing ultrathin Ir films on a Pt RDE;

FIG. 123 shows a graph of the area specific exchange current density for HER/HOR versus Ir+Pt surface area for multi-pulse ultrathin Ir films deposited on a Pt RDE;

FIG. 124 shows a graph of current density versus potential voltammograms in Ar-purged 0.5 mol/L H₂SO₄ wherein H_{UPD} and gold oxide reduction were used to determine the electrochemical active surface area of multi-pulse Ir deposits grown on a one pulse Pt film on a Au RDE;

FIG. 125 shows a graph of current density versus potential for HER/HOR on the multi-pulse Ir deposits grown on a one pulse Pt film on Au RDE;

FIG. 126 shows a graph of H_{UPD} charge density versus number of deposition pulses for ultrathin Ir films on a one pulse Pt film on Au RDE;

FIG. 127 shows a graph of area specific exchange current density versus Ir+Pt surface area for multi-pulse Ir deposition on a one pulse Pt film on Au RDE;

FIG. 128 shows a graph of current density based on geometric area for HER at −0.05 V_{RHE} in alkaline media as a function of the number of Ir or Pt deposition pulses on different substrates;

FIG. 129 shows a graph of specific current density, H_{UPD} normalized, at −0.05 V_{RHE} as a function of the H_{UPD} normalized area for various self-terminated Ir or Pt layers grown on various substrates;

FIG. 130 shows a graph of current density versus potential of the OER and ORR on ultrathin Ir films, the number 1-10 corresponds to the number of Ir deposition pulses;

FIG. 131 shows a graph of overpotential for OER at 5 mA/cm² versus number of iridium deposition pulses;

FIG. 132 shows a graph of specific OER activity at an overpotential of 0.25 V and 0.35 V versus iridium electroactive surface area;

FIG. 133 shows a graph of current density versus potential for the bifunctional OER/ORR on different ultrathin Pt and Ir films.

FIG. 134 shows a graph of current density versus iR-corrected potential for bifunctional ORR/OER on various ultrathin Ir films grown by pulsed deposition on Au RDE.

### DETAILED DESCRIPTION

A detailed description of one or more embodiments is presented herein by way of exemplification and not limitation.

It has been discovered that a process herein provides deposition of iridium on a substrate. The iridium is deposited in layers, and deposition of each iridium layer is self-terminated by accumulation of hydrogen on the substrate. Further deposition of iridium on the substrate occurs by oxidizing hydrogen on the substrate and subjecting the substrate to a potential effective to reduce iridium cations to iridium on the substrate. In this manner, a thickness or number of layers of iridium on the substrate are selectively controllable. Advantageously, a catalytic article is produced by such deposition of iridium on the substrate.

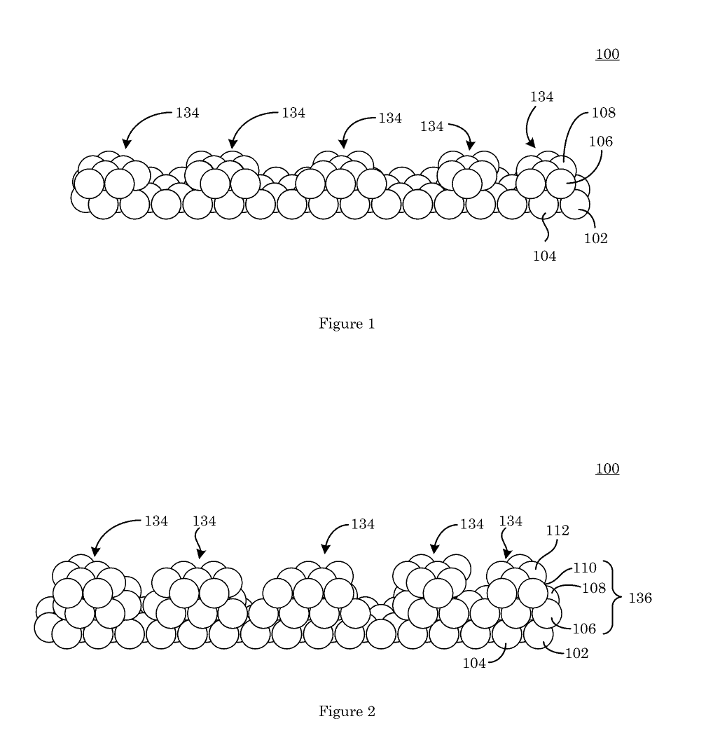

In an embodiment, as shown in FIG. 1, catalytic article 100 includes substrate 102 and first layer 106 of iridium atoms 108 disposed on substrate 102. Substrate 102 includes a plurality of substrate atoms 104 arranged in a selected lattice pattern. The lattice pattern can be ordered (e.g., crystalline, semi-crystalline, and the like) or disordered (e.g., amorphous), or a combination thereof. According to an embodiment, substrate 102 includes the lattice pattern that is ordered in a crystalline arrangement such as a single crystal.

First iridium layer 106 can be arranged in a plurality of discreet islands 134 that include a plurality of iridium atoms 108. Here, it should be appreciated that iridium atoms 108 have a neutral charge. An arrangement of first iridium layer 106 into discreet islands 134 is a result of deposition of iridium atoms 108 in a process (described below) that includes self-terminating deposition of iridium electrochemically from iridium cations in a presence of hydrogen adsorbed on substrate 102. According to an embodiment, some discreet islands 134 can be joined by iridium atoms 108 in first iridium layer 106 to link together some of discreet islands 134 via iridium islands. In some embodiments, discreet islands 134 are isolated from other discreet islands 132 in first iridium layer 106 due an absence of iridium atoms 108 that link discreet islands 134.

With reference to FIG. 2, in an embodiment, catalytic article 100 includes substrate 102 and a plurality of iridium layers (first iridium layer 106, second iridium layer 110) of iridium disposed on substrate 102. The plurality of iridium layers (106, 110) are arranged as thin film 136 disposed on substrate 102. First iridium layer 106 includes the plurality of iridium atoms 108 disposed in contact with substrate 102, and second iridium layer 110 includes a plurality of iridium atoms 112 disposed on first iridium layer 106. Here, second iridium layer 110 includes a plurality of discreet islands 134. Again, it should be appreciated that iridium atoms 108, 112 have a neutral charge and deposited by a process that includes self-terminating deposition of iridium electrochemically from iridium cations in a presence of hydrogen adsorbed on substrate 102.

A number of layers of iridium disposed on substrate 102 in catalytic article 100 is selectively controlled by a process that includes self-terminating deposition of iridium electrochemically from iridium cations in a presence of hydrogen adsorbed on substrate 102. It is contemplated that the number of layers of iridium disposed on substrate 102 in catalytic article 100 is selected by terminating deposition of iridium as subsequent iridium layers on substrate 102 in a number of ways as described below. As a consequence, the number of layers of iridium disposed on substrate 102 can be any number (e.g., 1, 2, 3, . . . , n, wherein n is an integer greater than 0) to provide thin film 134 of iridium on substrate 102.

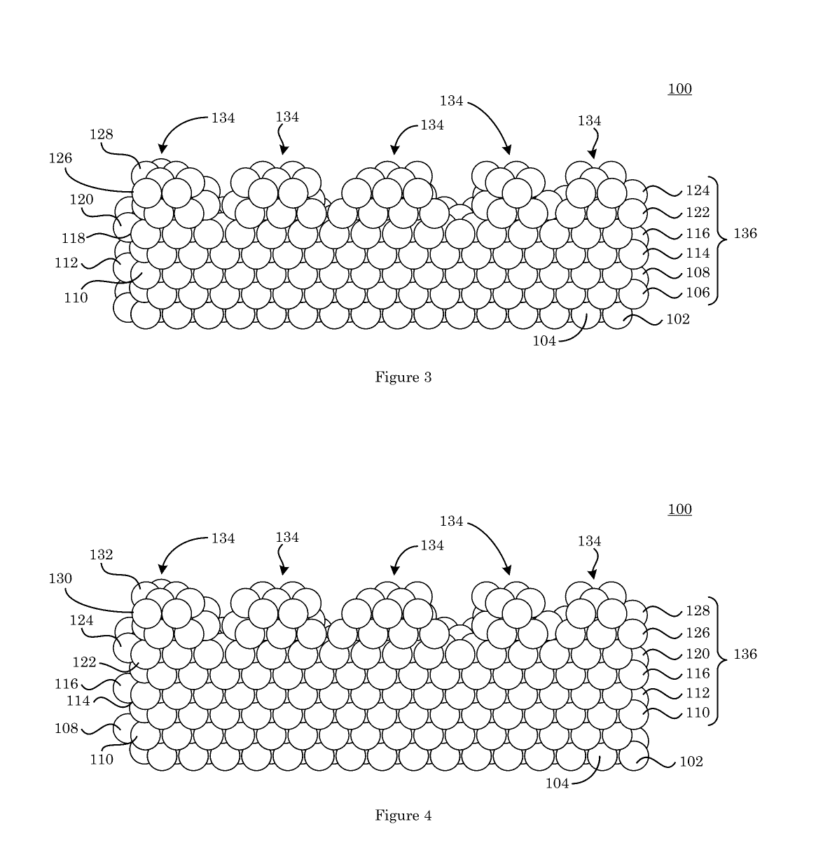

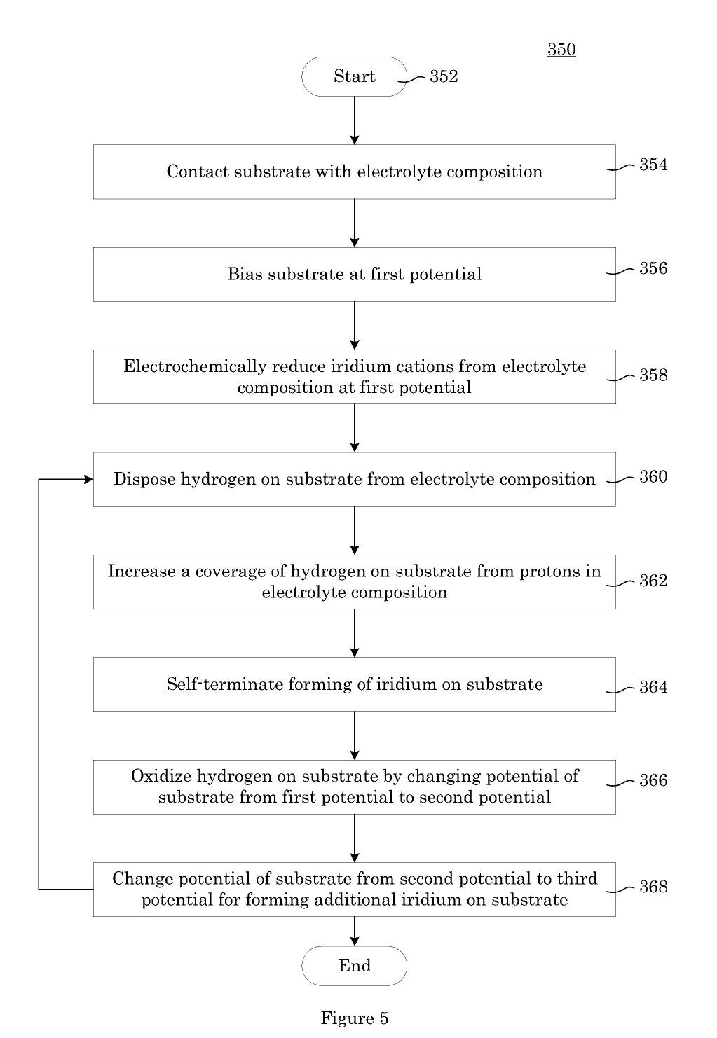

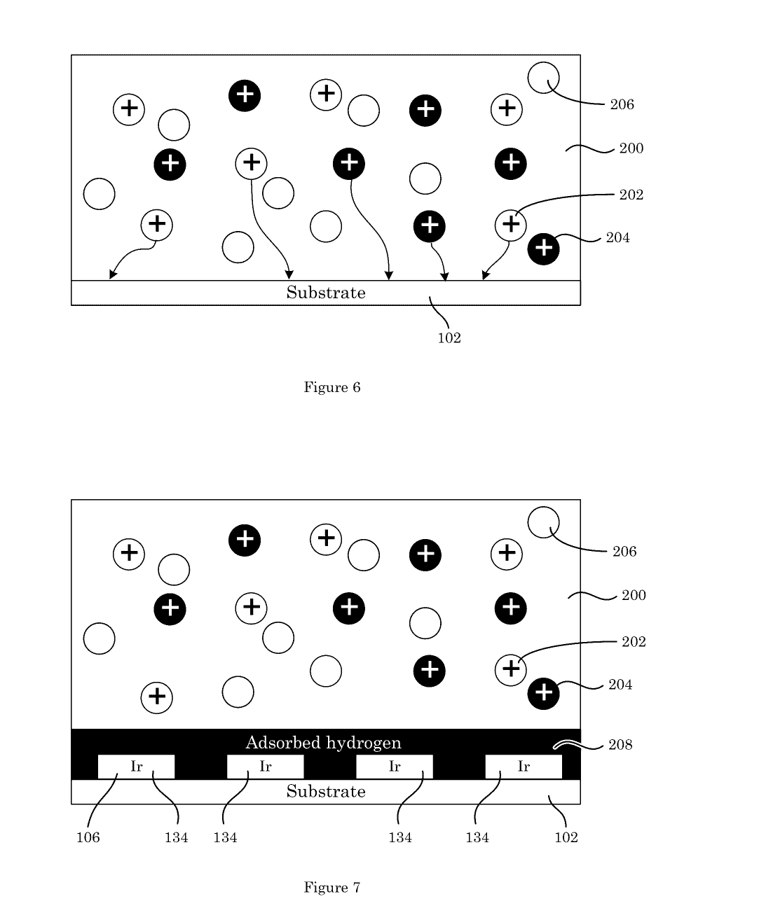

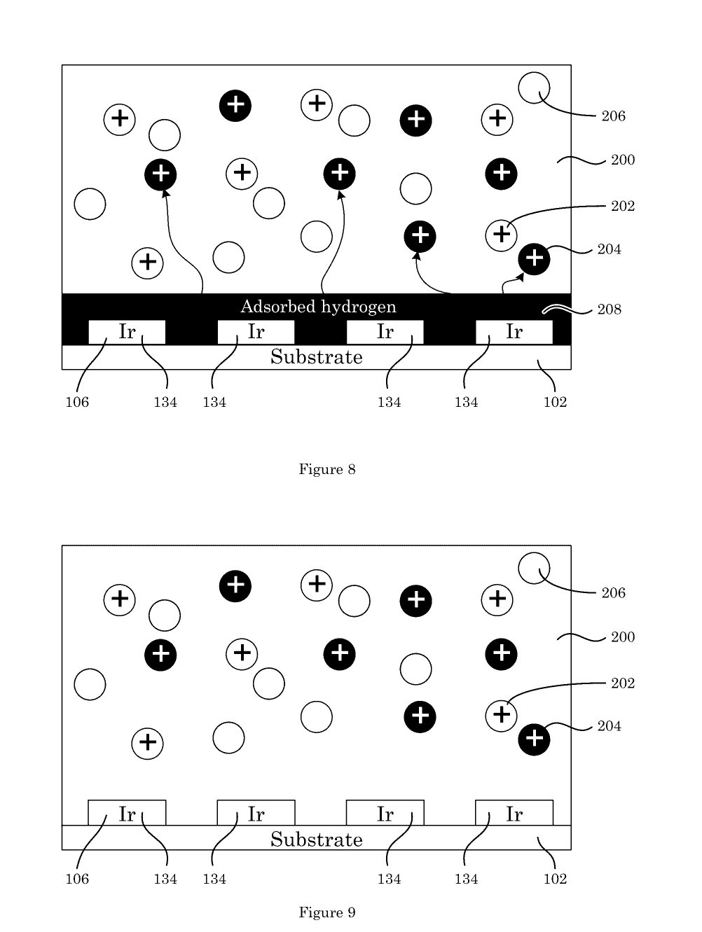

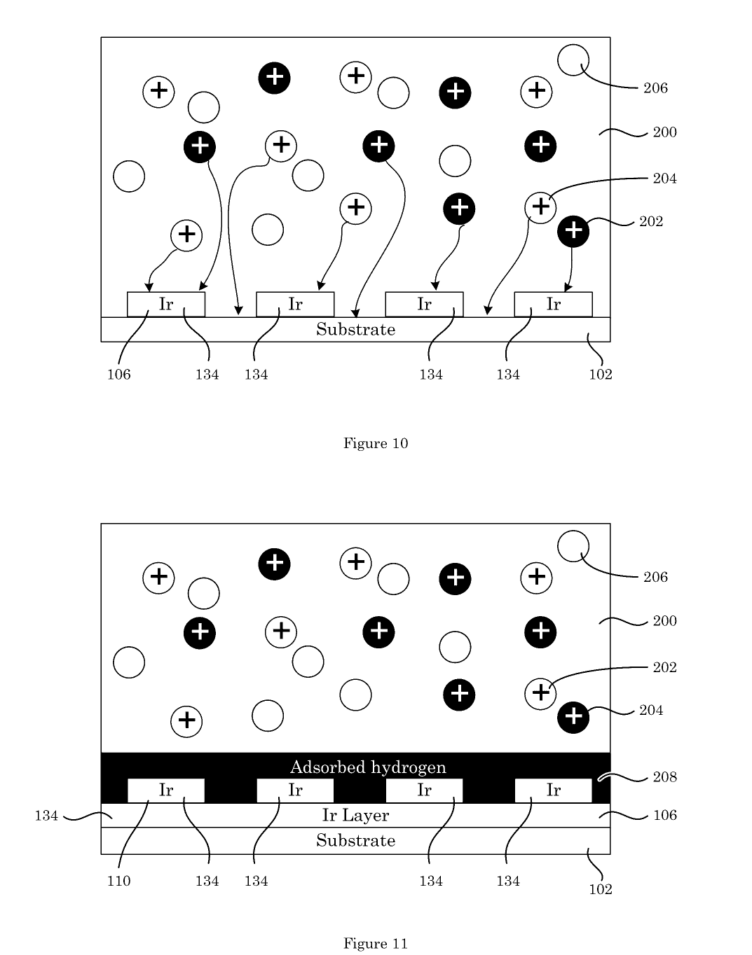

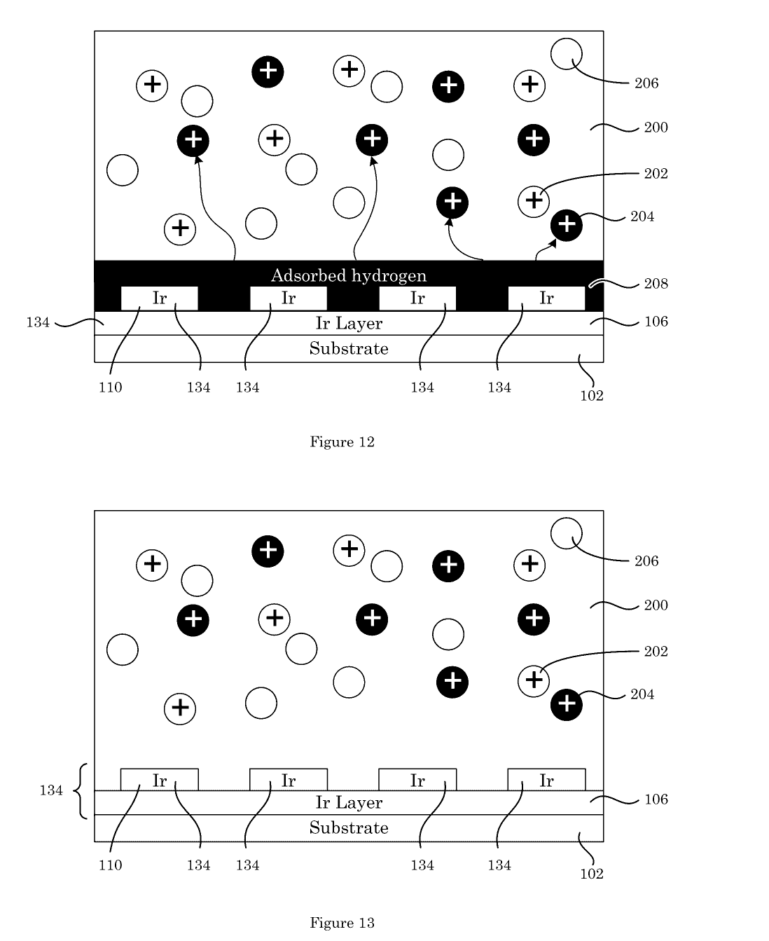

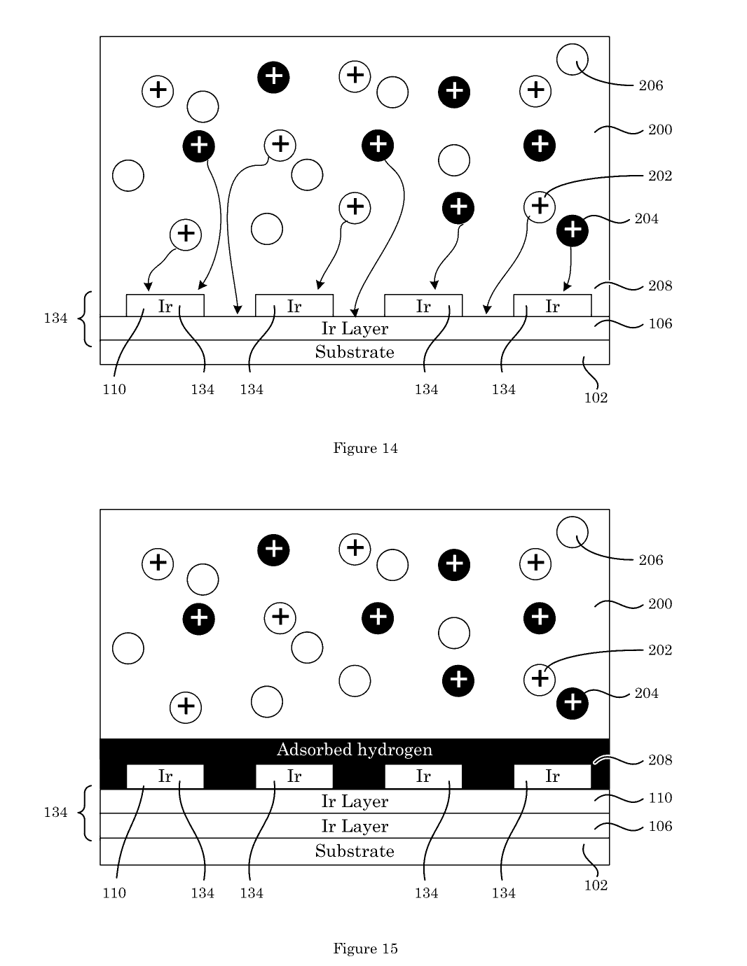

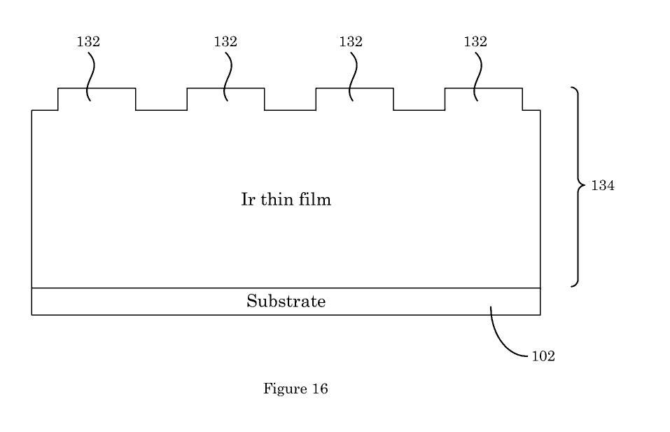

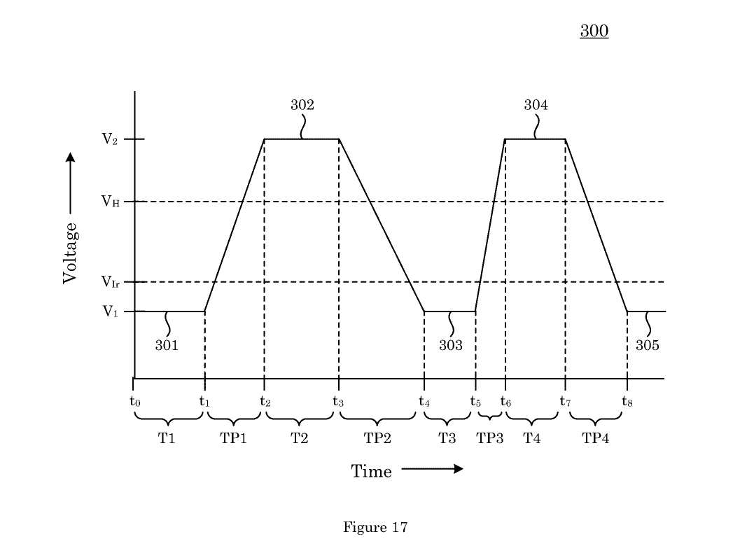

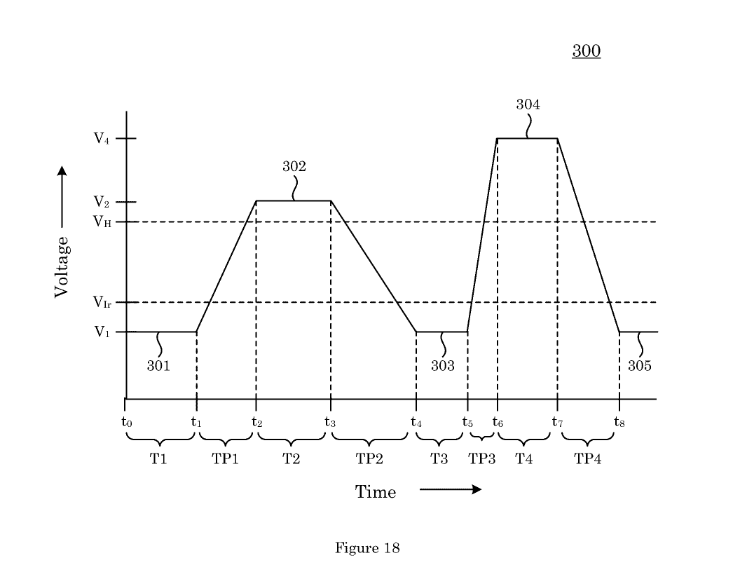

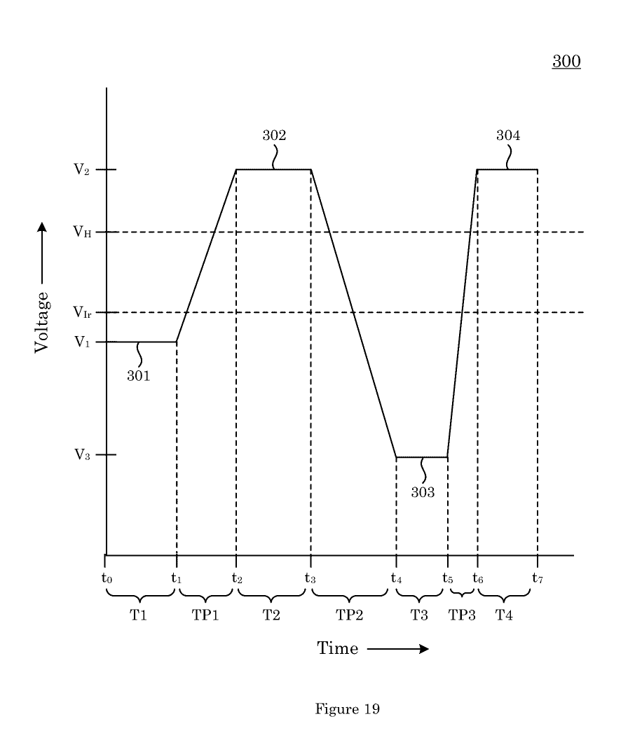

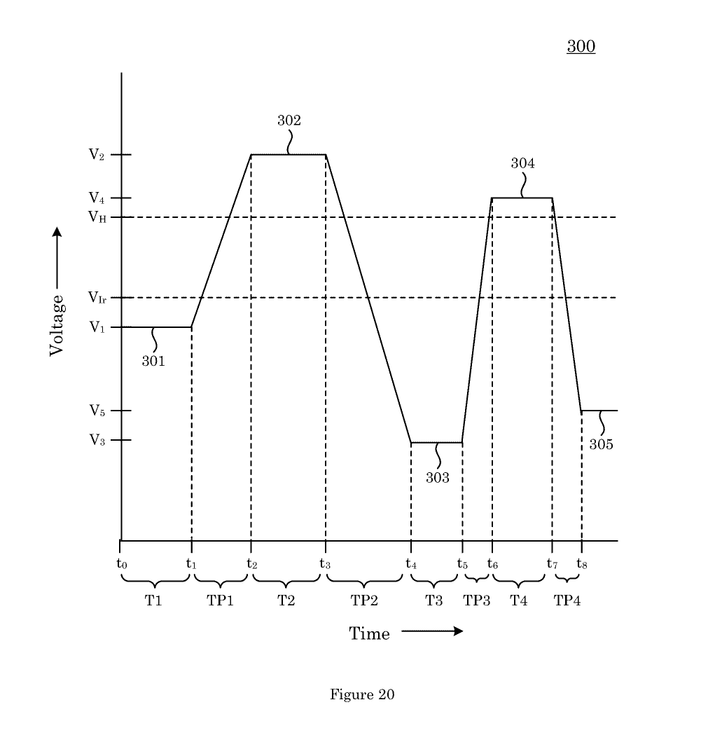

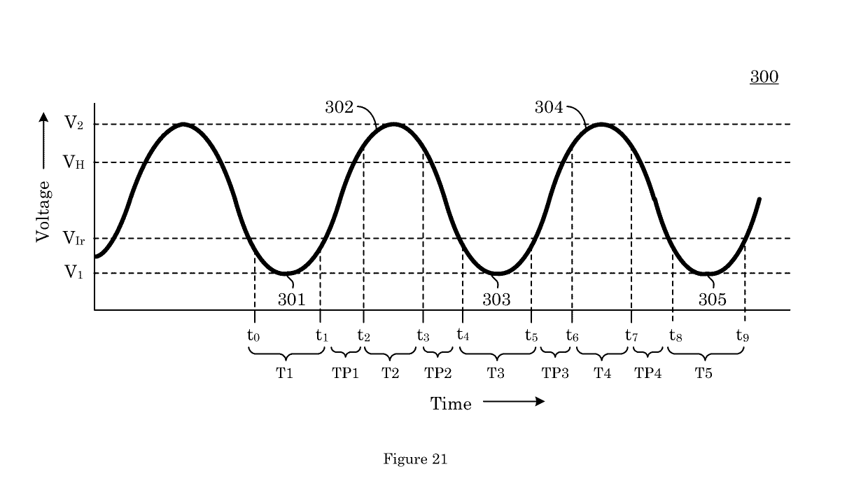

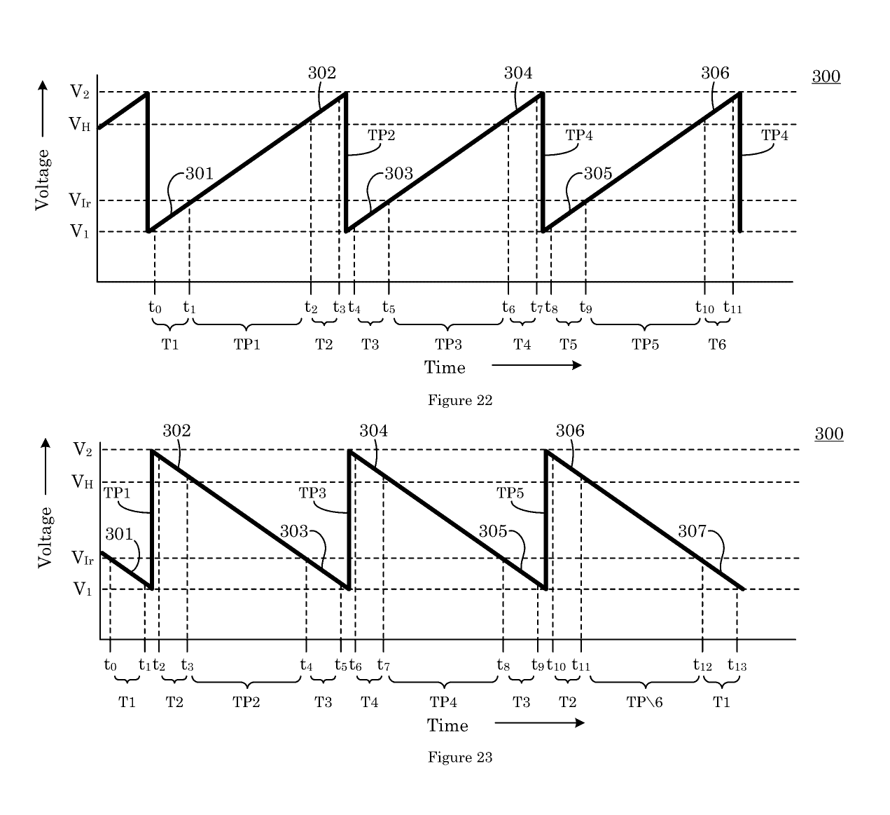

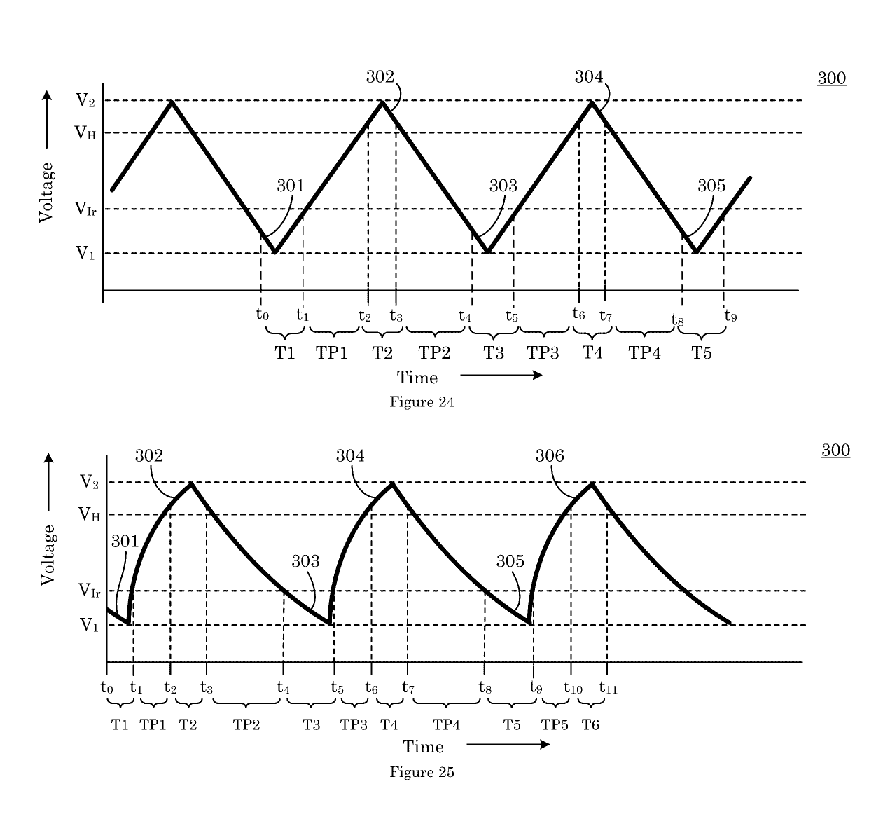

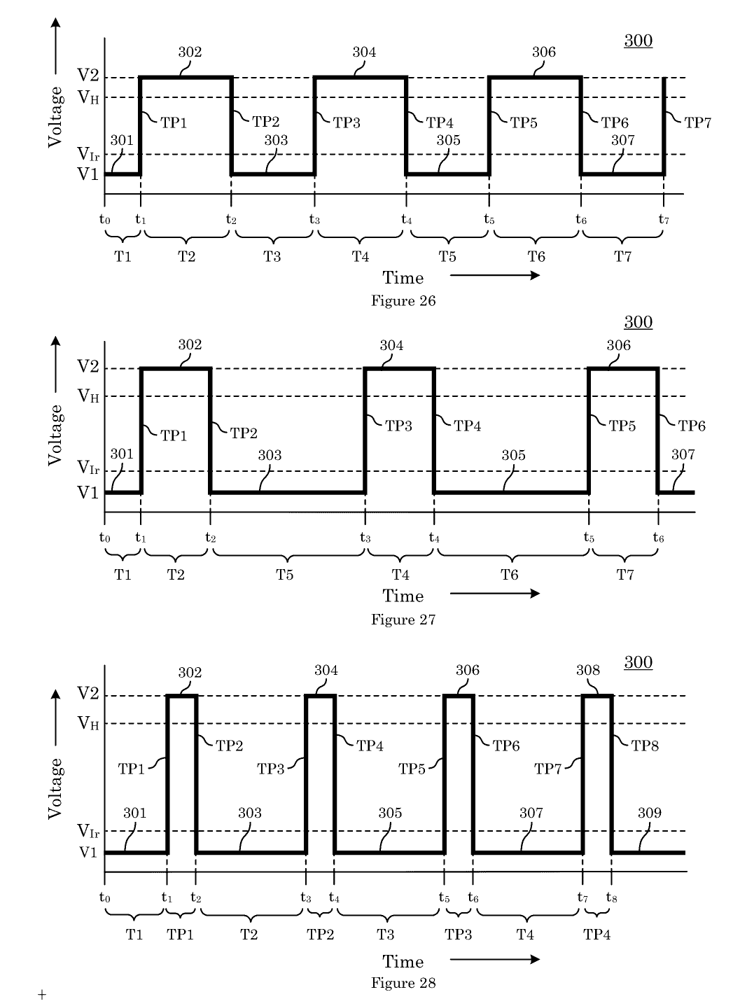

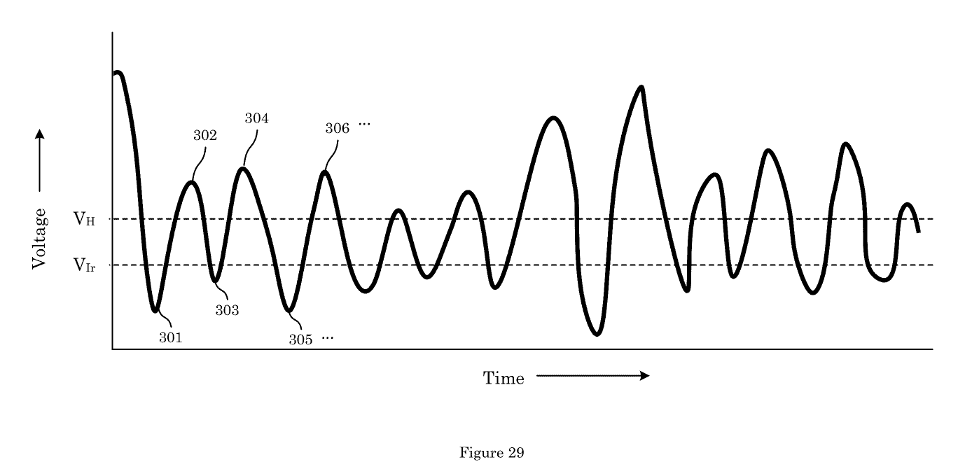

In an embodiment, as shown in FIG. 3 and FIG. 4, catalytic article 100 includes substrate 102 and a plurality of layers (e.g., 106, 110, 114, 118, 122, 126, 128, or the like) of iridium (e.g., Ir atoms 108, 112, 116, 120, 124, 128, 132, or the like) disposed on substrate 102 as thin film 136. First iridium layer 106 includes the plurality of iridium atoms 108 disposed in contact with substrate 102, and the plurality of iridium layers include the plurality of iridium atoms disposed on first iridium layer 106. Here, thin film 136 includes the plurality of discreet islands 134. Again, it should be appreciated that iridium atoms 108, 112 have a neutral charge and are deposited by a process that includes self-terminating deposition of iridium electrochemically from iridium cations in a presence of hydrogen adsorbed on substrate 102. In a particular embodiment, the hydrogen adsorbed on substrate 102 is adsorbed directly on iridium atoms disposed in a layer of iridium when depositing a new layer of iridium thereon.

Article 100 includes substrate 102 upon which iridium is deposited to form the plurality of layers of iridium. Substrate 102 includes the plurality of substrate atoms 104 and is electrically conductive. Substrate atoms 104 include a transition metal such as copper, gold, iridium, nickel, cobalt, palladium, ruthenium, titanium, platinum, rhodium, silver, or a combination thereof. Additionally, substrate atoms 104 can include oxides thereof such that substrate 102 includes the transition metal (such as copper, gold, iridium, nickel, cobalt, palladium, ruthenium, titanium, platinum, rhodium, silver), a thin (i.e., tunneling) oxide thereof, a conductive oxide thereof, or a combination thereof.

Substrate 102 also can include a supplemental element such as C, H, N, Li, Na, K, Mg, Ca, Sr, Ba, Bi, B, Al, P, S, O, and the like in an amount typically less than an amount of the transition metal. In an embodiment, substrate 102 includes gold. Substrate 102 can be produced from, e.g., a commercially available transition metal or can be grown, e.g., by sputtering, deposition, etc. Substrate 102 can include a particular crystalline orientation, e.g., having Miller indices <111>, <100>, and the like. Substrate can be amorphous, polycrystalline, or a single crystal. In an embodiment, substrate 102 has a stacked structure that includes a plurality of electrically conductive layers such as by forming a second film of a second transition metal (e.g., Pt) on a first film of a first transition metal (e.g., gold). In some embodiments, substrate 102 includes crystalline domains among amorphous material. Substrate 102 is selected to provide a surface on which to deposit iridium electrochemically. In an embodiment, substrate 102 is subjected to an electrical potential to provide electrons to iridium cations to form iridium (neutrally charged), to protons to form hydrogen (neutrally charged), or a combination thereof in an electrochemical reaction. In a certain embodiment, substrate 102 is subjected to an electrical potential to accept electrons from, hydrogen adsorbed on substrate 102 or the iridium layer to oxidize the hydrogen to protons in an electrochemical reaction.

With reference to FIG. 6, the plurality of layers of iridium are deposited as thin film 136 on substrate 102 electrochemically from electrochemical reduction of iridium cations 202 provided by electrolyte composition 200 in contact with substrate 102, a layer of iridium disposed on substrate 102, or a combination thereof. Electrolyte composition 200 can include salt 206, a source of iridium cations 202, a source of protons 204, a pH control agent, a buffer, a solvent, or a combination thereof. It is contemplated that the electrolyte composition 200 can be any ionic liquid that provides a source of iridium cations and protons.

Salt 206 can include an anion such as sulfate, sulfite, bisulfite, chloride, perchlorate, acetate, phosphate, nitrate, methane sulfonate, trifluromethanesulfonate, bis(trifluoromethylsulfonyl) imide, hexafluorophosphate, and the like in combination with a positive ion such as an alkali metal cation (e.g., H⁺, Li⁺, Na⁺, K⁺, Rb⁺, Cs⁺ and the like), alkaline earth metal cation (e.g., Mg²⁺, Ca²⁺, and the like), polyatomic positive ion (e.g., NH₄⁺, alkylammonium, imidazolium and its derivatives, and the like), and the like.

Exemplary salts include NaCl, KCl, NaBr, KBr, NH₄Cl, NH₄Br and the like. In an embodiment, the salt is Na₂SO₄.

The source of iridium cations 202 in electrolyte composition 200 can include an iridium cation 202 (Ir³⁺, Ir⁴⁺, or a combination thereof), a complex ion of iridium, or a combination thereof. The complex of iridium includes iridium(III) or iridium(IV) bound to a ligand, wherein the complex has a charge that ranged from +4 to −4, and the like, and the complex is included a cation in an iridium salt to provide the source of iridium cations 202 with a neutral charge in electrolyte composition 200. In an embodiment, the source of iridium cations 202 is the complex of iridium, wherein in response to reduction of iridium in the complex to form iridium atoms on substrate 102, the ligand is removed from the iridium atoms and can return to electrolyte composition 200.

The ligand can be any neutral or charged species that reversibly binds to iridium and provides Ir³⁺, Ir⁴⁺, Ir, and the like to participate in electrochemical reactions with substrate 102. Exemplary ligands in the complex of iridium include a halide (e.g., Cl⁻, Br⁻, and the like), water, polyatomic anions (e.g., OH⁻, SO₄²⁻, and the like), and the like. Exemplary complexes of iridium include [IrX₆]³⁻, [IrX₆]²⁻, [IrX₅(H₂O)]²⁻, [IrX₅(H₂O)₂]⁻, [(H₂O)₄Ir(OH)₂Ir(H₂O)₄]⁴⁺, [(H₂O)₅Ir(OH)Ir(H₂O)₅]⁵⁺, [Ir³⁺X⁻_{w}(HSO₄⁻)_{y}(H₂O)_{z}]^{3-w-y}, [Ir³⁺X⁻_{w}(SO₄²⁻)_{y}(H₂O)_{z}]^{3-w-2y}, a chloride equivalent thereof, a bromide equivalent thereof, a mixed chloride-bromide equivalent thereof, or a combination comprising at least one of the foregoing iridium complexes, wherein X is a halogen that includes Cl, Br, or a combination of Cl and Br (i.e., a mixed chloride-bromide); w is an integer from 1 to 6; y is an integer selected from 0, 1, or 2; and z is an integer such that z=6−x−y. The iridium complexes include [IrCl₆]³⁻, [IrCl₆]²⁻, [IrCl₅(H₂O)]²⁻, [IrCl₅(H₂O)₂]⁻, [Ir³⁺Cl⁻_{w}HSO₄⁻_{y}(H₂O)_{z}]^{3-w-y}, [Ir³⁺Cl⁻_{w}SO₄²⁻_{y}(H₂O)_{z}]^{3-w-2y}, [Ir(Cl,Br)₆]³⁻, [Ir(Cl,Br)₆]²⁻, [Ir(Cl,Br)₅(H₂O)]²⁻, [Ir(Cl,Br)₅(H₂O)₂]⁻, [Ir³⁺(Cl,Br)⁻_{w}HSO₄⁻_{y}(H₂O)_{z}]^{3-w-y}, [Ir³⁺(Cl,Br)⁻_{w}SO₄²⁻_{y}(H₂O)_{z}]^{3-w-2y}, [IrCl₅Br]³⁻, [IrCl₅Br]²⁻, [IrCl₄Br(H₂O)]²⁻, [IrCl₄Br(H₂O)₂]₋, [IrCl₄Br₂]³⁻, [IrCl₄Br₂]2⁻, [IrCl3Br₂(H₂O)]²⁻, [IrCl₃Br₂(H₂O)₂]⁻, [IrCl₃Br₃]3⁻, [IrCl₃Br₃]²⁻, [IrCl₂Br₃(H₂O)]²⁻, [IrCl₃Br₃(H₂O)₂]⁻, [IrCl₂Br₄]³⁻, [IrCl₂Br₄]²⁻, [IrClBr₄(H₂O)]²⁻, [IrCl2Br₄(H₂O)₂]⁻, [IrClBr₅]³⁻, [IrClBr₅]²⁻, [IrClBr₅(H₂O)₂]⁻, [IrBr₆]³⁻, [IrBr₆]²⁻, [IrBr₅(H₂O)]²⁻, [IrBr₅(H₂O)₂]⁻, [Ir³⁺Br⁻_{w}HSO₄⁻_{y}(H₂O)_{z]}^{3-w-y}, [Ir³⁺Br⁻_{w}SO₄²⁻_{y}(H₂O)_{z}]^{3-w-2y}, [(H₂O)₄Ir(OH)₂Ir(H₂O)₄]⁴⁺, [(H₂O)₅Ir(OH)Ir(H₂O)₅]⁵⁺, and the like, wherein w, y, and z are as previously defined.

According to an embodiment, iridium cations 202 include Ir³⁺ in an iridium complex, and electrolyte composition 200 further includes SO₄²⁻. In a particular embodiment, electrolyte composition 200 includes K₃IrCl₆—Na₂SO₄—H²SO₄.

The source of protons 204 in electrolyte composition 200 can include a protic solvent (e.g., water, an alcohol such as CH₃OH, isopropanol, and the like), mineral acid (e.g., H₂SO4, HCl, H₃PO₄, and the like), organic acid (e.g., formic acid, citric acid, and the like), and the like. The protic solvent can include a functional group such as a carboxyl group, carboxylate group, hydroxyl group amino group, and the like. According to an embodiment, the source of protons 204 is the protic solvent that includes a carboxylic acid, a salt of a carboxylic acid, an alcohol, an amine, or a combination thereof. The alcohol can be a monool, diol, triol, or polyol having more than three hydroxyl groups. In some embodiment, the source of protons is the monool alcohol having, e.g., from 1 to 10 carbon atoms such as methanol, ethanol, propanol, butanol, pentanol, hexanol, and the like. In a certain embodiment, the source of protons is mineral acid

In an embodiment electrolyte composition 200 is an aqueous solution, e.g., an aqueous solution that includes the protic solvent, which is sulfuric acid, methane sulfonic acid, nitric acid, hydrochloric acid, phosphoric acid, HBF4, perchloric acid, pyrophosphoric acid, polyvinyl sulfonic acid, polyvinyl sulfuric acid, sulfurous acid, or a combination thereof.

Electrolyte composition 200 can include a pH control agent with a proton dissociation constant Kₐ (as provided herein as pKₐ=−log (Kₐ)) effective to control a pH of electrolyte composition 200 to above or below a selected pH. Exemplary pH control agents include an acid, a base, and the like. To control the pH of electrolyte composition 200 to be acidic, a pKₐ of the pH control agent can be from −2 to 7. To control the pH of electrolyte composition 200 to be alkaline, the pKₐ of the pH control agent can be from 7 to 14.

In an embodiment, electrolyte composition 200 includes the solvent. Here, the solvent can be H₂O, or isopropanol, or a combination thereof. It should be appreciated that the solvent is selected not to interfere with depositing iridium layers on substrate 102. Moreover, the solvent is selected not to poison a catalytic activity of the iridium layers or catalytic article 100. However, a protic solvent can be added to electrolyte composition 200 to terminate forming the iridium on substrate 102.

In catalytic article 100, substrate 102 can have a thickness or surface area effective to deposit the plurality of layers of iridium thereon. Substrate 102 is electrically conductive, photoconductive, or a combination thereof. It is contemplated that substrate 102 can be planar or have another shape such as a curved shape that includes circular, toroidal, convex, concave, and the like shape.

The plurality of layers of iridium disposed as thin film 136 on substrate 102 of catalytic article 100 can have a thickness or surface area effective to catalyze a reaction on catalytic article 100. The thickness of thin film 134 can be, e.g., less than 0.0002 micrometers (μm), specifically from 0.0002 nm to 100 μm's, and more specifically 0.2 nm to 100 nm. The thickness of thin film 134 of iridium layers formed on substrate 102 is controlled during deposition of the plurality of iridium layers deposited on substrate 102 by increasing a number of repetitions of changing a potential of substrate 102. As used herein, “thin film” refers to a thickness that is less than or equal to 100 nm and includes such structures as an ultrathin film, multilayers thereof, and the like.

In an embodiment, thin film 134 of iridium layers (e.g., 106, 110, 114, and the like) on substrate 102 includes a submonolayer coverage of iridium. Thin film 136 of the plurality of iridium layers can include discreet islands 134, e.g., see FIG. 1, FIG. 2, FIG. 3, or FIG. 4. Thin film 136 can be semi-coherent with a mismatch in lattice parameters present between iridium atoms in thin film 136 and the arrangement of substrate atoms 104 in substrate 102. Thin film 136 can be a coherent lattice matched to the substrate, or semi-coherent, wherein the film and substrate lattices are aligned but with the misfit strain accommodated by dislocations typically concentrated at the interface, or completely the film and substrate lattices may be uncorrelated with no texture inheritance from substrate 102.

The plurality of layers of iridium (e.g., 106, 110) are electrochemically deposited on substrate 102 from components of electrolyte composition 200. Electrolyte composition 200 includes, e.g., the salt, iridium complex, and acid in an aqueous solution. The salt can be present in electrolyte composition 200 in an amount from 0 moles per liter (mol/L) to 4.9 mol/L, specifically from 0.0001 mol/L to 1 mol/L, and more specifically from 0.001 mol/L to 0.5 mol/L. The iridium complex can be present in electrolyte composition 200 in an amount from 0.000001 moles per liter (mol/L) to 0.1 mol/L, specifically from 0.0001 mol/L to 0.01 mol/L, and more specifically from 0.0005 mol/L to 0.005 mol/L. The acid can be present in electrolyte composition 200 in an amount from 0.0000001 moles per liter (mol/L) to 2 mol/L, specifically from 0.0000001 mol/L to 0.1 mol/L. It should be appreciated that chloride present in electrolyte composition 200 can decrease a rate of depositing a plurality of iridium layers (e.g., 106, 110) on substrate 102. In a certain embodiment, Cl⁻ can be present in electrolyte composition 200 in an amount less than 3 mol/L, from 0.001 mol/L to 0.1 mol/L.

A pH of electrolyte composition 200 is effective to deposit a plurality of iridium layers (e.g., 106, 110) as thin film 134 on substrate 102. The pH of electrolyte composition 200 can be from 0 to 14, specifically from 0 to 7, and more specifically from 0 to 6.5. According to an embodiment, the pH of electrolyte composition 200 is acidic to 1.5. In an embodiment, the pH of electrode composition 200 is alkaline to 6.5.

According to an embodiment, electrolyte composition 200 includes 3 mol/L K₃IrCl₆, 0.5 mol/L Na₂SO₄, and 0.0001 mol/L H₂SO₄.

Catalytic article 100 has numerous beneficial uses, including performing an electrochemical reaction. According to an embodiment, a process for performing an electrochemical reaction includes: providing an electrode such as catalytic article 100 that includes substrate 102 and a plurality of iridium layers (e.g., 106 and the like) disposed on substrate 102 and deposited according to the process of depositing the plurality of iridium layers on substrate 102; contacting the electrode with a second electrolyte composition including an electrochemically active reagent; and biasing the electrode at a potential effective to catalyze: an oxygen evolution reaction, wherein the second electrolyte composition is an acid environment; a hydrogen evolution reaction, wherein the second electrolyte composition is an alkaline environment; or a hydrogen oxidation reaction wherein the second electrolyte composition is an alkaline environment, to perform the electrochemical reaction. In an embodiment, a reference electrode is disposed in a container that includes the electrode and second electrolyte composition. Additionally, a pH monitor (e.g., an electronic pH monitor, litmus paper, an acid-base indicator, and the like) monitors the pH of the second electrolyte composition. A temperature of this electrochemical reactions arrangement is monitored or controlled via a thermocouple, resistance temperature detector, infrared detector, heating element, cooling element, and the like.

In an embodiment, the electrochemical reaction is the oxygen evolution reaction (OER), wherein the second electrolyte composition is an acid environment. Here, the second electrolyte composition can include sulfuric acid, perchloric acid, Nafion membrane, and the electrochemically active agent is H₂0. The electrode is biased positive of 1.4 V_{RHE} (where RHE is the reversible hydrogen electrode potential for the system) to catalyze the reaction.

In an embodiment, the electrochemical reaction is the hydrogen evolution reaction (HER), wherein the second electrolyte composition is an alkaline environment. Here, the second electrolyte composition can include NaOH or KOH or any OH— conducting membrane, and the electrochemically active agent is H₂0. The electrode is biased at any potential below 0.0 V_{RHE} to catalyze H2 production.

In an embodiment, the electrochemical reaction is the hydrogen oxidation reaction (HOR) wherein the second electrolyte composition is an alkaline environment. Here, the second electrolyte composition can include NaOH, KOH or any OH— conducting membrane, and the electrochemically active agent is hydrogen. The electrode is biased at potential positive of 0.0 V RHE to catalyze H₂ oxidation to water.

In an embodiment, catalytic article 100 is included as an anode, cathode or bifunctional electrode in a H₂—O₂ fuel cell or an organic-O₂ fuel cell, as an electrode for borohydride oxidation, ammonia oxidation and nitrate reduction. Such a fuel cell that includes catalytic article 100 provides water electrolysis. Beneficially catalytic article 100 can include a catalytic alloy (e.g., a bimetallic alloy) formed by depositing iridium on substrate 100 (that can be, e.g., platinum) to provide engineered substrate 102-iridium catalyst interactions. Catalytic article 100 includes the plurality of iridium layers on substrate 102, wherein the iridium provides an elemental catalyst for the oxygen evolution reaction (OER) in acid environments and production (HER) and oxidation (HOR) of hydrogen in alkaline media.

The process for depositing the plurality of iridium layers on substrate 102 and catalytic article 100 have beneficial and advantageous properties. The process provides electrochemical submonolayer deposition of thin catalytic iridium films on substrate 102 and effective use of different substrate materials (e.g., a transition metal such as Ni, Pt group elements, a combination thereof, and the like) to facilitate bimetallic catalysis in a sustainable hydrogen economy. Iridium thin film 136 can be deposited on substrate 102 as a semi-coherent Ir film using a K₃IrCl₆—Na₂SO₄—H₂SO₄ electrolyte composition 200 at a temperature from 40° C. to 70° C. Unexpectedly and advantageously, deposition reaction to form iridium on substrate 102 is quenched at an onset of H₂ production where adsorbed H 208 blocks reduction of IrCl₆₋ₓH₂Oₓ^{x-3} (wherein x is an integer from 0 to 6) to Ir on substrate 102 and such reaction self-terminates. Reduction of iridium cations 202 to the plurality of iridium layers on substrate 102 can be reactivated for further deposition of iridium by changing (e.g., pulsing) the potential of substrate 102 to a more positive value to oxidize adsorbed hydrogen 208. Iridium thin film 136 has electrocatalytic activity that is a function of the number of self-terminating deposition pulses of iridium. Moreover, iridium thin film 136 catalyzes electrochemical reactions for hydrogen production and its oxidation in alkaline media or oxygen production from acid.

Beneficially, the process for depositing the plurality of iridium layers on substrate 102 provides rapid, inexpensive atomic layer deposition of iridium in a fluid medium (e.g., electrolyte composition 200) and includes self-terminated Ir electrodeposition for making thin Ir films on a variety of substrates such as Au, Pt, Ni, Co, Cu, Ag, WC, C. Iridium thin film 136 provides OER and HER/HOR activity and also provides scalability growing such thin films of iridium, e.g., in energy conversion devices.

Advantageously, the process for depositing the plurality of iridium layers on substrate 102 provides enhanced catalytic performance by alloying and minimization of Pt-group metal loading by using iridium thin film 136 that maximizes a surface area to volume ratio of iridium and minimizes an amount of iridium used to produce iridium thin film 136.

Beneficially, the process for depositing the plurality of iridium layers on substrate 102 provides electrodeposition of Ir from Ir³⁺ chloro-complexes, self-terminated electrodeposition of Ir, and formation of Ir clusters and thin films on substrates such as Au, Pt, Ni, Co, Ag, Cu, WC, C in pulsed potential deposition.

The favorable corrosion and high temperature oxidation properties of Ir are well known and the articles and processes described herein can be usefully applied for mediation of environmental degradation of the underlying substrate materials.

The articles and processes herein are illustrated further by the following Examples, which are non-limiting.

### EXAMPLES

### Example 1

Experimental details for electrodeposition of iridium thin film, characterization of Ir thin film, and electrocatalysis using Ir thin film.

Ir electrodeposition was carried out in a double-jacketed three-electrode cell consisting of a Au or Pt working electrode, Ir counter electrode and a saturated K₂SO₄/Hg₂SO₄/Hg (SSE) reference electrode. The counter and reference electrodes were held in separate compartments connected to the main cell by fritted junctions. All three compartments were filled with 0.5 mol/L Na₂SO₄ at the same pH, while 3 mmol/L K₃IrCl₆, was dissolved in the main compartment; its addition denotes t=0 in timed experiments. Electrolytes were prepared using 18 MΩ deionized water; adjusting pH (1.5, 4.0, and 6.5) with dilute H₂SO₄ or NaOH. Parallel UV-vis absorption experiments at room temperature and 70° C. were performed using a spectrometer to follow the evolution, i.e., ligand exchange, in the electrolyte composition. Electrodeposition was performed on Au thin films or rotating disk electrodes of Au or Pt. The 120 nm thick 111-textured Au films were grown on 5 nm Ti seeded native SiO₂/Si(100) wafers, by electron beam evaporation. Organic residue on Au was eliminated by immersion in Caro's (piranha) solution (75% H₂SO₄₊₂₅% H₂O₂, based on volume) for 15 min, rinsed with water, dried with N₂ and transferred to the electrolyte within 2 minutes (min). Au and Pt rotating disc electrodes (RDE) 0.196 cm_{geo}² were prepared by mechanical polishing with 1.0 to 0.05 μm particle size Al₂O₃ slurries immediately prior to each experiment. Self-terminated Pt films were grown using a 3 mmol/L K₂PtCl₄-0.5 mol/L NaCl electrolyte titrated with HCl to pH 4.0. Deposition of platinum was performed at room temperature by stepping the potential to −0.8 V_{SSCE} using a saturated NaCl calomel (SSCE) reference electrode.

Characterization of the deposited iridium films were examined using an X-ray photoelectron spectroscopy (XPS) energy calibrated to the Au 4f_{7/2} peak at 83.98 eV. Spectra were analyzed with XPS software using a Shirley background correction. Ir overlayer thickness was estimated using the area ratio of Ir 4f and Au 4f, corrected by the sensitivity factors, s_{Ir}=5.021, s_{Au}=6.250, and the Lambert-Beer description of photoelectron transmission through the solid, with an effective attenuation length of 1.273 nm. For sub monolayer films, island coverage was evaluated while a hemispherical cluster model was used to estimate the island density for thicker films. Ir films deposited on Ni were briefly examined by XPS and Ion scattering (ISS). A scanning tunneling microscope (STM) and electrochemically etched W tips were used to examine the topography of the Ir films and Au substrate under Ar. Freshly deposited films were transferred to the STM under H₂ atmosphere and imaged with 0.75 nA to 1 nA tunneling current at 0.1 V tip-substrate bias. Scanning transmission electron microscopy with energy dispersive X-ray spectroscopy (STEM-EDS) and transmission electron microscopy (TEM) measurements were used to examine cross-sectioned lamella of Ir films on Au. The films were prepared by focus ion beam (FIB) milling using a coating of C and Pt to protect against ion damage. An as-prepared lamella was milled and cleaned with Ga ions for electron transparency, typically 50 nm in thickness. High-angle annular dark-field scanning transmission electron microscopy (HAADF-STEM) images were acquired from the prepared lamella using a probe corrected STEM microscope operated at 300 keV. The probe was typically corrected to 20 mrad providing a spatial resolution of 0.1 nm. The probe convergence angle is 24 mrad and the HAADF inner and outer collection angles are 70 mrad and 400 mrad, respectively. EDS spectral images were collected using a windowless detector with solid angles up to 0.5 sr.

Electrocatalysis measurements were performed on Ir thin films grown by multi-pulse deposition in 3 mmol/L K₃IrCl₆-0.5 mol/L Na₂SO₄ pH 4.0 electrolyte. Pt and Pt—Ir composite films were also examined. Hydrogen evolution (HER) and the hydrogen oxidation (HOR) reactions were examined by voltammetry in the hydrogen-saturated 0.1 mol/L KOH at room temperature, ≈21° C. The counter electrodes were Ir or Pt plates and a reversible hydrogen reference electrode (RHE), was used. Impedance measurements determined the electrolyte resistance between the working and reference electrode, 42.6Ω, that was used for post-measurement iR-correction of the voltammetry. The first positive-going voltammetric scan is presented while the exchange current density was determined by linear polarization analysis±10 mV around 0 V_{RHE}. The room temperature oxygen reduction (ORR) and water oxidation OER activity were examined in O₂-saturated 0.1 mol/L HClO₄ or 0.1 mol/L H₂SO₄ using a scan rate of (5 or 10) mV/s. Voltammetric scans were corrected for the measured electrolyte resistance, 25.9Ω and 20.7Ω, respectively. The data presented correspond to the first positive-going voltammetric scan. The counter electrode was either an Ir wire or Pt plate while potentials were measured relative to a reversible trapped hydrogen electrode (RHE).

### Example 2

### Analysis of Iridium Films

Electrodeposition of iridium was performed as described in Example 1 using the electrolyte composition that included K₃IrCl₆—Na₂SO₄—H₂SO₄ from pH 1.5 and pH 6.5.

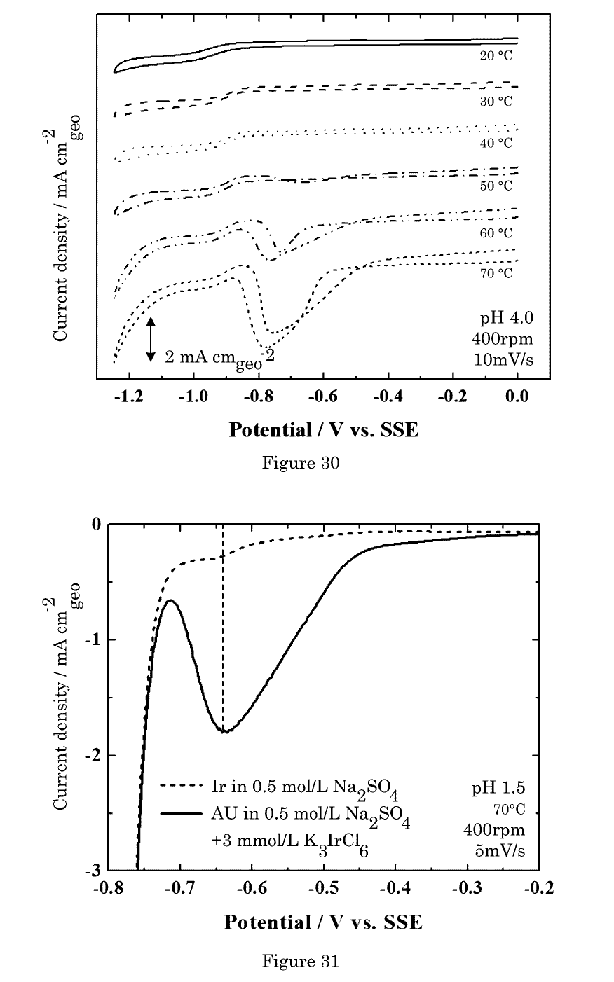

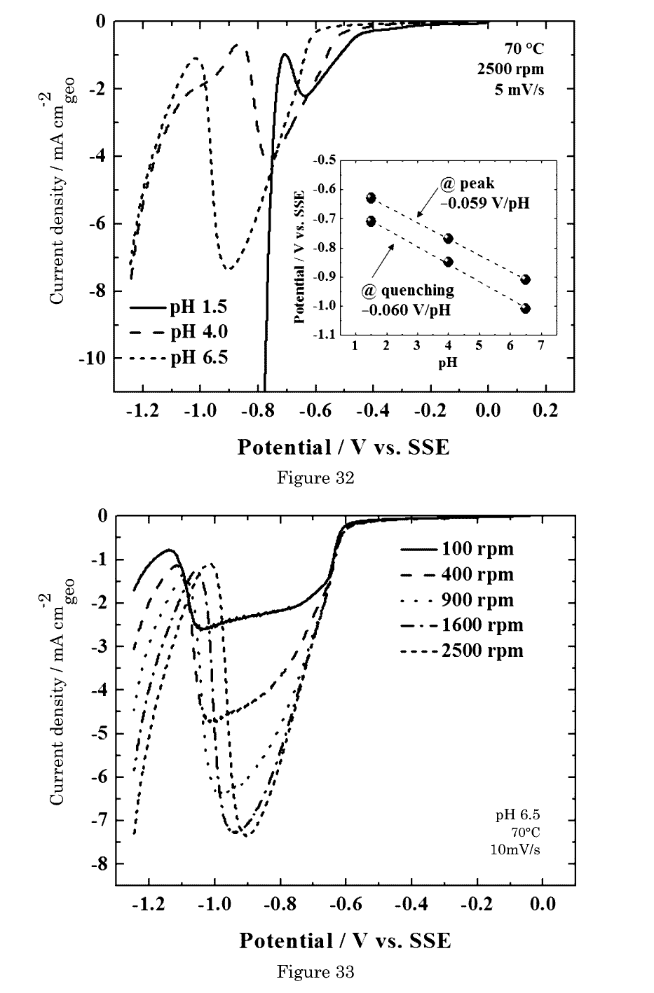

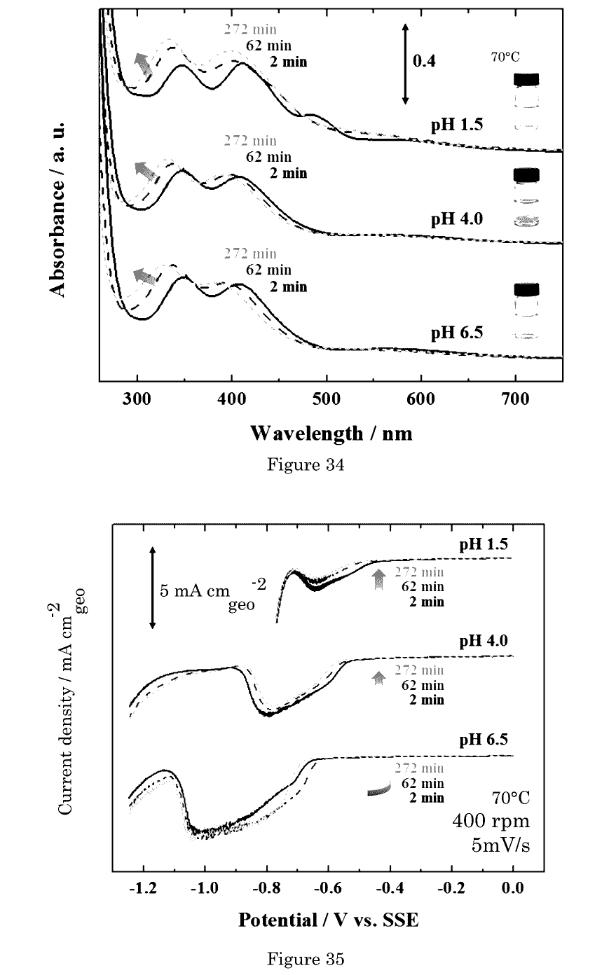

FIG. 30, FIG. 31, FIG. 32, and FIG. 33 show data for self-terminated Ir electrodeposition on Au RDE in 3 mmol L⁻¹ K₃IrCl₆—0.5 mol L⁻¹Na₂SO₄—x mol L⁻¹ H₂SO₄ in which: Ir deposition was thermally activated (FIG. 30); Ir deposition was quenched at the onset of hydrogen evolution (FIG. 31); Ir deposition and quenching depended on pH (FIG. 32, wherein the inset shows a pH dependence of the maximum deposition rate and minimum associated with self-termination that was consistent with a proton coupled charge transfer reaction); and for pH 6.5 the Ir deposition peak and quenching potentials depended on hydrodynamics (FIG. 33). FIG. 34 shows a graph of absorbance versus wavelength in which an evolution of UV-vis spectra for electrolyte compositions was acquired at 70° C., wherein the insets show photographs of the as-prepared electrolyte compositions. FIG. 35 shows a graph of current density versus potential that corresponded to voltammograms for Ir deposition.

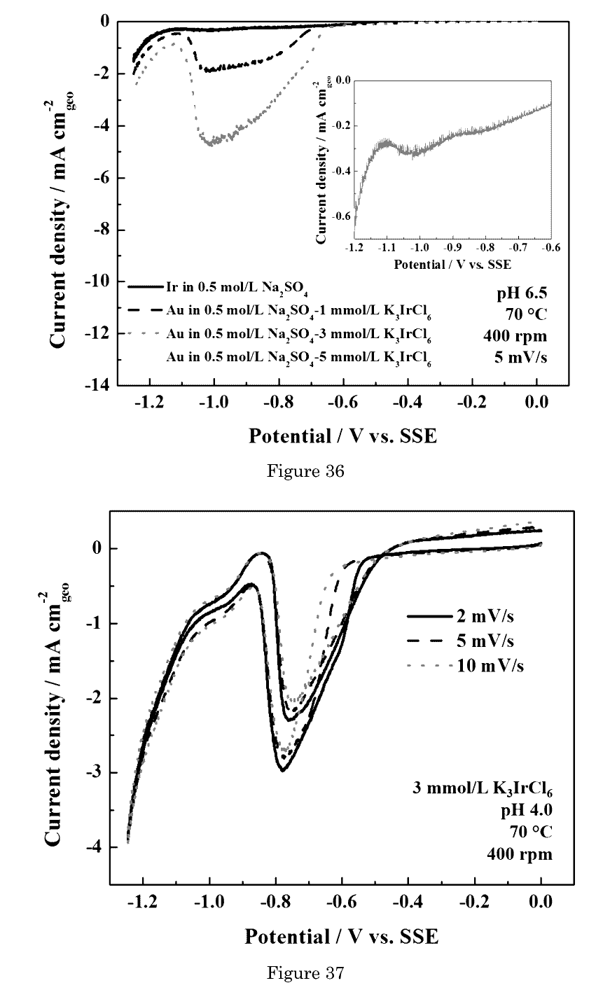

Ir deposition on Au was thermally activated with development of a well-defined current peak near −0.80 V_{SSE} at temperatures above 40° C. in a pH 4 electrolyte composition (FIG. 30). At more negative potentials, the current decreased due to quenching of Ir deposition. Self-termination occurred with onset of hydrogen production followed by diffusion limited proton reduction below −0.85 V_{SSE}. The same processes occurred in pH 1.5 with quenching of Ir growth coincident with onset of hydrogen evolution, ≈−0.70 V_{SSE}, on Ir-covered Au electrode (FIG. 31). Comparison to Ir voltammetry in the supporting electrolyte composition revealed overlap between the maximum deposition current and the H_{UPD} regime observed on Ir in the absence of dissolved Ir³⁺. Similar phenomenon was observed in pH 6.5 as shown in FIG. 36. It is believed that H_{UPD} waves convolve anion desorption and H adsorption on iridium.

Superposition of Ir deposition and anion desorption/proton adsorption suggest that metal deposition is associated with disruption and desorption of the anion adlayer while formation of a complete H_{UPD} layer terminates Ir deposition.

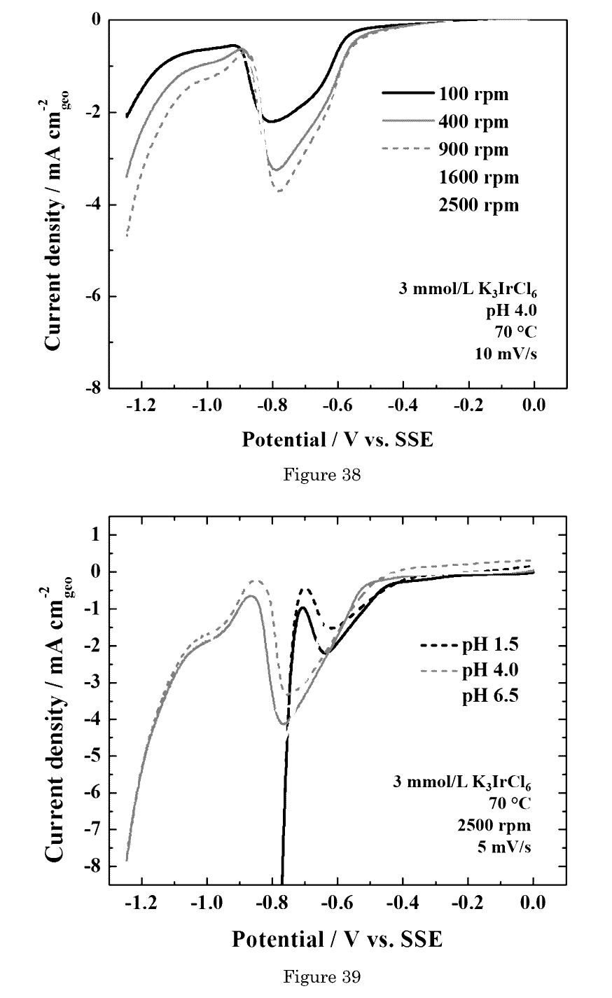

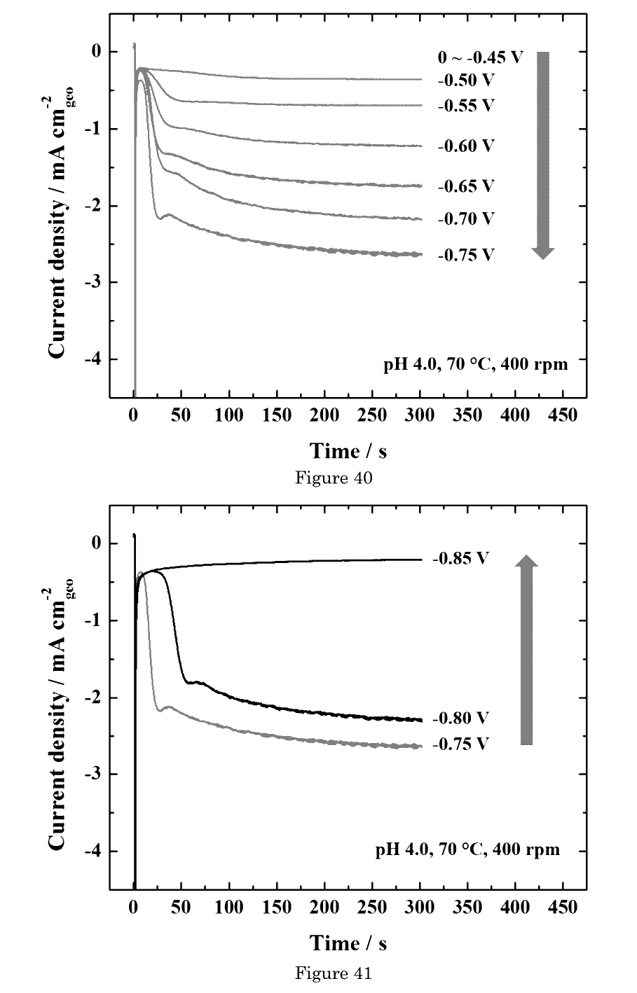

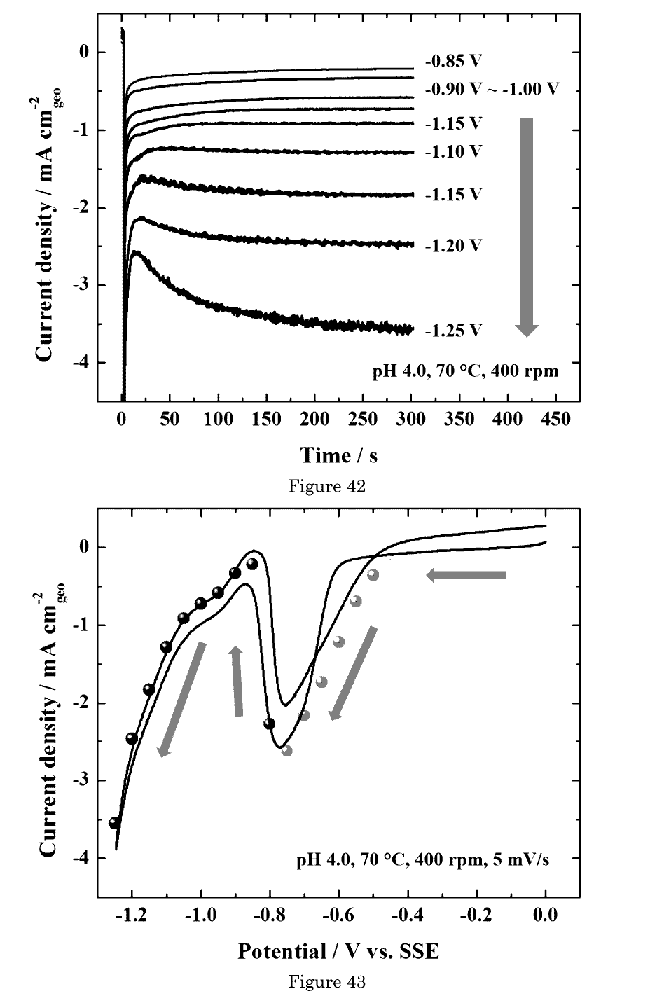

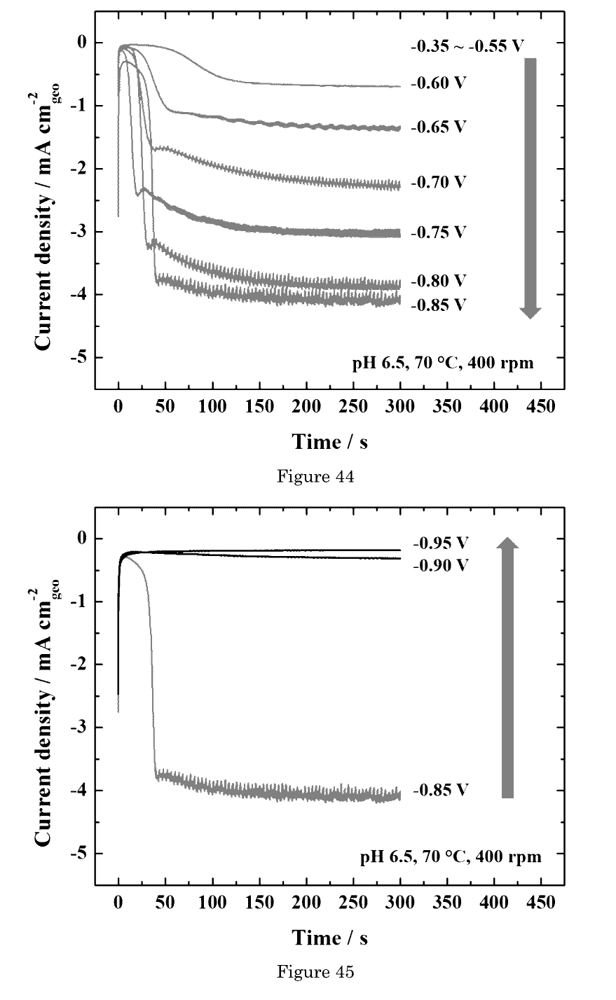

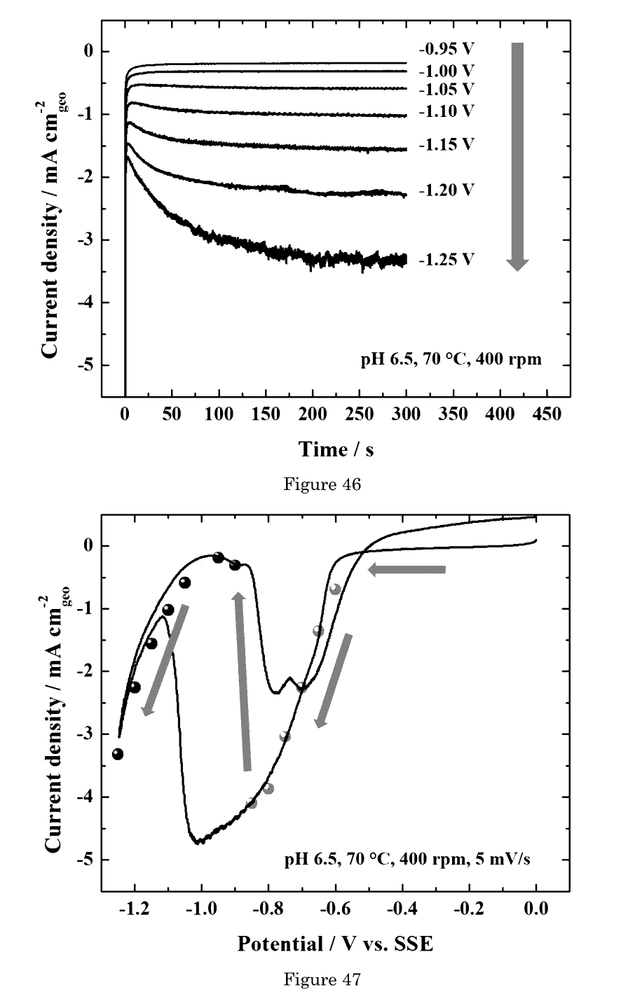

Ir nucleation on Au is hindered as shown by the scan rate dependence of the onset of deposition in pH 4.0 (FIG. 37). The onset potential decreased with pH while the peak current increased (FIG. 32). At low Ir³⁺ concentrations and slow electrode rotation rates, the peak deposition current was a monotonic function of the Ir³⁺ flux. However, the peak current saturated for rotation rates above 1600 rpm (FIG. 33, FIG. 38) reflecting dominance by surface processes. In contrast to pH 4.0 (FIG. 38), quenching of Ir deposition in pH 6.5 (FIG. 33) was influenced by mass transport. For the slowest rotation speed a broad deposition wave developed prior to termination of Ir growth at −1.04 V_{SSE}. With increasing rotation speed, quenching occurred at more positive potentials and the overall deposition wave was more symmetric. At 2500 rpm, the peak potential shifted −0.059 V pH⁻¹ (FIG. 32) consistent with a proton coupled charge transfer controlled reaction. Reactivation of the deposition process occurred during the return voltammetric sweep (FIG. 30, FIG. 39). Ir nucleation and growth kinetics were also examined by chronoamperometry. The steady-state sampled current at modest overpotentials was congruent with the voltammetric results in pH 4.0 (FIG. 40, FIG. 41, FIG. 42, FIG. 43) while in pH 6.5 a lag in quenching is apparent for the negative going sweep (FIG. 44, FIG. 45, FIG. 46, FIG. 47).

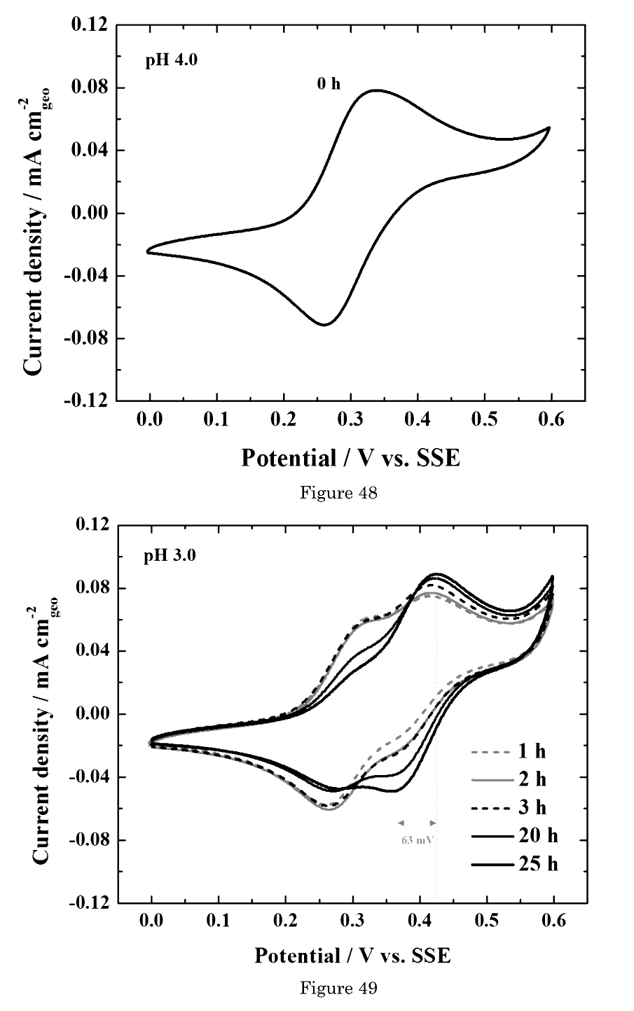

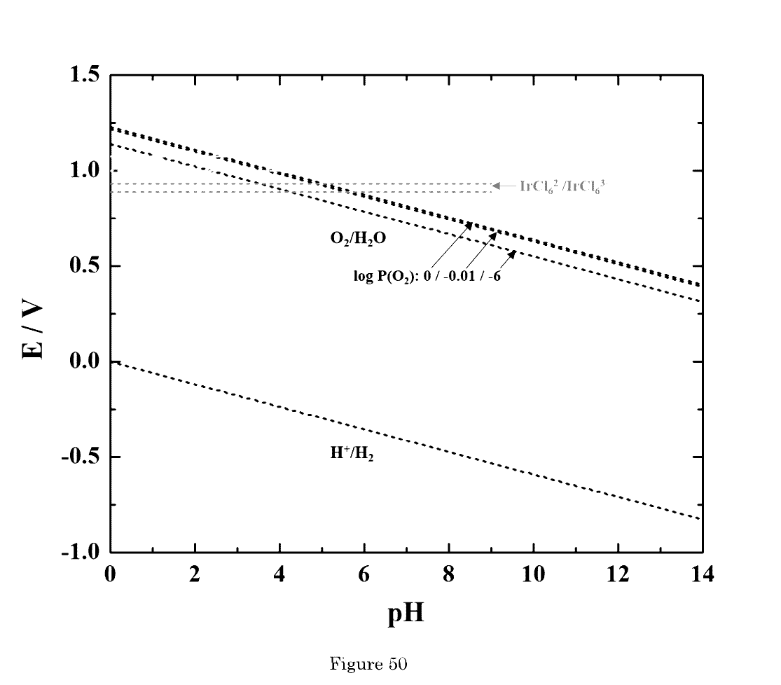

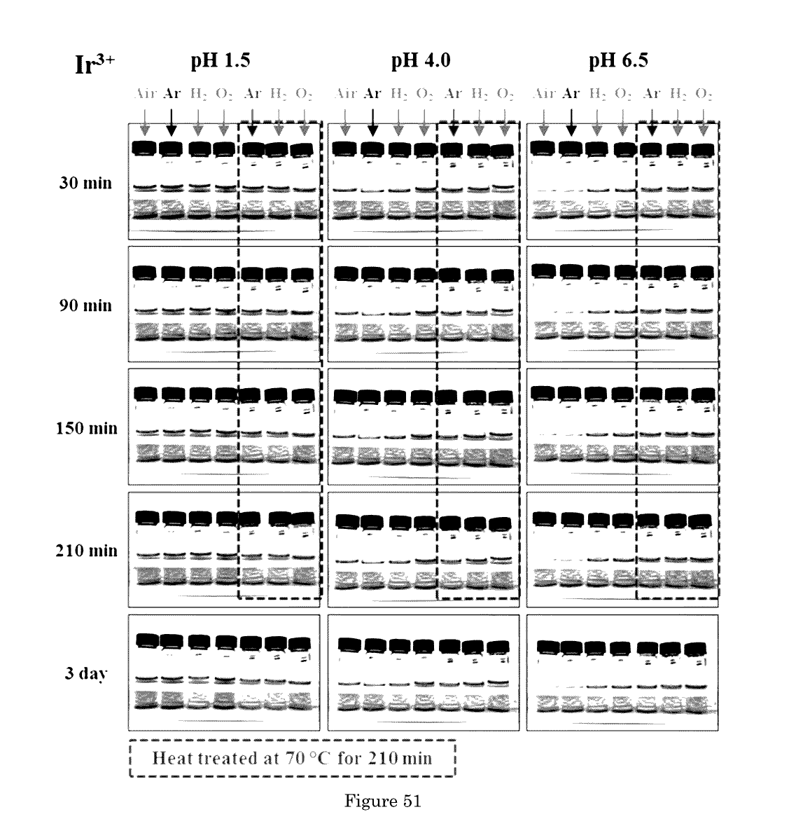

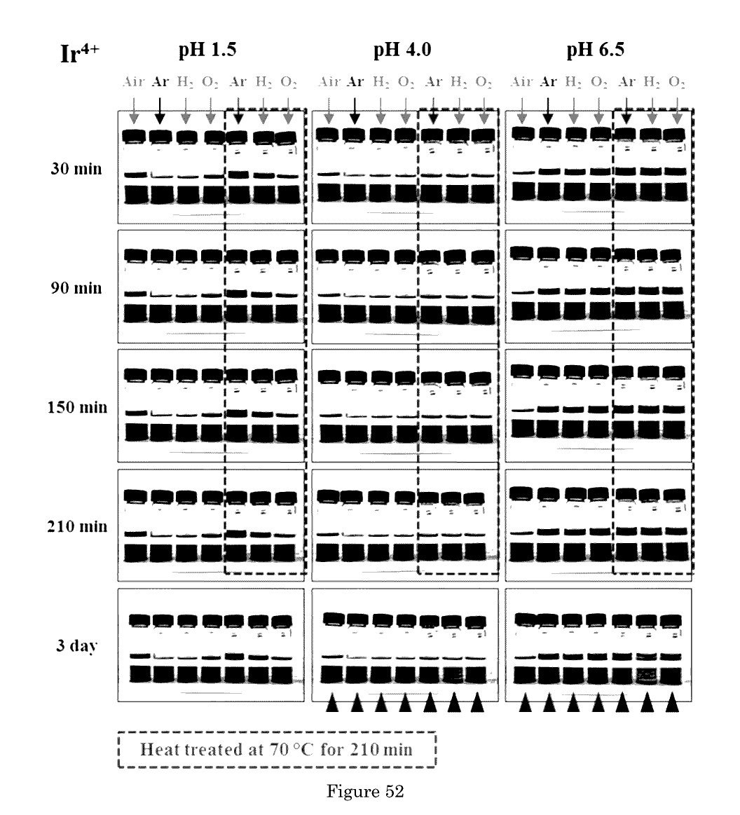

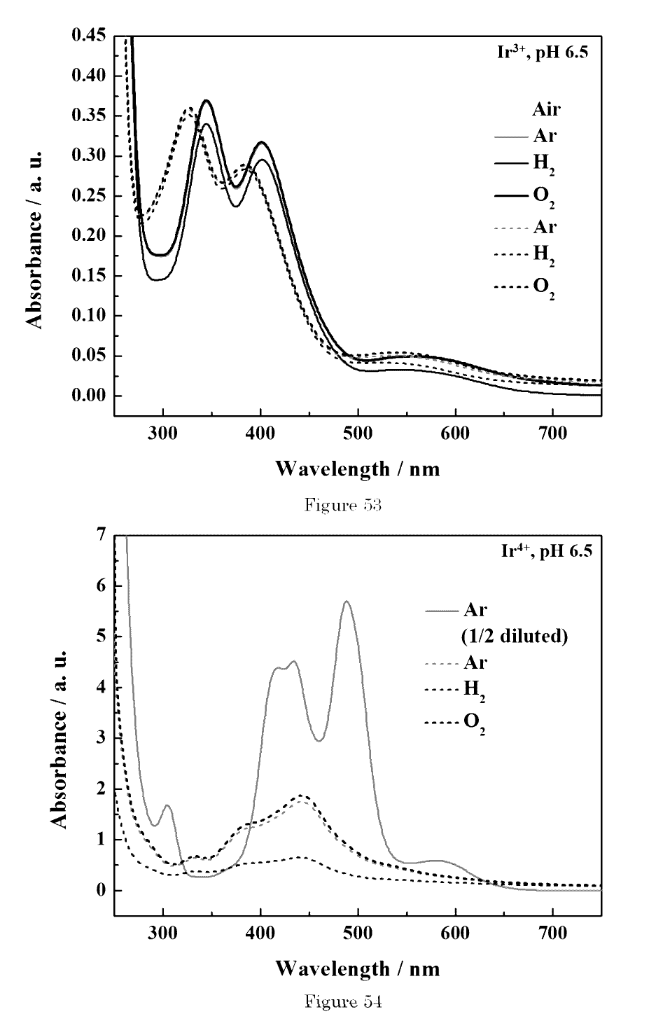

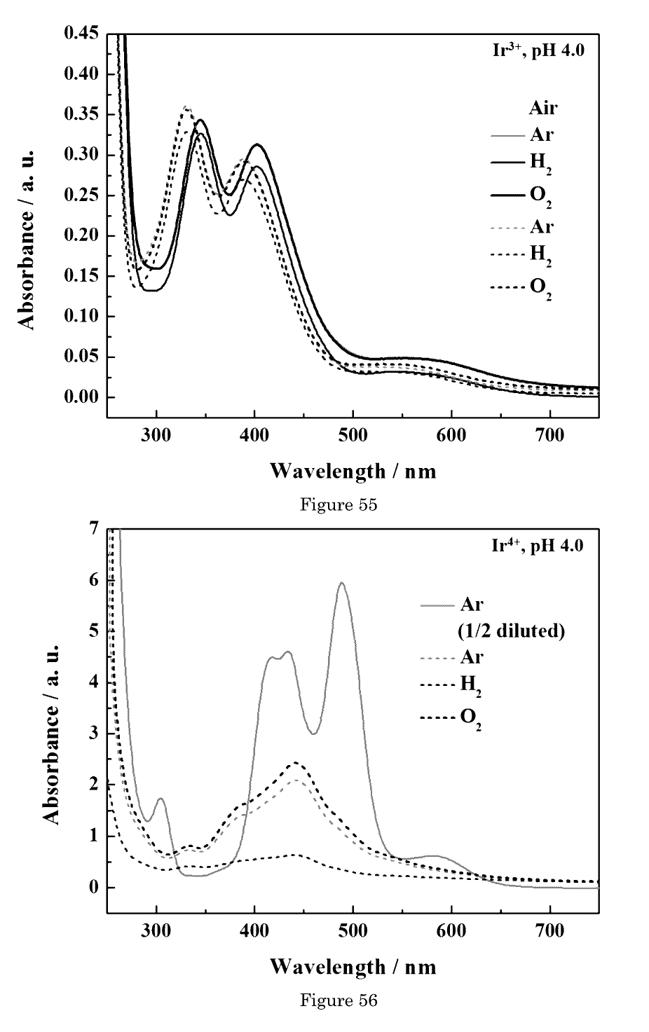

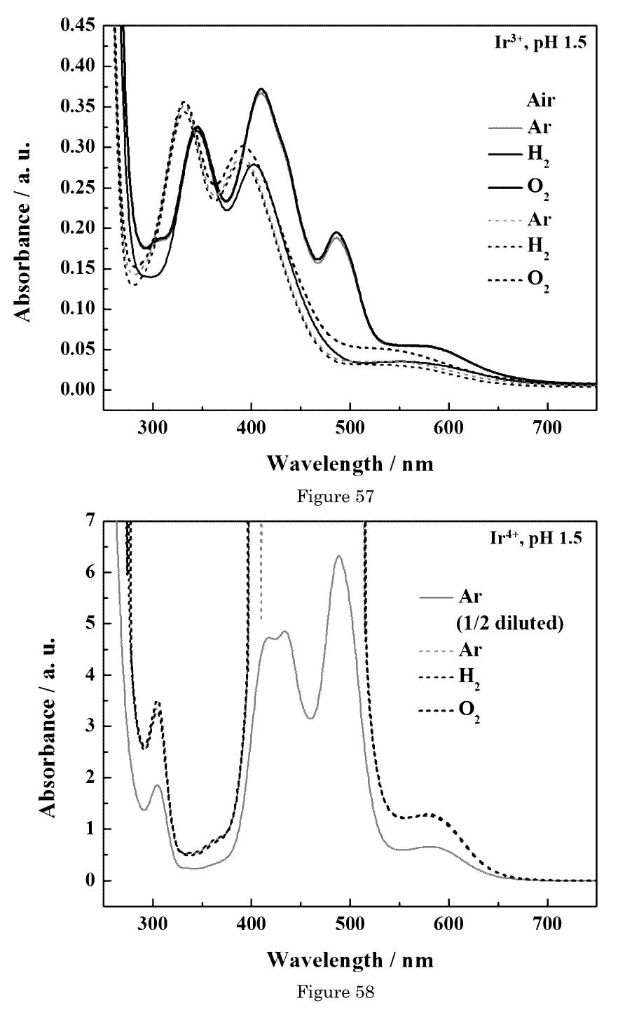

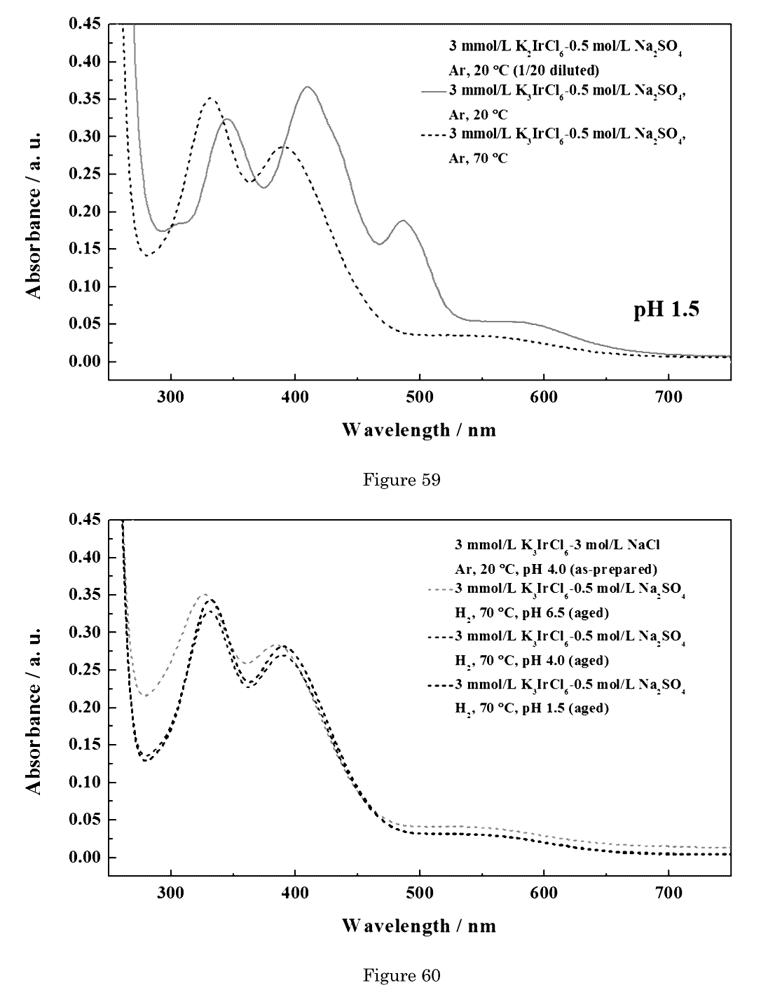

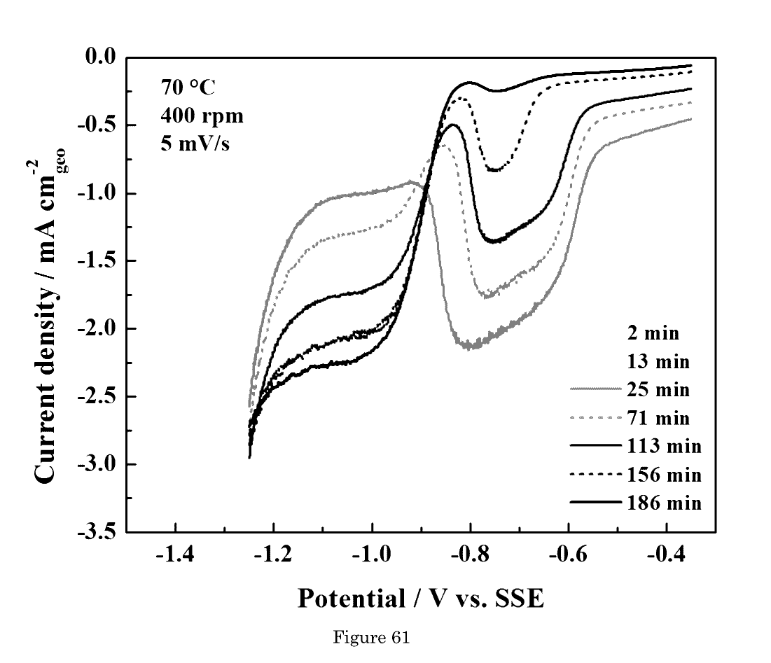

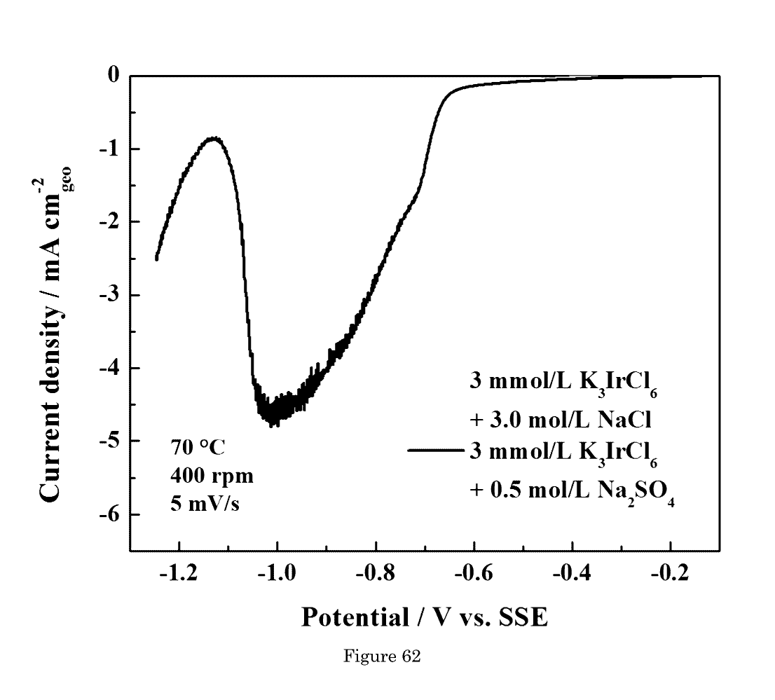

Speciation of Ir³⁺ complexes in the as-prepared electrolyte compositions and during electrolysis was examined by UV-visible absorption spectroscopy. At room temperature octahedral IrCl₆³⁻ is relatively inert to water exchange however, at 70° C. ligand exchange was evident by color change and evolution of the IrCl₆₋ₓ(H₂O)ₓ^{3-x} spectra shown in FIG. 34. Likewise, a multiplicity of Ir³⁺/Ir⁴⁺ redox states developed with aging as evident by cyclic voltammetry (FIG. 48, FIG. 49). Spectra for aged Ir³⁺ electrolyte compositions were quite similar although a small quantity of Ir⁴⁺ species was initially present in the pH 1.5 solution due to homogenous reaction between Ir³⁺ and O₂ (FIG. 50, FIG. 51, FIG. 52, FIG. 53, FIG. 54, FIG. 55, FIG. 56, FIG. 57, FIG. 58, FIG. 59, FIG. 60, FIG. 61). Also, certain voltammetric characteristics of Ir deposition were not significantly altered by aging of the Ir³⁺ precursors (FIG. 35). However, when the supporting electrolyte composition is changed from 0.5 mol L⁻¹ Na₂SO₄ to 3.0 mol L⁻¹ NaCl, negligible Ir deposition was observed at 70° C. (FIG. 62). The high Cl⁻ concentration stabilizes the chloro-complexes and supports formation of a saturated Cl⁻ adlayer on the electrode surface. Since IrCl₆³⁻ was the dominant complex in freshly prepared 0.5 mol L⁻¹ Na₂SO₄ and metal deposition still occurred at 70° C., adsorbed Cl⁻ can serve as an inhibitor of Ir nucleation on Au by blocking adsorption of Ir³⁺ species. Similarly, a rapid increase in Cl⁻ from 0.01 mol L⁻¹ to 0.5 mol L⁻¹ resulted in quenching of Ir deposition while re-equilibration of chloro-complexes required a more extended time period (not shown).

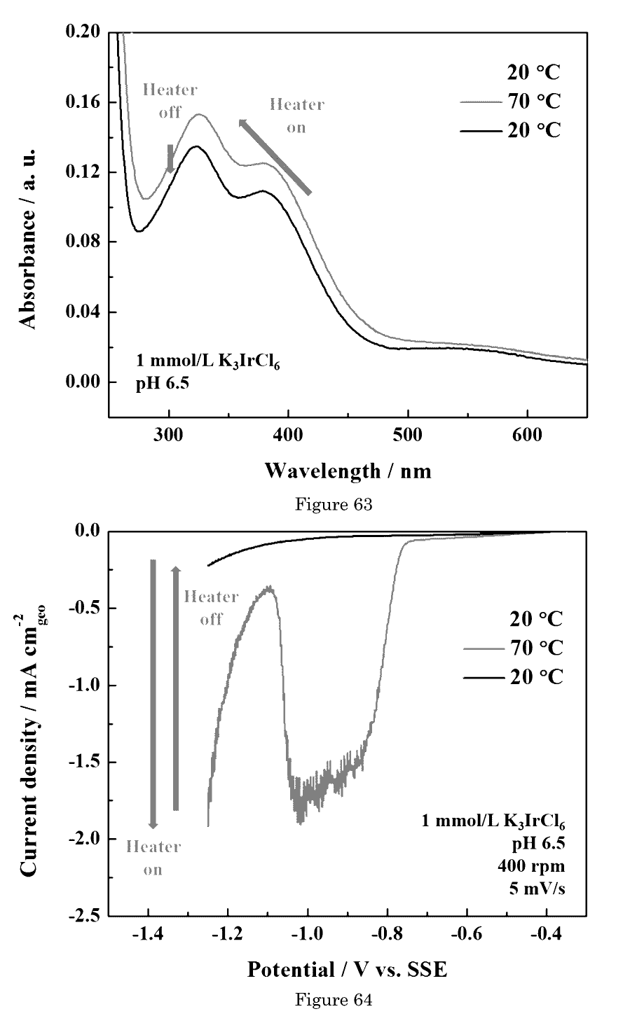

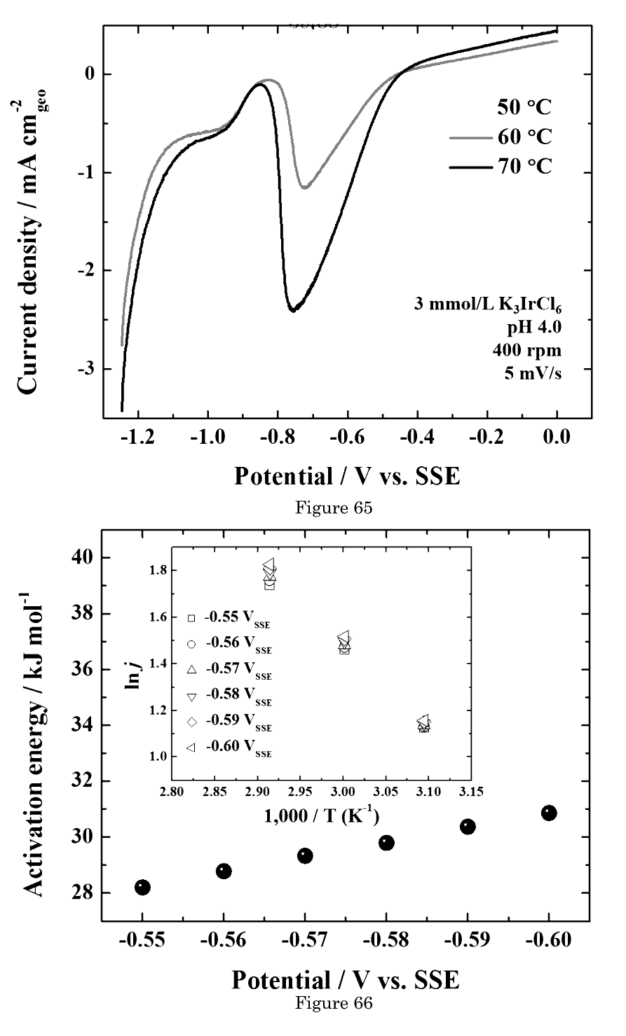

Thermal activation of Ir deposition was also examined by thermally cycling the electrolyte composition. Moving between 70° C. and 20° C. the reaction was turned on and off with little correlation to the UV-vis spectral positions of the evolving Ir³⁺ species, although the molar absorptivity changed measurably with temperature (FIG. 63, FIG. 64). Analysis of Ir deposition in FIG. 30 indicates an activation energy of (29.5±0.9) kJ mol⁻¹ (FIG. 65, FIG. 66).

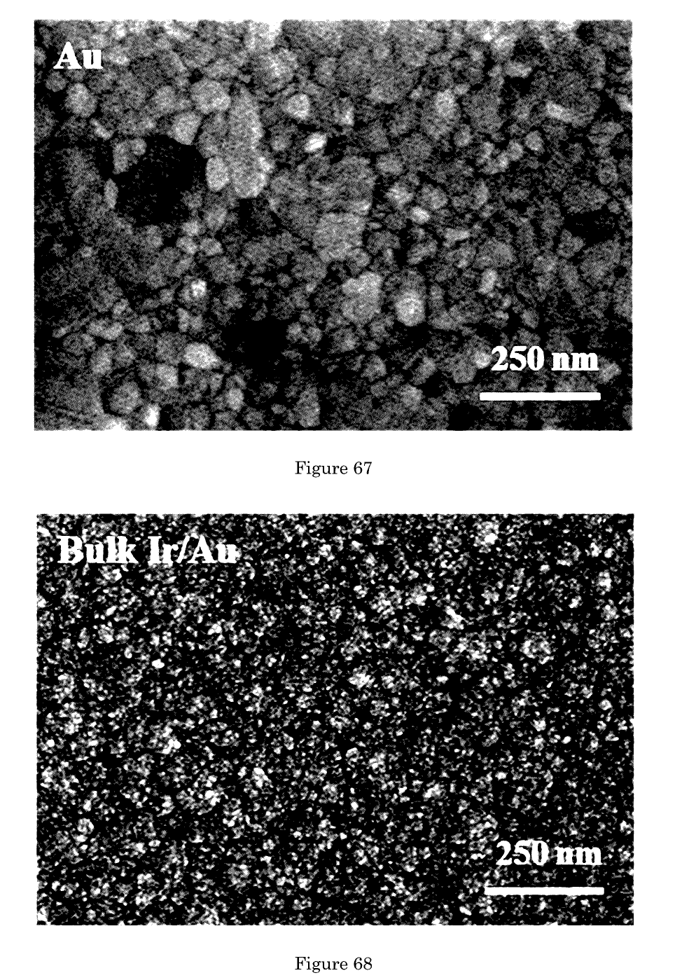

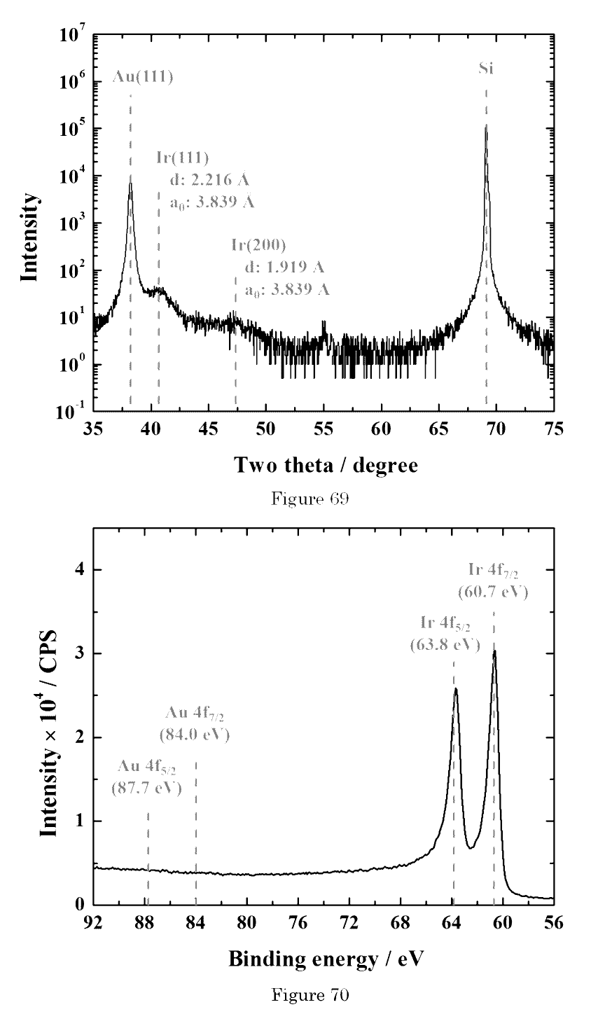

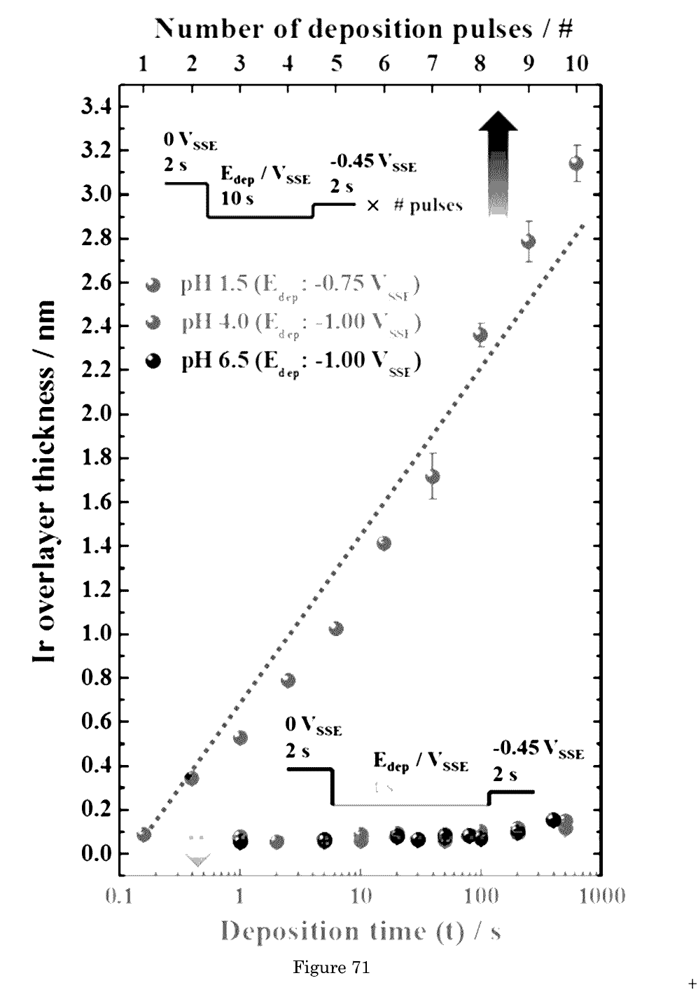

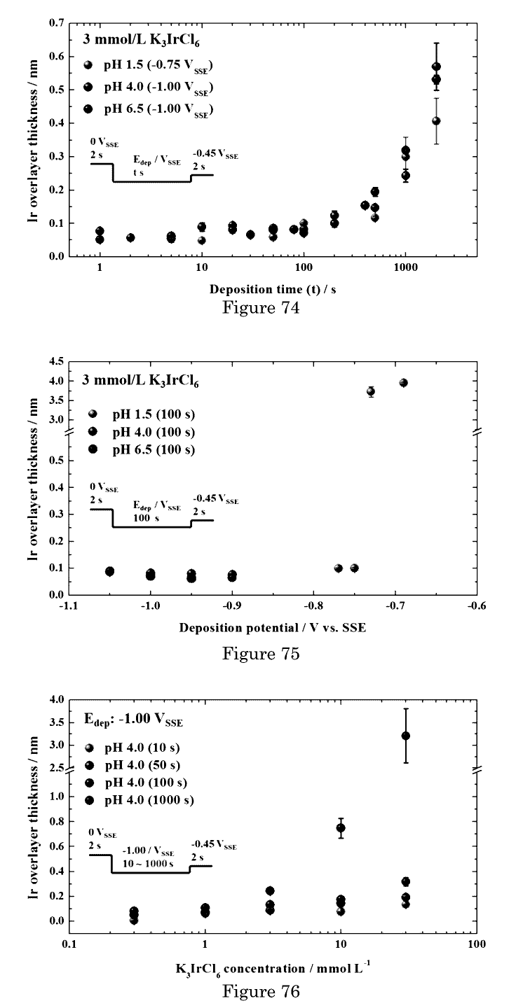

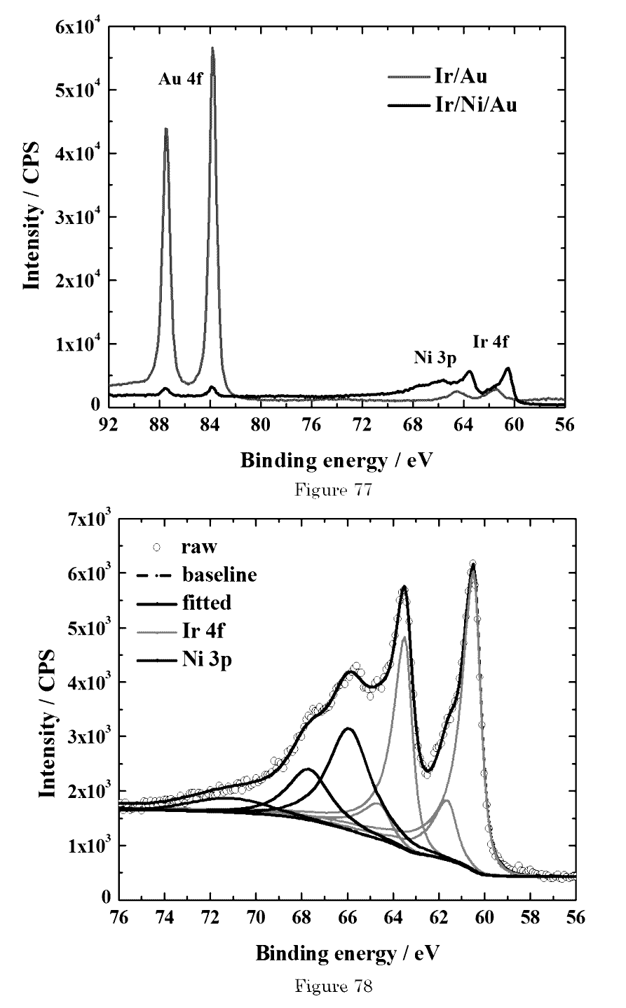

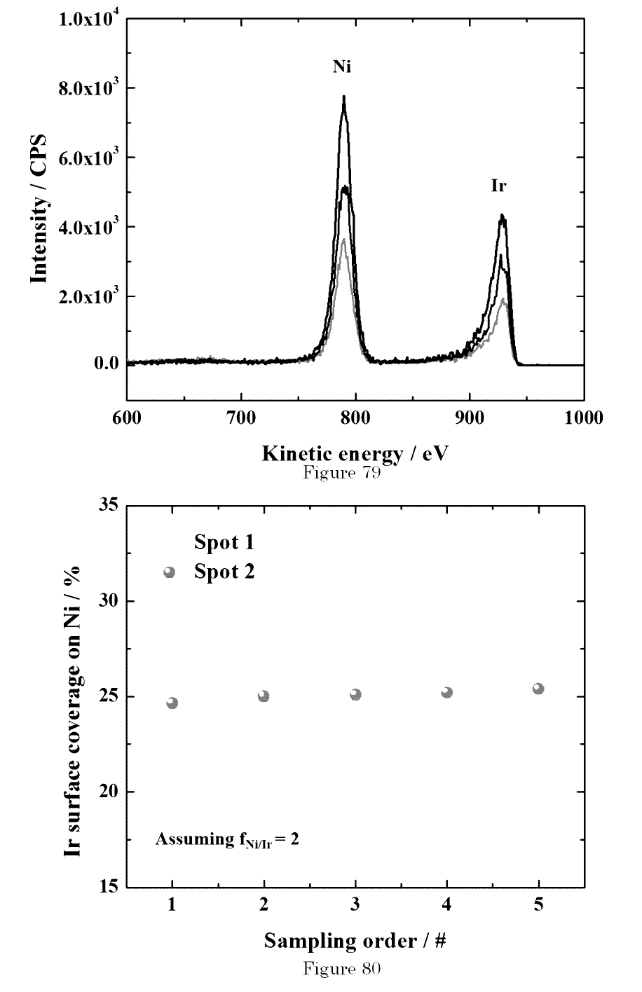

Although thick Ir films may be grown at potentials within the deposition wave (FIG. 67, FIG. 68, FIG. 69, FIG. 70), control of pulsed potential deposition provides self-terminating character of Ir deposition used to form thin films. Submonolayer thickness control was attained by stepping to potentials, E_{dep}, where deposition was quenched (FIG. 71). X-ray photoelectron spectroscopy (XPS) was used to evaluate the amount of Ir deposited on Au-seeded Si wafer fragments. The Ir 4f/Au 4f intensity ratio for one deposition pulse yields an effective Ir thickness of (0.085±0.028) nm based on a uniform overlayer model. A complete monolayer of Ir(111) corresponded to a thickness of 0.2216 nm thus one deposition pulse gives Ir clusters or islands that cover 25% to 50% of the surface. Alternatively, a fractional surface coverage scaled XPS model gives 0.42±0.11 for one layer thick Ir islands or 0.23±0.06 if the islands were two layers in thickness. The coverage was nearly independent of pH (1.5 to 6.5) and deposition time (1 to 100) s. Additional deposition occurred beyond 100 s (FIG. 74). The thickness was insensitive to the deposition potential provided it was below the reversible hydrogen potential (FIG. 75). For growth times below 100 s coverage is a weak function of the bulk Ir³⁺ concentration (FIG. 76). Deposition on other substrates, e.g., nickel, was examined (FIG. 77, FIG. 78, FIG. 79, FIG. 80).

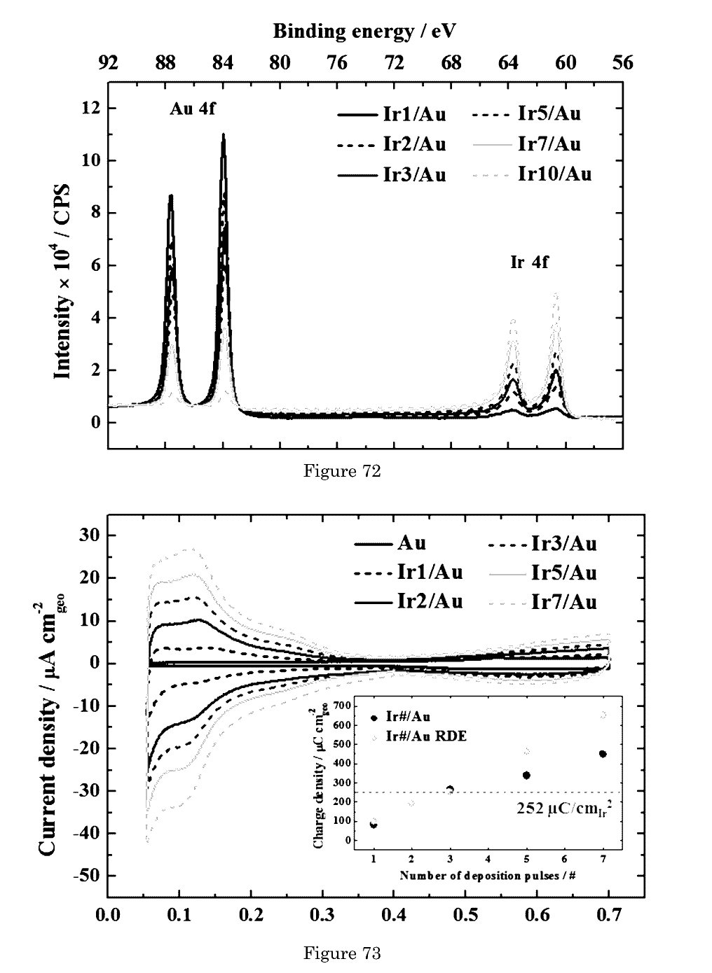

With reference to FIG. 71, FIG. 72, FIG. 73, spectroscopic and electrochemical characterization of thin Ir films grown on Au-seeded Si wafer by multi-pulse deposition in 3 mmol L⁻¹ K₃IrCl₆—0.5 mol L⁻¹ Na₂SO₄—x mol L⁻¹ H₂SO₄ electrolyte composition at 70° C. was performed in which data acquired include: (FIG. 71) XPS-derived Ir overlayer thickness was dependent on the number of pulses, independent of pH. Data points were averaged from at least 3 different regions of individual specimens, and the error bars represented standard deviation of the measurements; (FIG. 72) Au 4f and Ir 4f XPS spectra for Ir films grown using multi-pulse deposition from a pH 4.0 electrolyte composition; and (FIG. 73) cyclic voltammetry of Ir multilayers in Ar-purged 0.5 mol L⁻¹ H₂SO₄, wherein the inset shows calculated H_{UPD} charge density for Ir deposits grown on Au-seeded Si wafer and Au RDE. The charge density corresponded to one-half of the total integrated charge passed between (0.05 and 0.40) V_{RHE}.

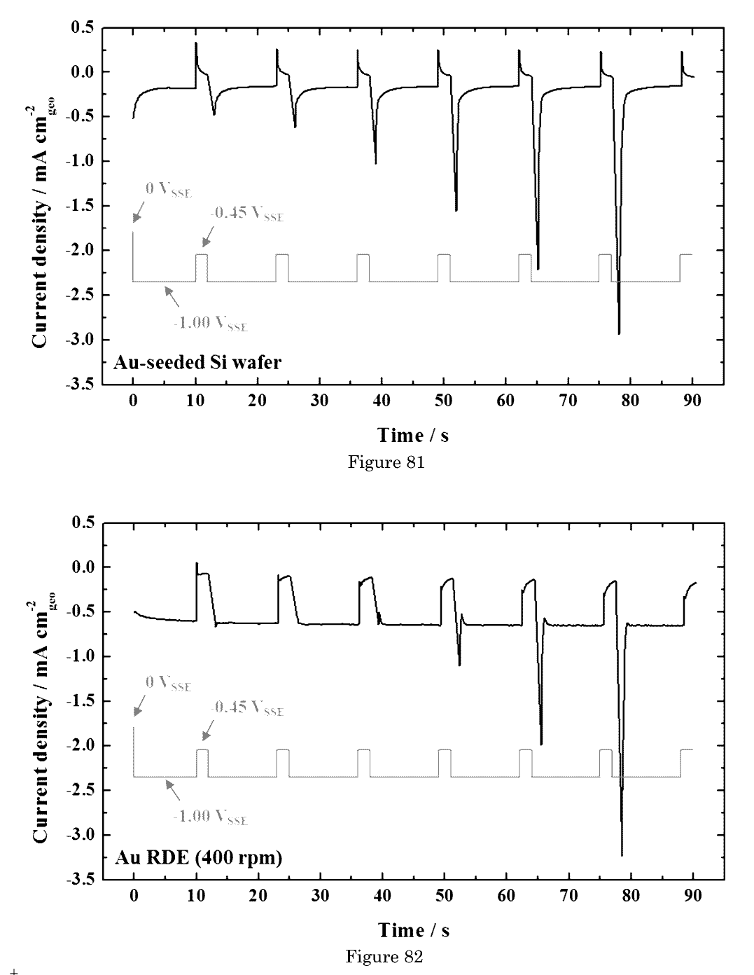

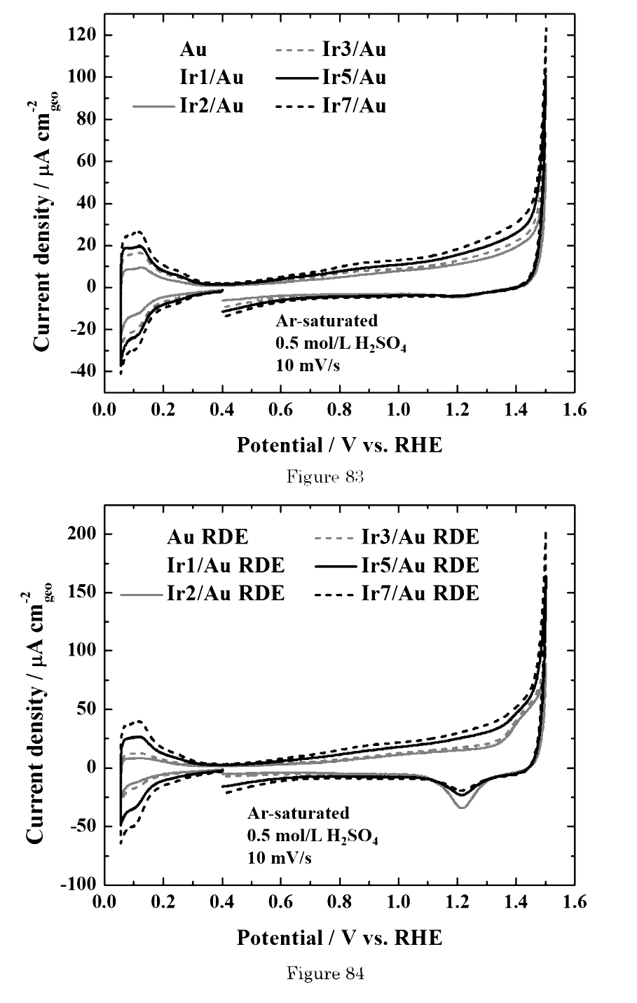

Thicker Ir films were deposited using a multi-pulse sequence where the freshly quenched surface is reactivated by stepping to −0.45 V_{SSE} to oxidize adsorbed H immediately prior to each deposition pulse. Representative potential pulse transient and current response for a pH 4.0 electrolyte composition are shown in FIG. 81 and FIG. 82. XPS revealed a monotonic increase in the Ir 4f/Au 4f ratio with the number of deposition pulses (FIG. 72), while the Ir 4f binding energy was congruent with its metallic form. Quantitative analysis using a simple Ir overlayer model yielded a linear increase in thickness from (0.343±0.012) nm (2 pulses deposition) to (3.143±0.083) nm (10 pulses deposition) (FIG. 71). Lateral variations in thickness increased with the number of deposition pulses as reflected by the error bars.

Several surface limited reactions were used to probe the Ir coverage on Au. H_{UPD} waves for the thin Ir films were stable to voltammetric cycling in 0.5 mol L⁻¹ H₂SO₄ provided the potential was kept at or below 0.7 V_{RHE} (FIG. 73). The H_{UPD} charge density increased monotonically with the number of deposition pulses. However, beyond the third Ir deposition pulse the electroactive area derived from the H_{UPD} charge was larger than that of the Au thin film substrates (FIG. 73, inset). Without wishing to be bound by theory, it was believed that the difference was due to substrate orientation effects on Ir nucleation and growth, and thereby roughness evolution or to variations in the electrochemical time constant. Complete H occupancy of atop or threefold hollow sites on Ir(111) corresponded to 252 μC cm_{Ir}⁻². For one deposition pulse films this corresponded to a fractional Ir surface coverage of ≈0.32 (i.e., 0.32 cm_{Ir}² cm_{geo}⁻²). After 3 deposition pulses the H_{UPD} coverage approached a monolayer. In contrast, XPS showed a monolayer was approached after 2 deposition pulses. Furthermore, the H_{UPD} waves were wider than the peaks on Ir(111) single crystals that indicated that the electrodeposited Ir was not in the form of large, well-defined 2-D Ir(111) islands but rather had more in common with Ir(110). The further increase in H_{UPD} charge with subsequent deposition cycles reflected increasing surface roughness.

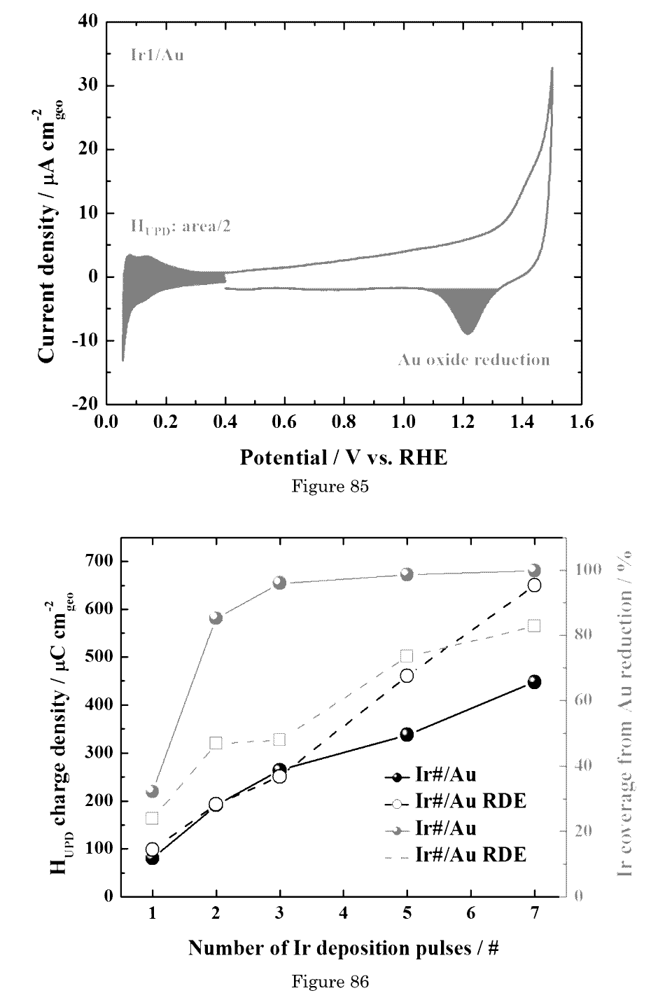

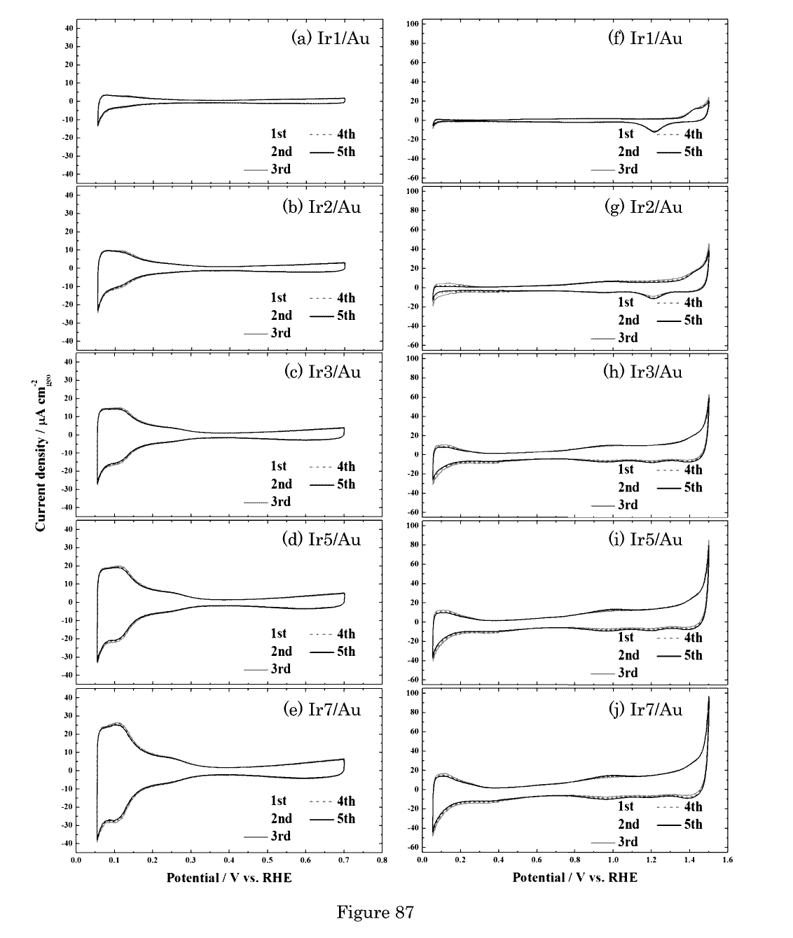

The continuity of the Ir overlayers was examined voltammetrically by probing for exposed Au sites via oxide formation and reduction. For Ir deposition on Au thin films, less than 10% of the Au surface remained exposed after 2 deposition cycles (FIG. 83, FIG. 84) while 7 deposition pulses provided similar coverage on the Au RDE (FIG. 85, FIG. 86). Rearrangement of the surface due to Au segregation and irreversible Ir oxidation occurred at potentials >0.7 V_{RHE} (FIG. 87).

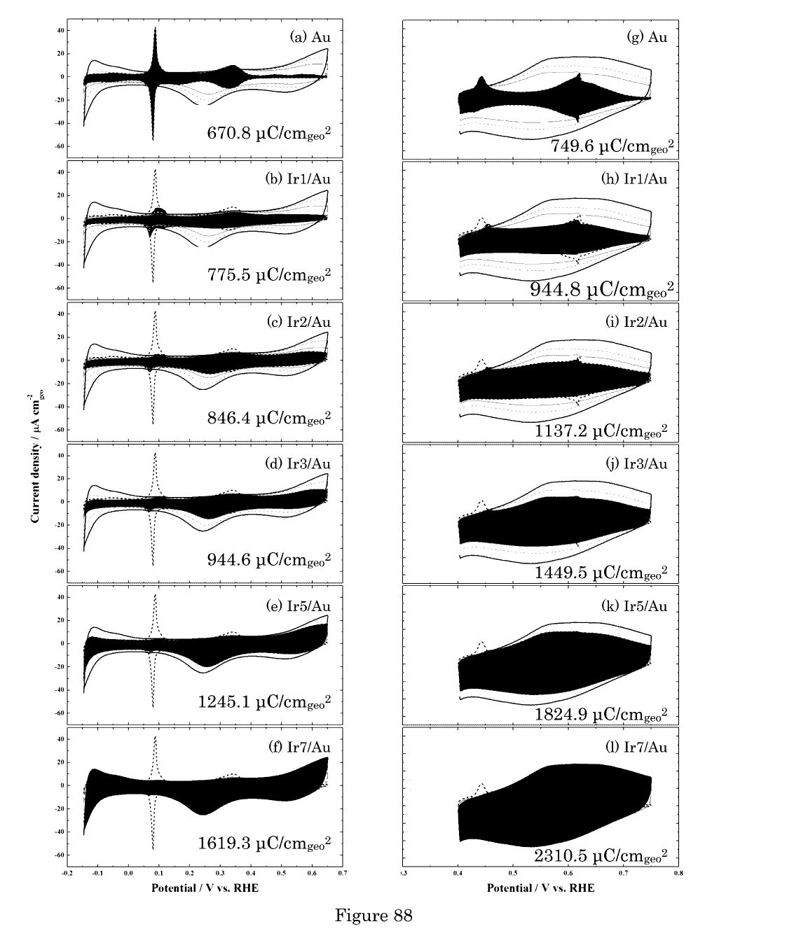

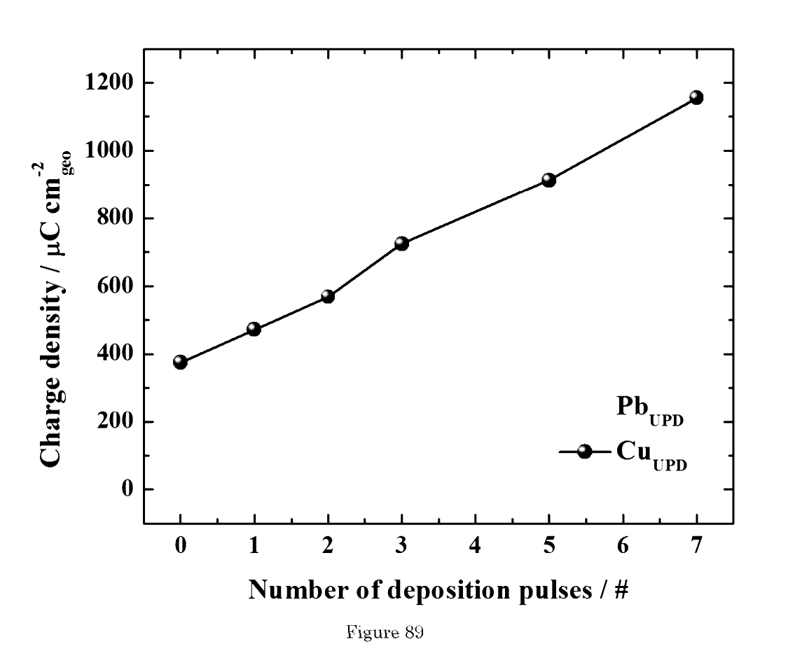

The Ir overlayers on Au were also examined using Pb_{UPD} and Cu_{UPD} (FIG. 88). Ir broadened the sharp UPD peaks associated with respective 2-D phase transitions on 111 textured Au while Pb_{UPD} blocked the H_{UPD} process on Ir. Following multiple Ir deposition pulses, a symmetry of the Pb_{UPD} and Cu_{UPD} waves were weakened. Nevertheless, the Pb_{UPD} and Cu_{UPD} charge increased with the number of Ir deposition pulses analogous to H_{UPD} (FIG. 89).

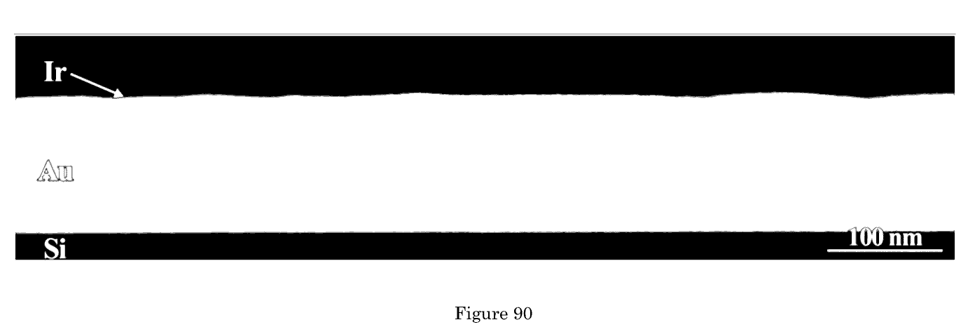

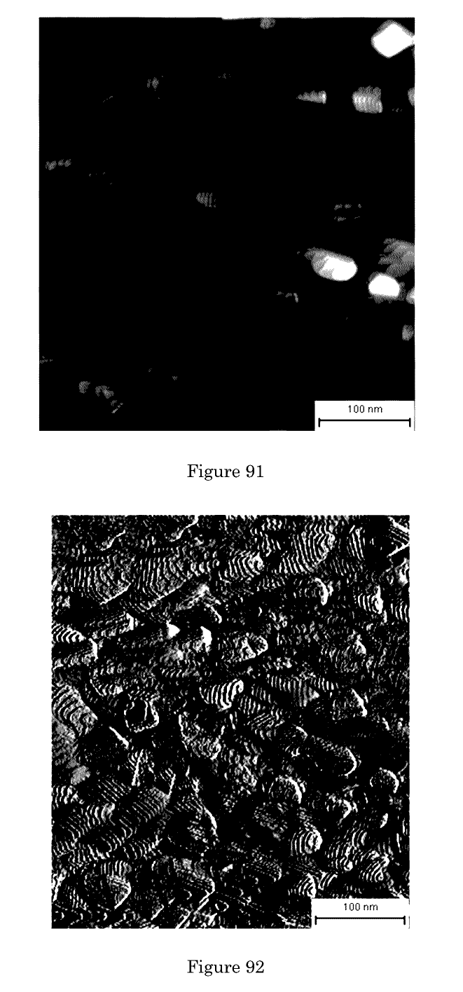

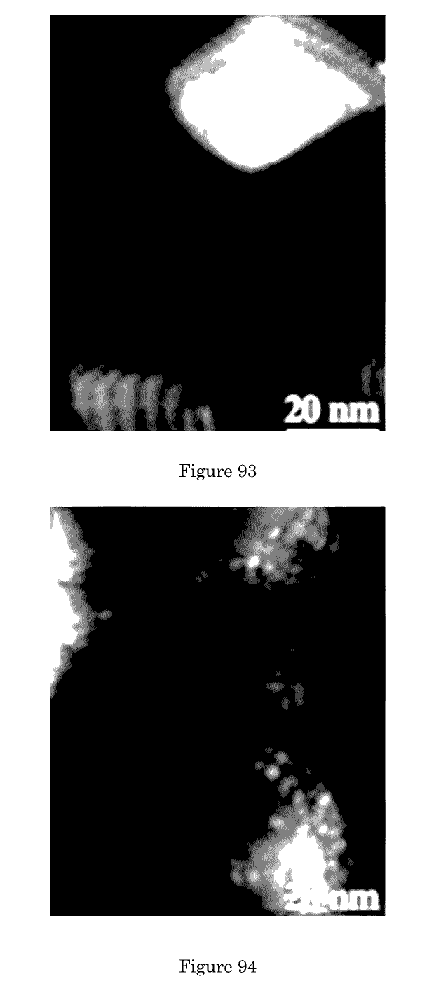

The structure and morphology of the as-deposited films were examined by high-angle annular dark-field scanning transmission electron microscopy (HAADF-STEM) and scanning tunneling microscope (STM). The grain size of the Au substrate was similar to the 118 nm film thickness (FIG. 90). STM revealed the distribution and arrangement of steps (FIG. 91, FIG. 92) congruent with the grain size and 111 texture (with possible 180° rotation) of the Au films. The frizzy steps indicated significant step motion accompanies imaging (FIG. 93). Following 2 deposition pulses, Ir islands ≈(2 to 3) nm in diameter are evident on the Au surface (FIG. 94). The Ir islands were preferentially associated with highly stepped regions on the Au substrate although significant step motion was evident on exposed Au regions.

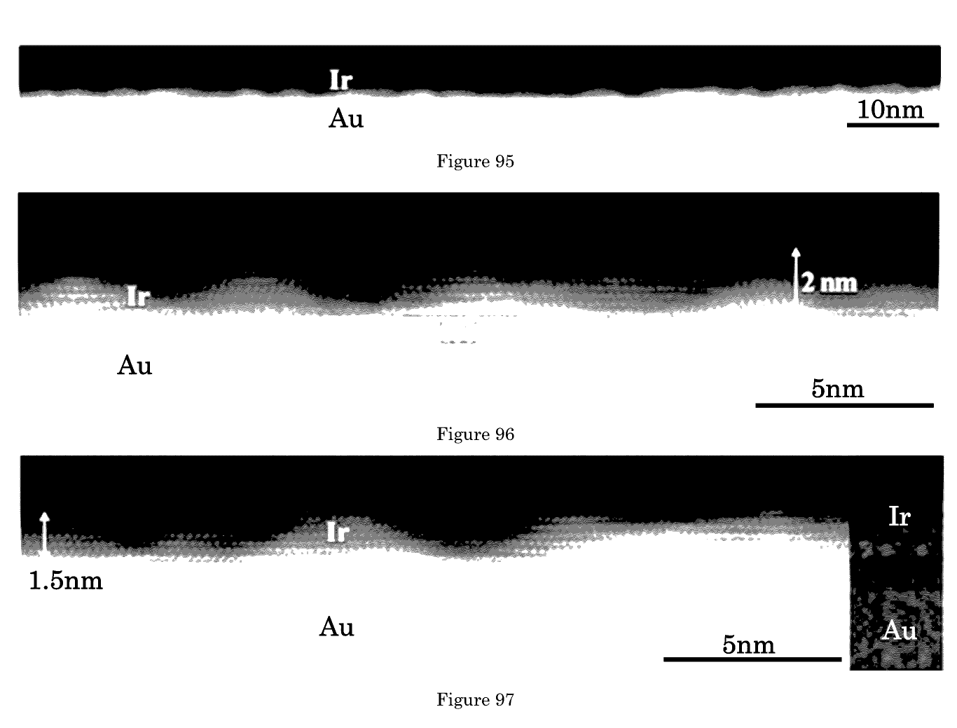

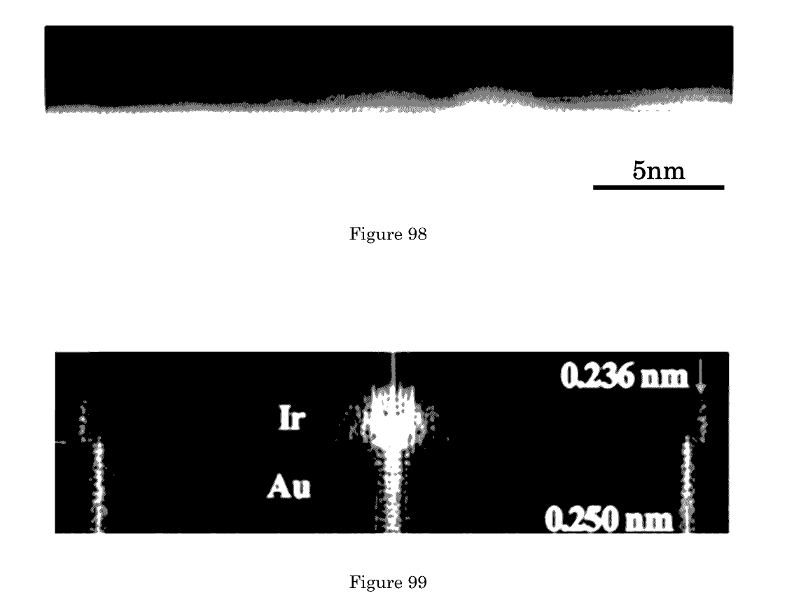

Data acquired from microscopic characterization of Ir grown on Au-seeded Si wafer by multi-pulse deposition in 3 mmol L⁻¹ K₃IrCl₆—0.5 mol L⁻¹ Na₂SO₄—x mol L⁻¹ H₂SO₄ pH 4.0 electrolyte composition at 70° C. are shown in FIG. 93, FIG. 94, FIG. 95, FIG. 96, FIG. 97, FIG. 98, and FIG. 99 as follows: (FIG. 93) STM image of 111 textured Au substrate; (FIG. 94) STM image following 2 pulses Ir deposition on Au showing a distribution of (2 to 3) nm diameter Ir islands; (FIG. 95, FIG. 96, FIG. 97) HAADF-STEM (110 zone axis) cross section image of a 7 pulses Ir film grown on Au at different magnifications; examination revealed semi-coherent Ir pyramids as well as a population of islands grew as twins on the Au(111) substrate; (FIG. 98) STEM-XEDS compositional mapping of 7 pulses Ir film (green) on Au (red); and (FIG. 98 and FIG. 99) a HAADF-STEM image and its horizontal 1-d FFT along the [112] showing a change in the spacing between [1-10] atomic columns reflecting the semi-coherent nature of the interface.

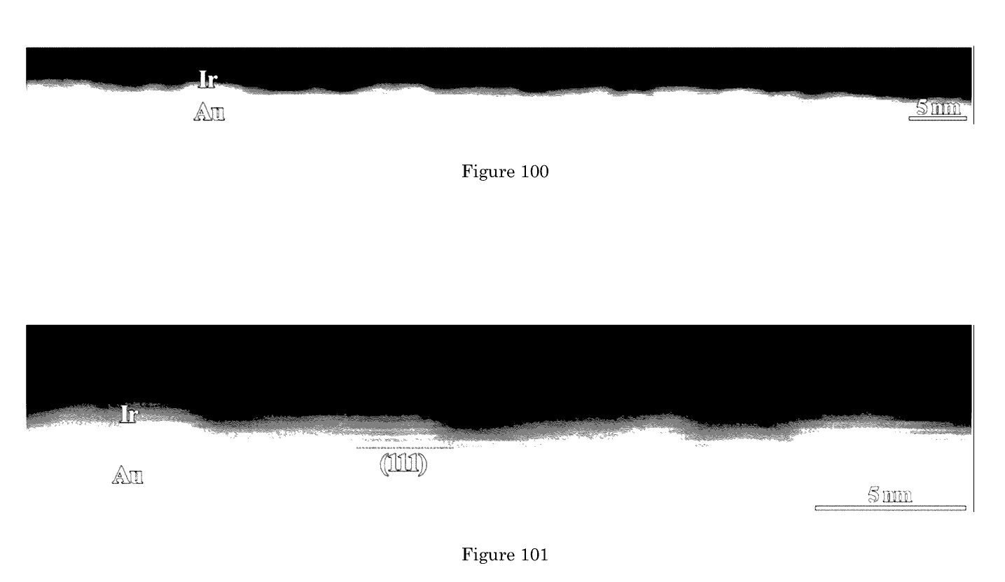

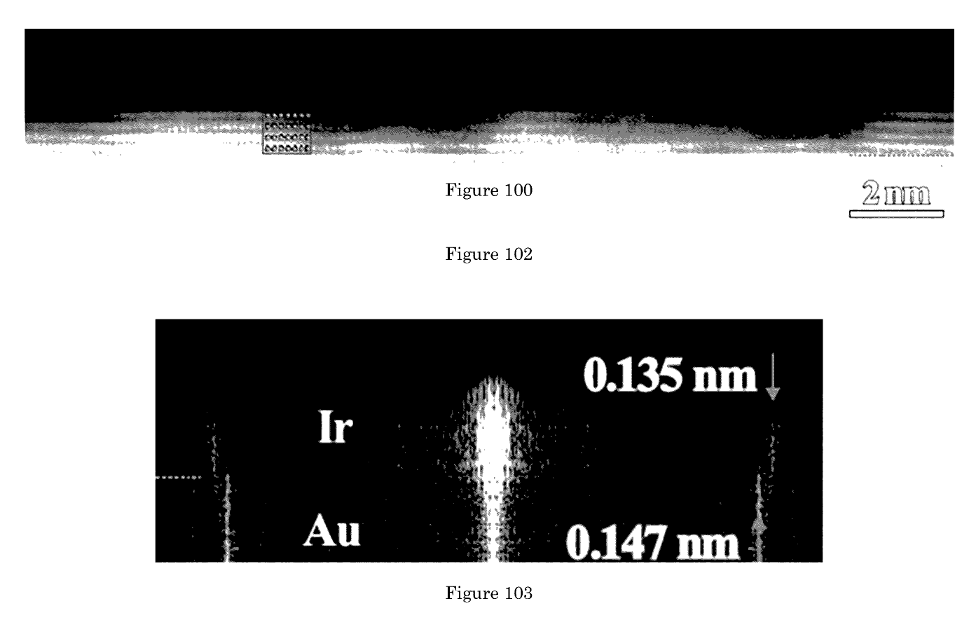

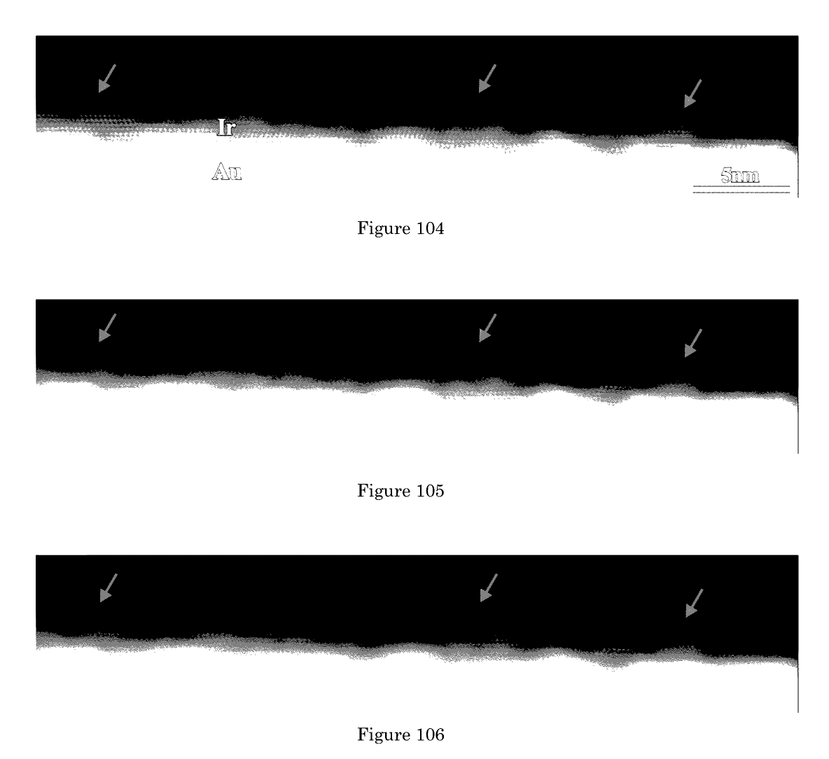

A thicker 7 pulse Ir film was examined by STEM. Atomically-resolved HAADF-STEM imaging revealed a distribution of dense pyramidal Ir islands on the exposed Au(111) surface viewed along the 1-10 (FIG. 95) and 1-12 zone axis (FIG. 100, FIG. 101, FIG. 102, FIG. 103). The islands ranged from 1.5 nm to 2.0 nm in height consistent with the (1.7±0.1) nm thickness determined by XPS using a uniform overlayer model. Application of a Volmer-Weber model to the XPS data provided ≈0.12 island per nm², assuming uniform hemispherical clusters with a radius equivalent to 8 Ir layers, 1.77 nm. The lateral island dimensions of the 7 pulse Ir films were congruent with the STM images of Ir islands grown using 2 pulses. Lattice alignment between several Ir pyramids and the Au substrate were evident while interface stacking faults yielded a significant population of 180° rotated pyramids (FIG. 96, FIG. 97). The non-uniform scattering density within a single image along with variation in lattice-resolved imaging of different islands as the focus conditions changed reflected the non-uniform Ir islands distribution on the Au(111) substrate (FIG. 104, FIG. 105, FIG. 106). The roughness of the Ir layer varied between different regions across the specimen due to variation in substrate step density and accommodation of the lattice misfit. A 1-dimensional FFT in the [112] of the (111) Au/Ir interface showed that the interface was atomically sharp (FIG. 98 and FIG. 99) with a discrete change in the spacing of the [1-10] atomic columns from 0.236 nm for the Ir islands to 0.250 nm for the Au substrate. Despite the 6.1% misfit between Ir and Au the islands were minimally strained due to capillarity and step line tension. STEM-XEDS (energy-dispersive X-ray spectroscopy) compositional mapping was congruent with a 2 nm Ir overlayer (FIG. 97, inset).

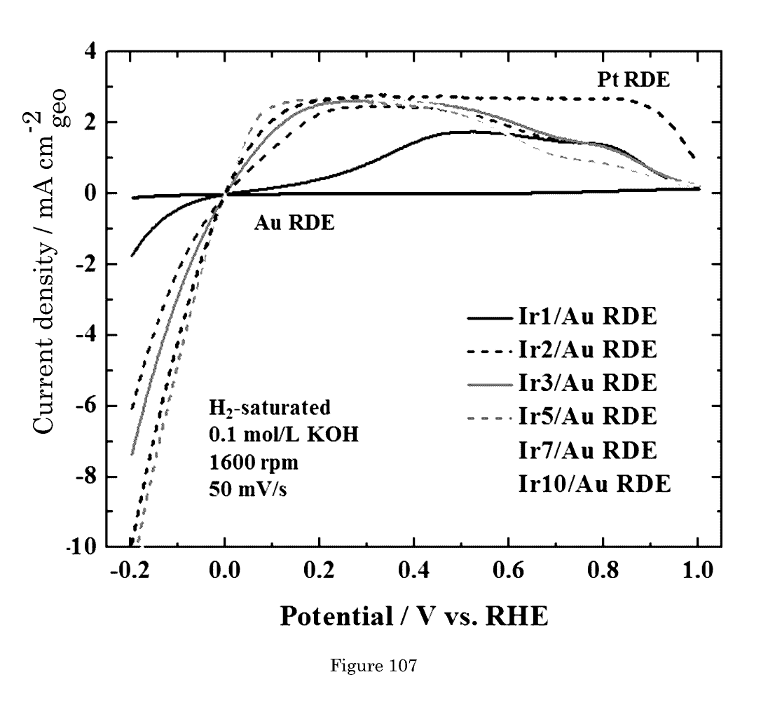

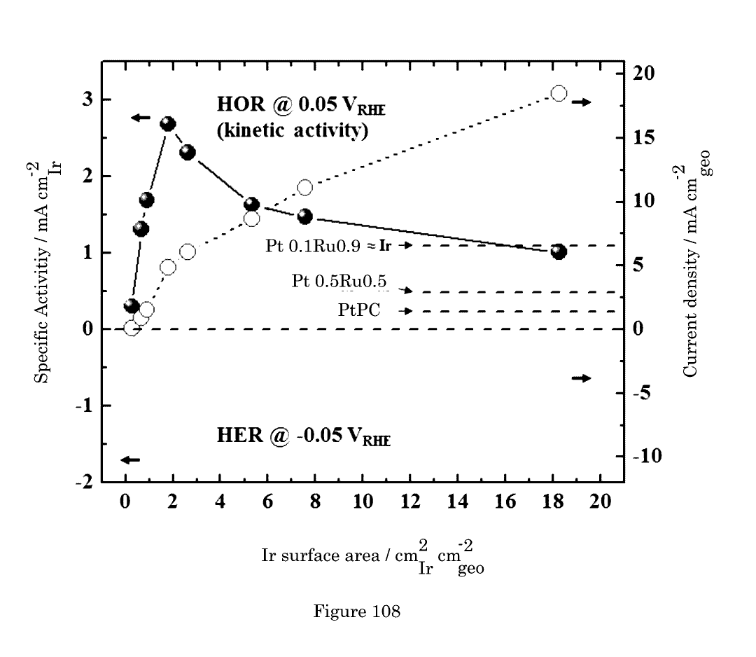

Hydrogen production and oxidation in alkali solutions (HER/HOR) was examined as a function of the number of Ir deposition pulses. The mechanically-polished polycrystalline Pt RDE (FIG. 107) was catalytic, but the Au was inactive. Ir deposition on the Au RDE resulted in a monotonic increase in the HOR/HER kinetics with the number of deposition pulses that correlated with the increase in H_{UPD} surface area (FIG. 108). For Ir films deposited with 3 or more deposition pulses, the HOR/HER current exceeded that of the Pt RDE. The HOR specific activity reached a maximum for Ir films grown using 5 pulses while the maximum specific activity for HER was observed after 3 deposition pulses. The peak in specific activity reflected interactions between Ir, Au, and subsurface H, that favorably affected the HOR/HER.

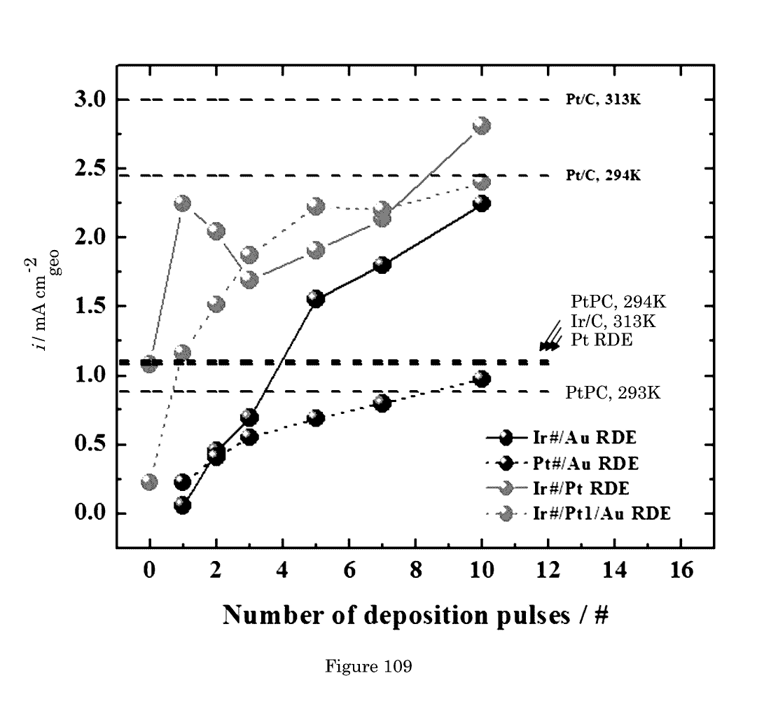

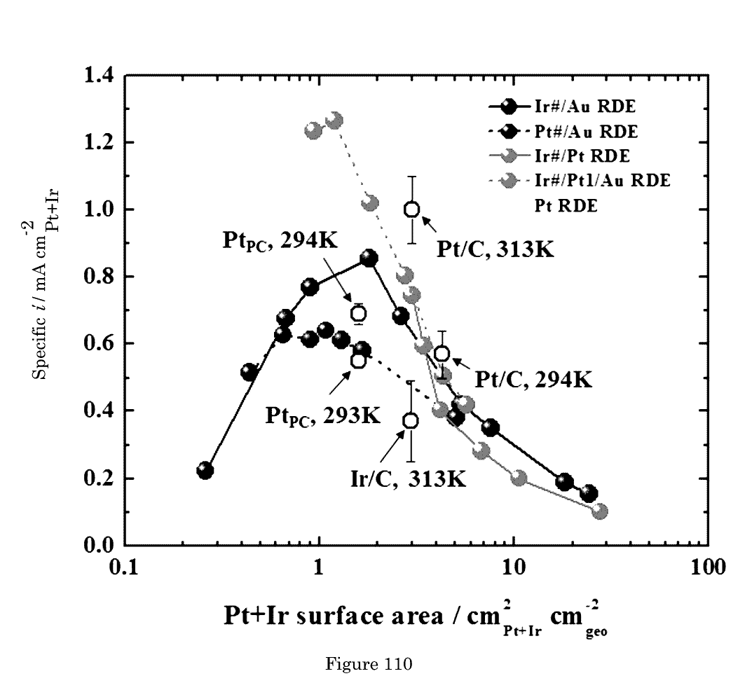

Data acquired from alkaline HER/HOR catalysis by self-terminated Ir or Pt layers grown on various substrates is shown as follows. (FIG. 107) Linear sweep voltammetry (notiR-corrected) for thin Ir films as function of the number of deposition pulses; (FIG. 108) HER current density (blue) and HOR current density (red) at 50 mV overpotential and normalized to the geometric (open) and Hupd surface area (solid); the dashed horizontal lines corresponded to literature data; (FIG. 109, FIG. 110) exchange current density (calculated from iR-corrected interface charge transfer resistance) for various Ir and/or Pt overlayers on Au or Pt RDE substrates; the exchange current was normalized by (FIG. 109) geometric and (FIG. 110) H_{UPD} surface area.

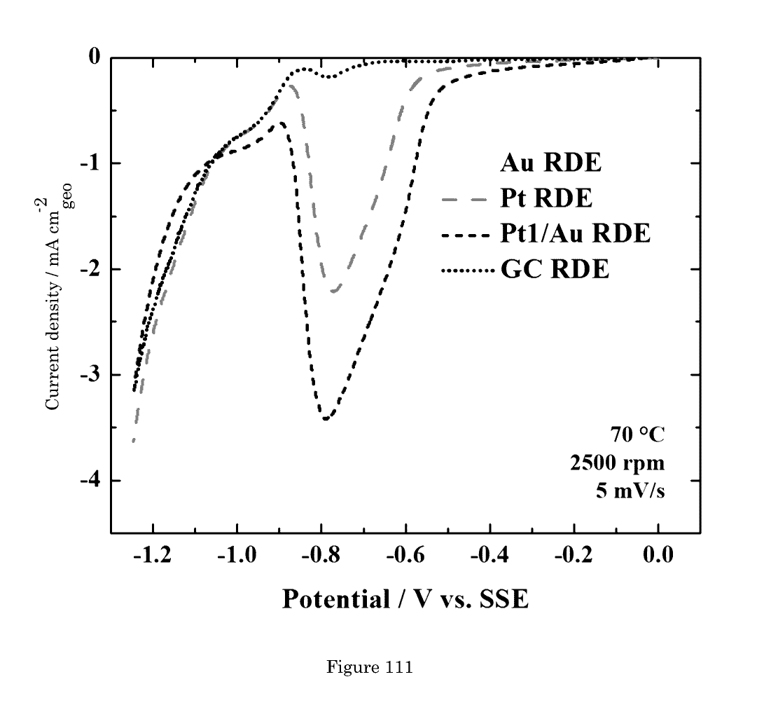

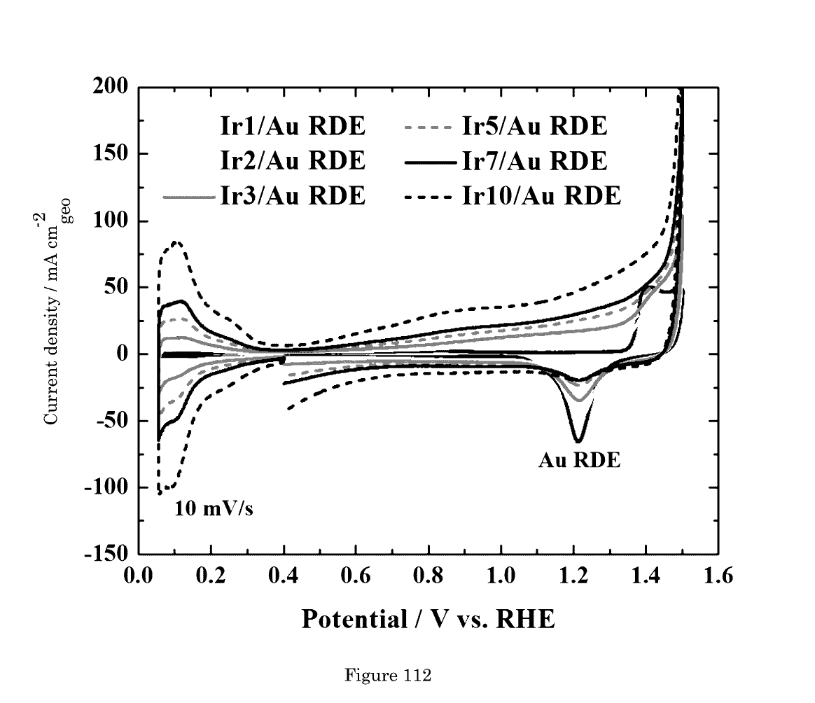

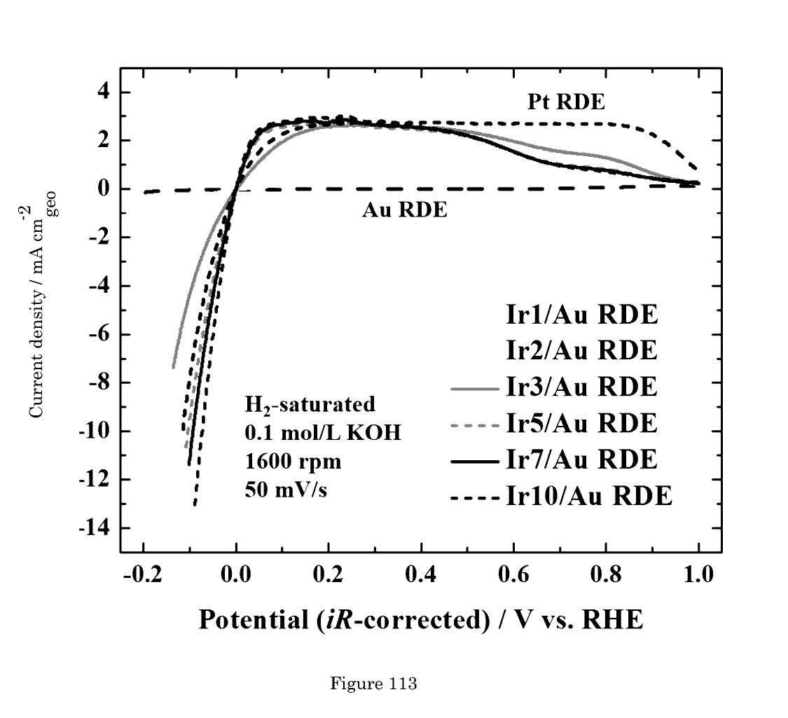

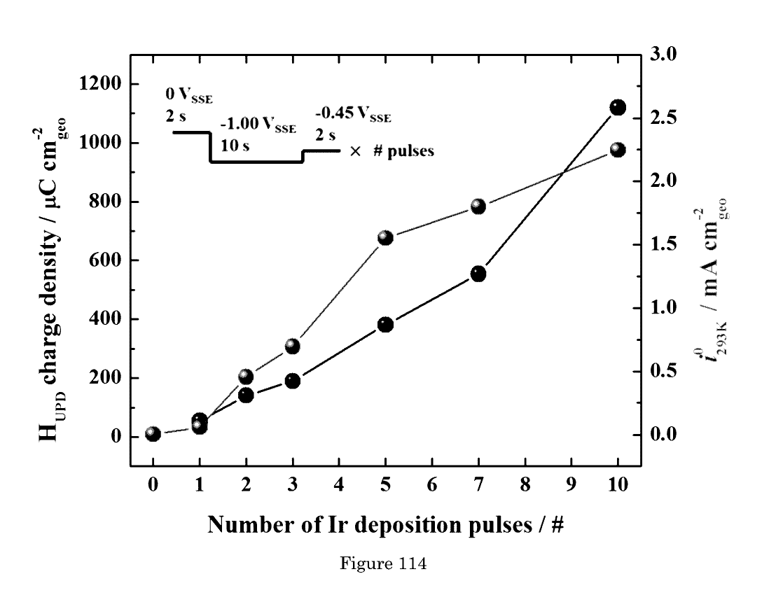

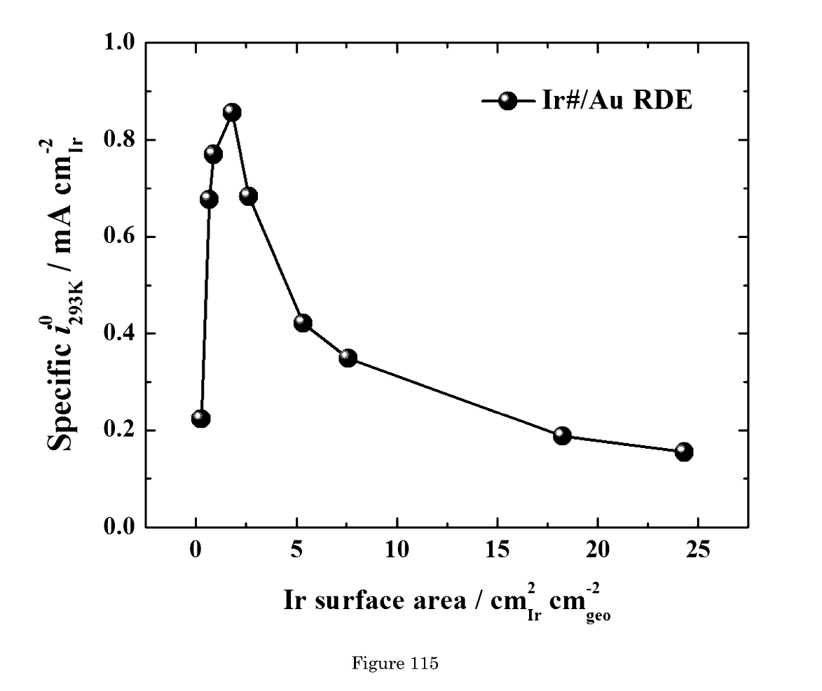

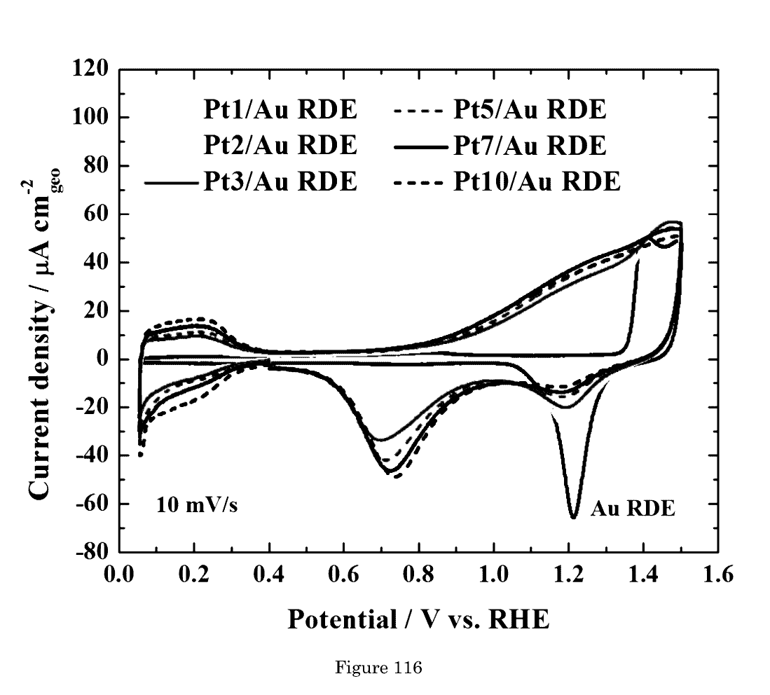

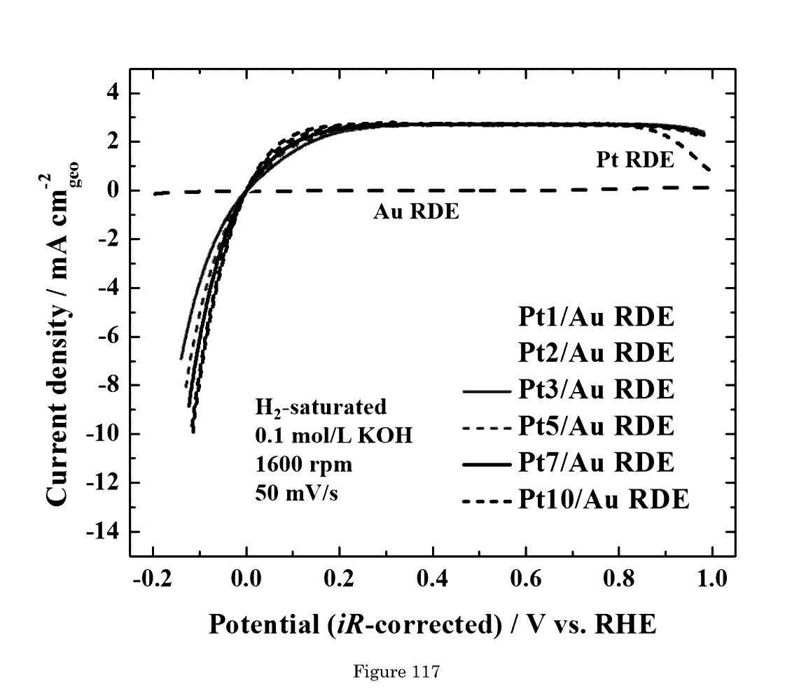

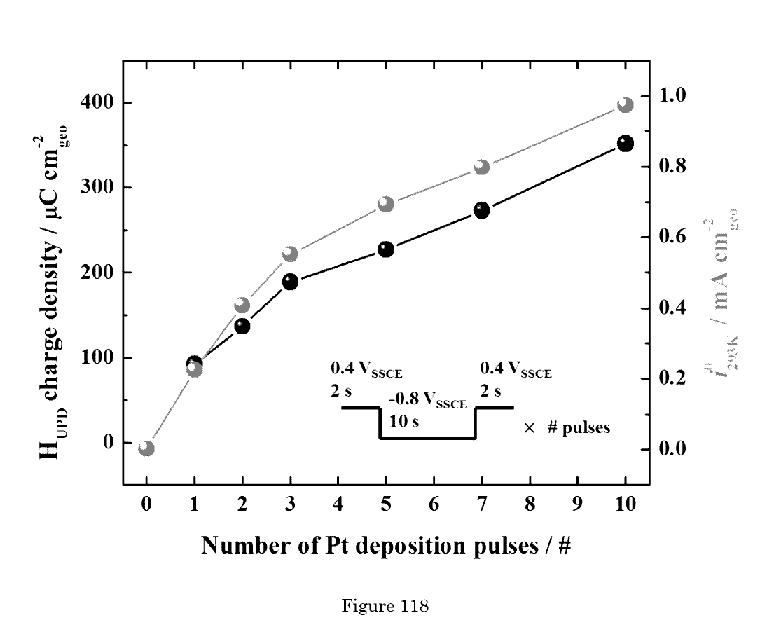

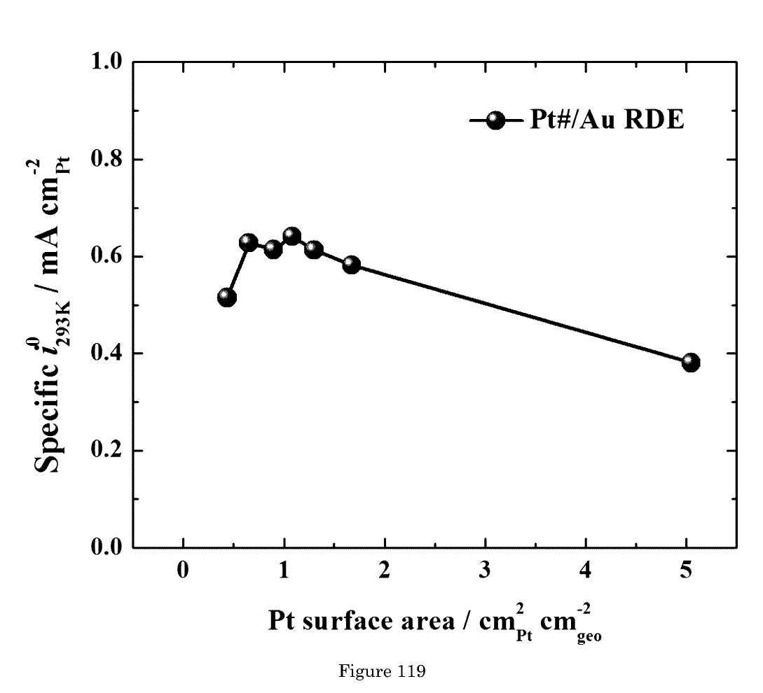

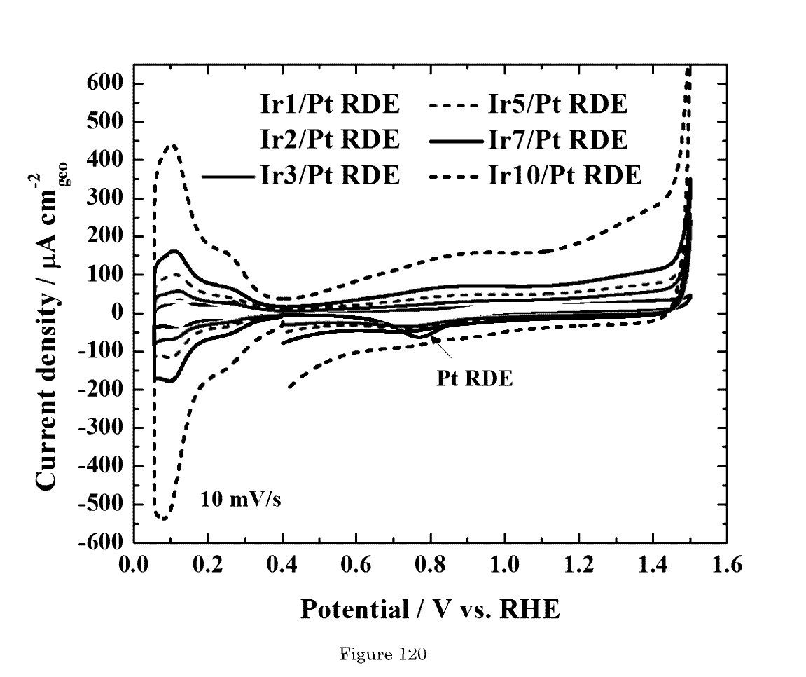

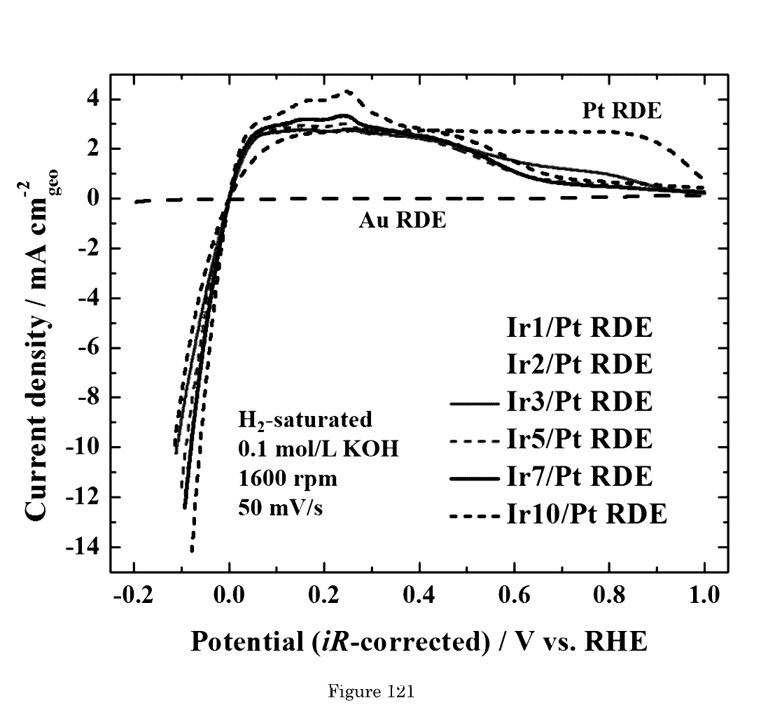

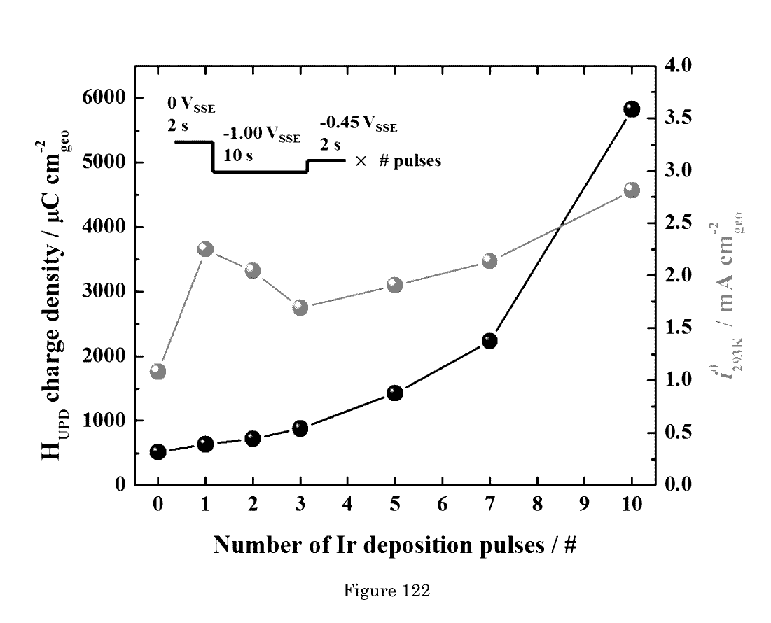

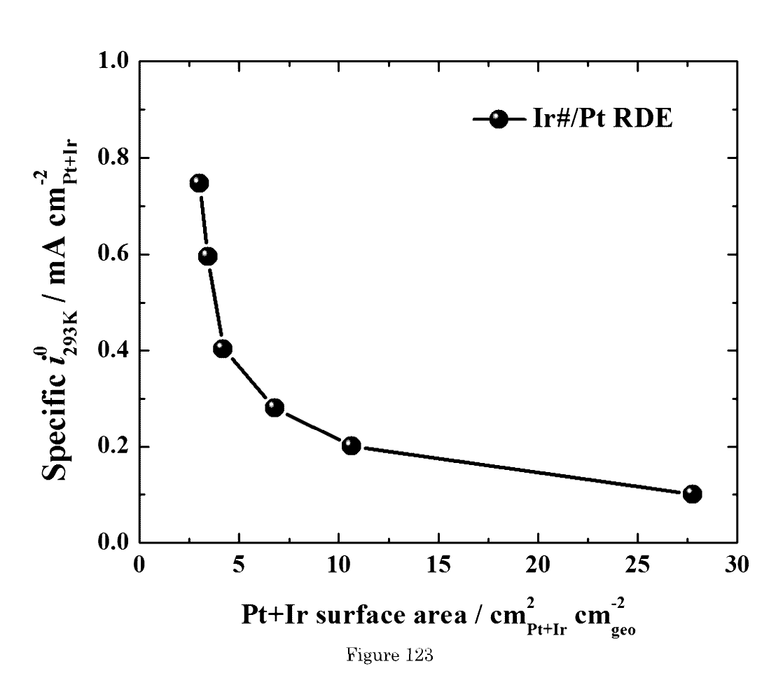

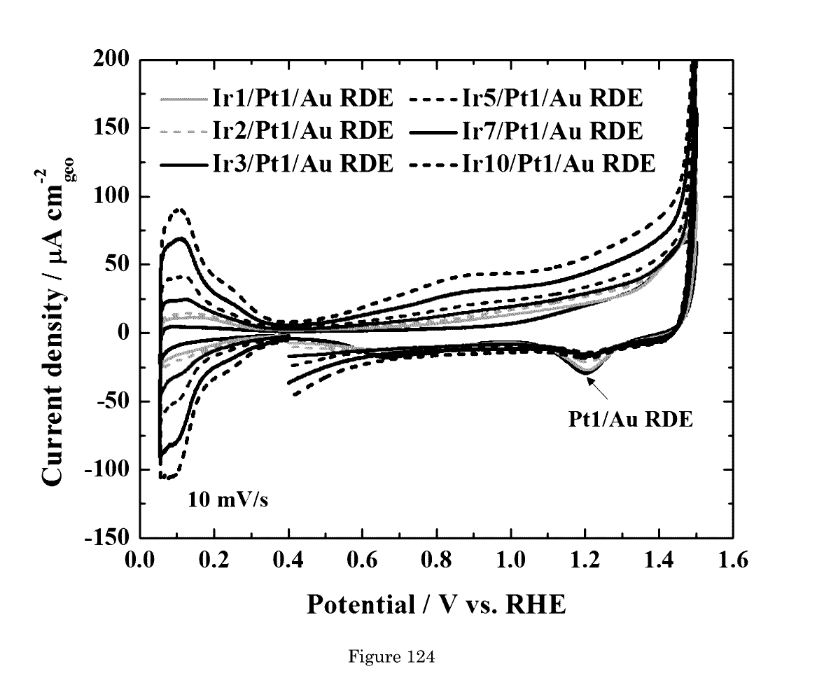

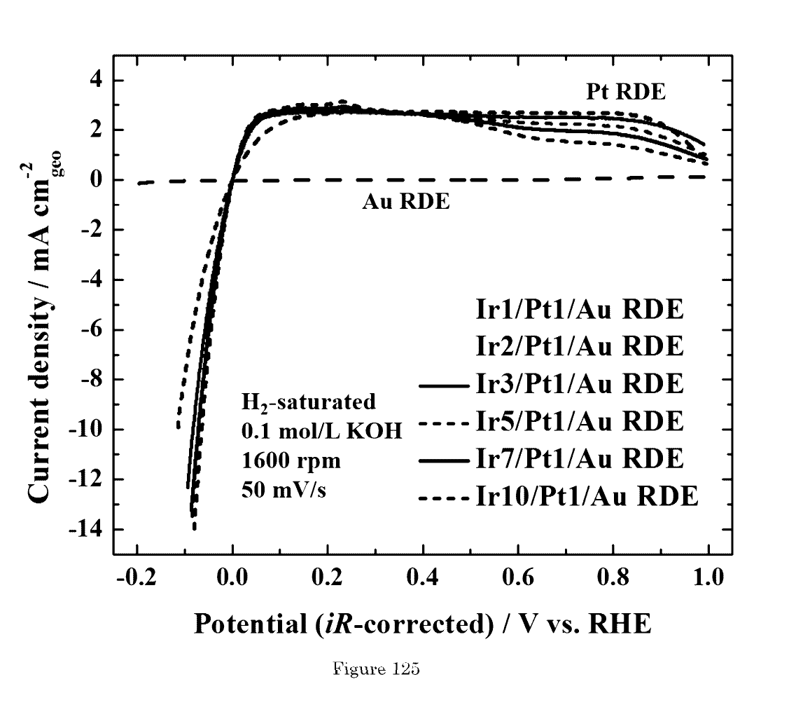

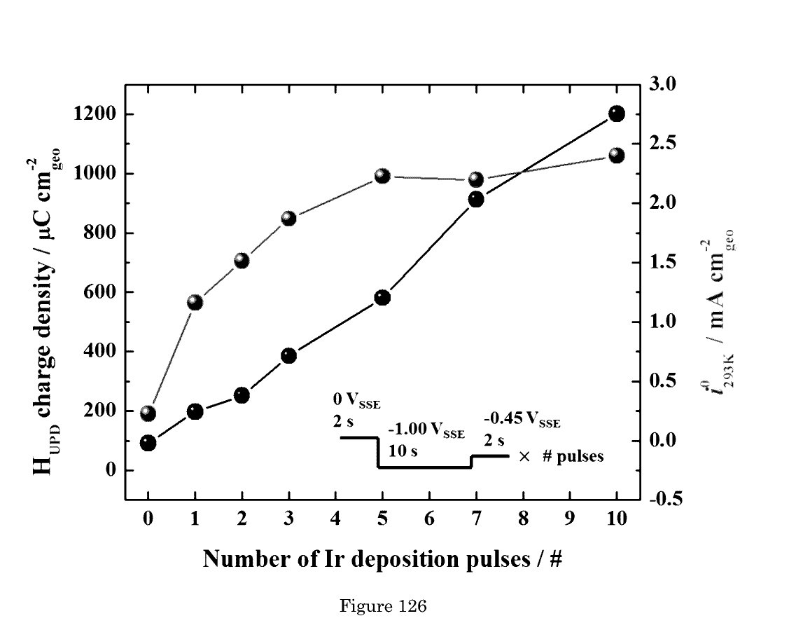

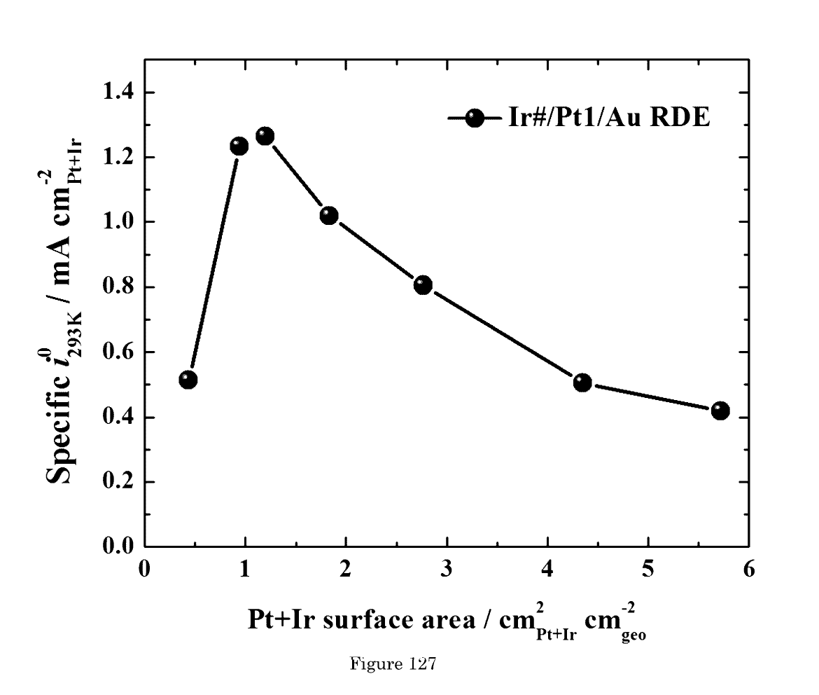

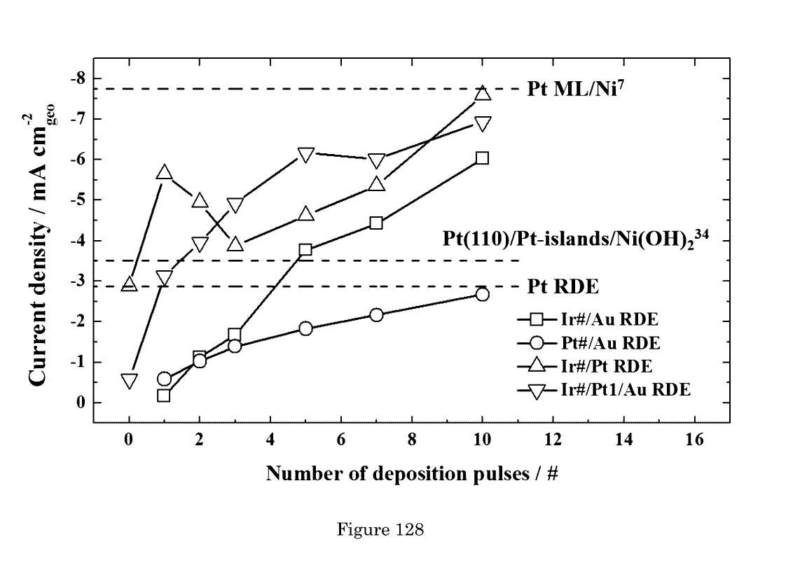

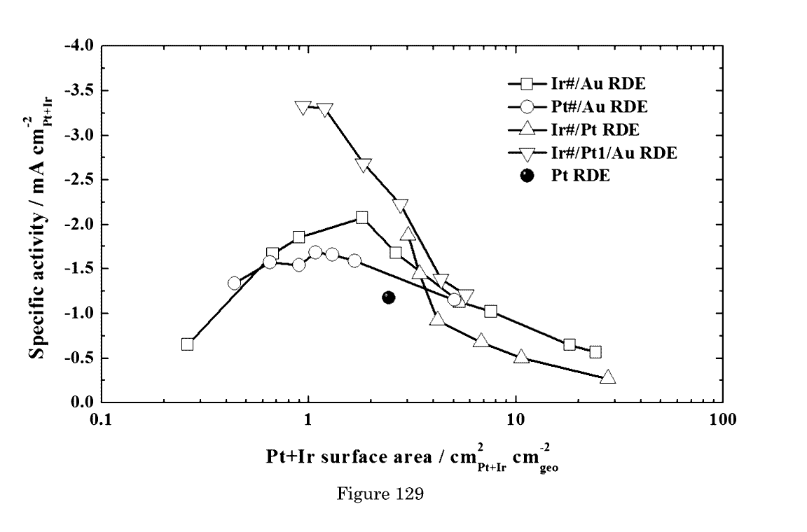

The HOR/HER on self-terminated Ir on Pt RDE, self-terminated Pt on Au RDE and Ir/Pt on Au RDE were examined (FIG. 111). The exchange current density normalized to the geometric surface area, H_{UPD} charge and real surface area is shown in FIG. 109, FIG. 110, FIG. 112, FIG. 113, FIG. 114, FIG. 115, FIG. 116, FIG. 117, FIG. 118, FIG. 119, FIG. 120, FIG. 121, FIG. 122, FIG. 123, FIG. 124, FIG. 125, FIG. 126, and FIG. 127. The iR-corrected HER activity is shown in FIG. 128, FIG. 129. The combination of self-terminated deposition of Ir and Pt provided enhanced HOR/HER performance.

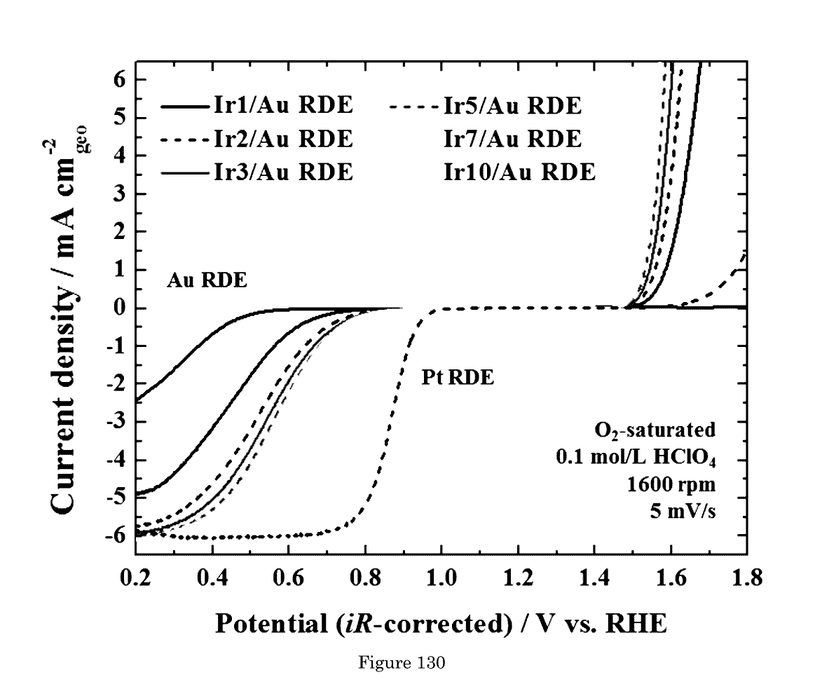

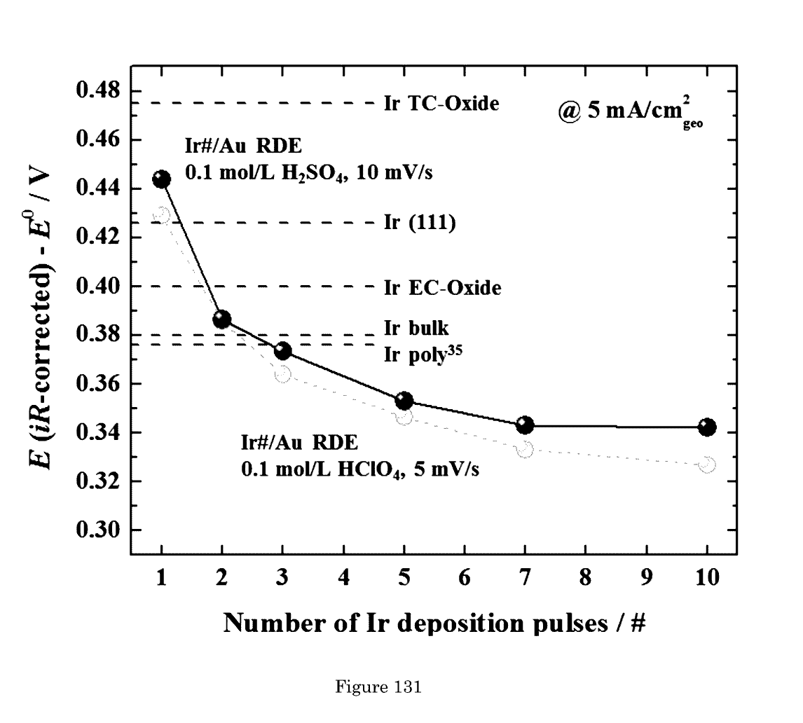

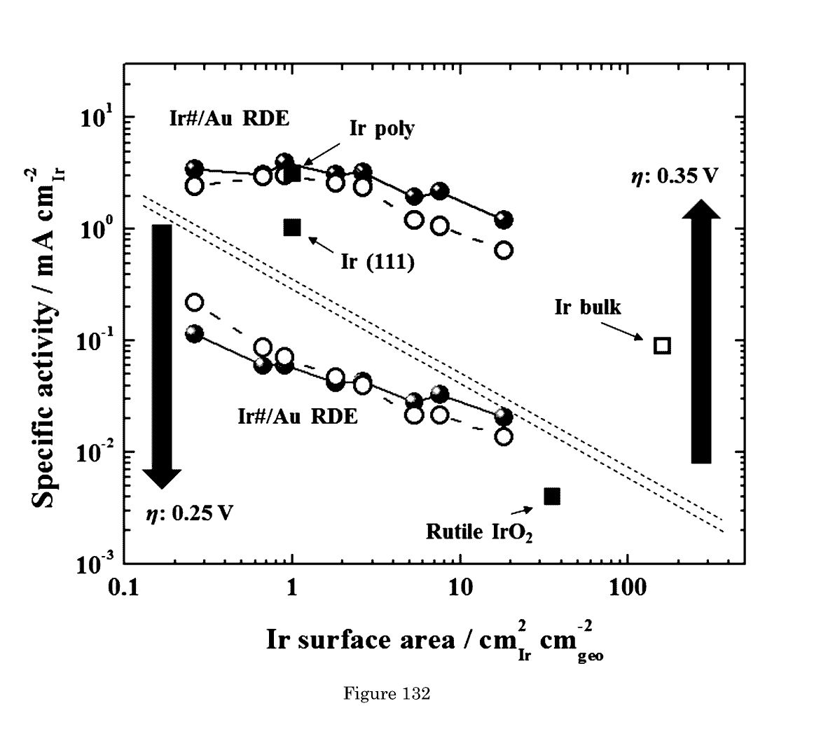

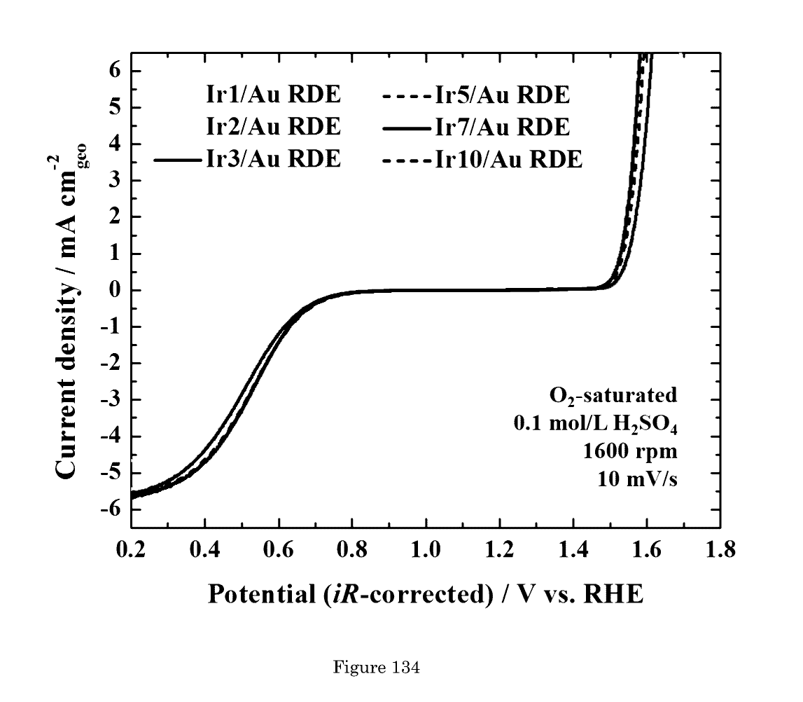

Water splitting through the oxygen evolution reaction (OER) on thin Ir films was examined in O₂-saturated 0.1 mol L⁻¹ HClO₄ (FIG. 130). Compared to Pt, water splitting was catalyzed on the thin Ir films with the depolarization increasing with the number of deposition pulse (FIG. 131, FIG. 134). For the 3 deposition pulse Ir film, where the H_{UPD} normalized Ir area was roughly equivalent to the projected electrode area, the overpotential at 5 mA cm⁻² was lower than freshly annealed bulk polycrystalline Ir electrodes (FIG. 131). Further depolarization accompanied the increase in surface roughness associated with the thicker films. Evaluation of the specific OER activity at the thermoneutral potential, 1.48 V, revealed an order of magnitude greater value than for IrO₂ nanoparticles (FIG. 132).

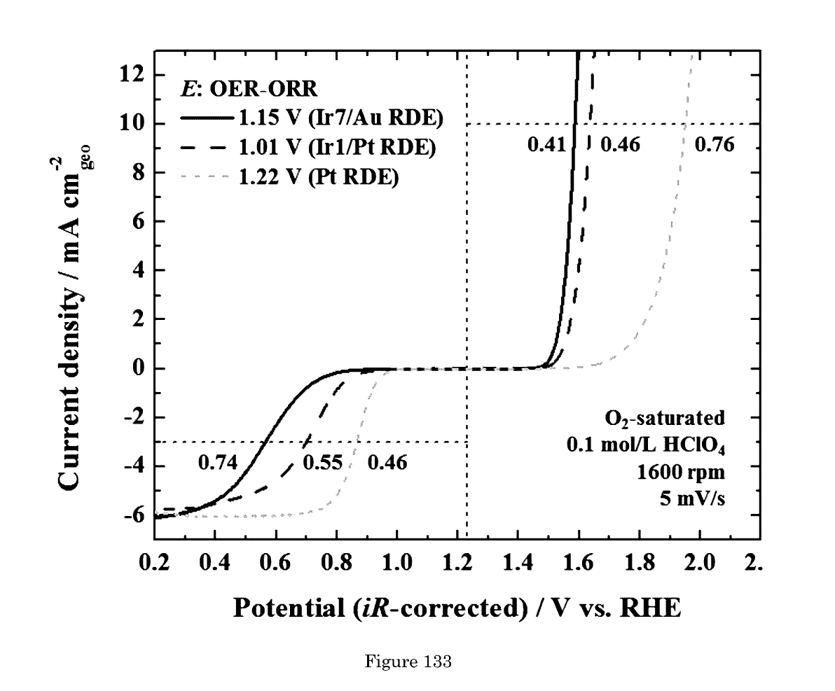

Data acquired from acid OER/ORR catalysis by self-terminated Ir or Pt layers grown on various substrates is shown as follows: (FIG. 130) ORR/OER polarization curves (iR-corrected) for thin Ir films as function of the number of deposition pulses; (FIG. 131) OER overpotential at 5 mA cm_{geo}⁻² for Ir films on Au RDE in 0.1 mol L⁻¹ HClO₄ (red) and 0.1 mol L⁻¹ H₂SO₄ (blue) where the dashed horizontal lines corresponded to literature data; (FIG. 132) OER specific activity of Ir films on Au RDE at fixed overpotentials, 0.25 V (red) and 0.35 V (blue) in 0.1 mol L⁻¹ HClO₄ (solid) and 0.1 mol L⁻¹H₂SO₄ (open) as function of the number of deposition pulses #; and (FIG. 133) bifunctional ORR/OER catalysis by Ir7/Au RDE, Ir1/Pt RDE, and Pt RDE.

Oxygen reduction reaction (ORR) on Ir films can provide development of unitized regenerative fuel cells having improved bifunctional oxygen electrodes (OER/ORR). The combination of self-terminated electrodeposition of Ir with Pt yielded an improved electrode for regenerative operation (FIG. 133).

Rapid self-terminating electrodeposition reactions provided an engineered catalytic bimetallic surfaces and minimized use of expensive materials. The Ir thin films were catalysts that were directly accessible to the electrolyte composition and provided enhanced signal to noise ratio.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

Reference throughout this specification to “one embodiment,” “particular embodiment,” “certain embodiment,” “an embodiment,” or the like means that a particular feature, structure, or characteristic described in connection with the embodiment is included in at least one embodiment. Thus, appearances of these phrases (e.g., “in one embodiment” or “in an embodiment”) throughout this specification are not necessarily all referring to the same embodiment, but may. Furthermore, particular features, structures, or characteristics may be combined in any suitable manner, as would be apparent to one of ordinary skill in the art from this disclosure, in one or more embodiments.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix “(s)” as used herein is intended to include both the singular and the plural of the term that it modifies, thereby including at least one of that term (e.g., the colorant(s) includes at least one colorants). “Optional” or “optionally” means that the subsequently described event or circumstance can or cannot occur, and that the description includes instances where the event occurs and instances where it does not. As used herein, “combination” is inclusive of blends, mixtures, alloys, reaction products, and the like.

As used herein, “a combination thereof” refers to a combination comprising at least one of the named constituents, components, compounds, or elements, optionally together with one or more of the same class of constituents, components, compounds, or elements.

All references are incorporated herein by reference.

The use of the terms “a” and “an” and “the” and similar referents in the context of describing the invention (especially in the context of the following claims) are to be construed to cover both the singular and the plural, unless otherwise indicated herein or clearly contradicted by context. “Or” means “and/or.” Further, the conjunction “or” is used to link objects of a list or alternatives and is not disjunctive; rather the elements can be used separately or can be combined together under appropriate circumstances. It should further be noted that the terms “first,” “second,” “primary,” “secondary,” and the like herein do not denote any order, quantity, or importance, but rather are used to distinguish one element from another. The modifier “about” used in connection with a quantity is inclusive of the stated value and has the meaning dictated by the context (e.g., it includes the degree of error associated with measurement of the particular quantity).

What is claimed is:

1. A process for depositing a plurality of layers of iridium on a substrate, the process comprising:
contacting the substrate with an electrolyte composition comprising:
a plurality of iridium cations; and
a plurality of protons;
biasing the substrate at a first potential;
forming iridium on the substrate by electrochemically reducing iridium cations from the electrolyte composition at the first potential of the substrate;
disposing hydrogen on the substrate from protons in the electrolyte composition;
increasing a coverage of hydrogen on the substrate;
self-terminating the forming of iridium on the substrate in response to increasing the coverage of hydrogen on the substrate;
oxidizing hydrogen on the substrate by changing a potential of the substrate from the first potential to a second potential; and
changing the potential of the substrate from the second potential to a third potential for forming additional iridium on the substrate by electrochemically reducing iridium cations from the electrolyte composition to deposit a plurality of layers of iridium on the substrate, such that forming the additional iridium on the substrate occurs at the third potential in response to oxidizing the hydrogen on the substrate at the second potential.

2. The process of claim 1, further comprising conducting the forming of iridium on the substrate at a temperature from 25° C. to 103° C.

3. The process of claim 2, further comprising conducting forming of iridium on the substrate at a pH of the electrolyte composition from 0 to 6.5.

4. The process of claim 3, wherein self-terminating the forming of iridium on the substrate comprises forming H₂ from hydrogen disposed on the substrate.

5. The process of claim 4, further comprising repetitively changing the potential of the substrate from the second potential to the third potential to control a thickness of the iridium formed on the substrate.

6. The process of claim 1, wherein the substrate comprises an electrically conductive metal.

7. The process of claim 6, wherein the electrically conductive metal comprises a transition metal, a thin oxide thereof, a conductive oxide thereof, or a combination comprising any of the foregoing electrically conductive metals.

8. The process of claim 7, wherein the transition metal comprises copper, gold, iridium, nickel, cobalt, palladium, ruthenium, titanium, tantalum, platinum, rhodium, silver, or a combination comprising any of the foregoing transition metals.

9. The process of claim 1, wherein the substrate comprises a main group element, and
the substrate is electrically conductive, semiconductive, or photoconductive.

10. The process of claim 9 wherein the conductive substrate comprises carbon, boron, phosphorus, silicon, germanium, gallium, arsenic, tin, lead, indium or lead.

11. The process of claim 1, wherein the iridium cations comprise Ir³⁺.

12. The process of claim 11, wherein the electrolyte composition further comprises SO₄²⁻, and
the Ir³⁺ is present as a complex comprising an Ir³⁺ complex.

13. The process of claim 12, wherein the Ir³⁺ complex comprises
[IrX₆]³⁻, [IrX₆]²⁻, [IrX₅(H₂O)]²⁻, [IrX₅(H₂O)₂]⁻, [(H₂O)₄Ir(OH)₂Ir(H₂O)₄]⁴⁺, [(H₂O)₅Ir(OH)Ir(H₂O)₅]⁵⁺, [Ir³⁺X⁻_{w}(HSO₄⁻)_{y}(H₂O)_{z}]^{3-w-y}, [Ir³⁺X⁻_{w}(SO₄²⁻)_{y}(H₂O)_{z}]^{3-w-2y}, a chloride equivalent thereof, a bromide equivalent thereof, a mixed chloride-bromide equivalent thereof, or a combination comprising at least one of the foregoing iridium complexes,
wherein X is a halogen that comprises Cl, Br, or a combination of Cl and Br; w is an integer from 1 to 6; y is an integer selected from 0, 1, or 2; and z is an integer such that z=6−x−y.

14. The process of claim 13, wherein the Ir3⁺ complex is [IrCl₆]³⁻, and
the electrolyte composition further comprises K₃IrCl₆—Na₂SO₄—H₂SO₄.

15. The process of claim 13, wherein the Ir3+ complex is [IrCl₆]³⁻, and
the electrolyte composition further comprises K₃IrCl₆—NaCl,
wherein the total Cl⁻ concentration is less than 3 mol/L.

16. The process of claim 1, wherein the iridium on the substrate comprises a submonolayer coverage of iridium.

17. The process of claim 16, wherein the submonolayer coverage comprises a thin film.

18. The process of claim 17, wherein the thin film is semi-coherent.

19. The process of claim 4, wherein a thickness of the iridium formed on the substrate is from 0.2 nanometers (nm) to 10,000 nm.

20. The process of claim 5, wherein a thickness of the iridium formed on the substrate increases with a number of repetitions of changing the potential of the substrate from the second potential to the third potential.

21. The process of claim 5, further comprising subjecting the substrate to a waveform that comprises:
biasing the substrate at the first potential for a first period to perform the forming iridium on the substrate;
changing the potential of the substrate from the first potential to the second potential over a first transition period;
biasing the substrate at the second potential for a second period to perform the oxidizing hydrogen on the substrate;
changing the potential of the substrate from the second potential to the third potential over a second transition period;
biasing the substrate at the third potential for a third period to perform the forming of additional iridium on the substrate;
changing the potential of the substrate from the third potential to a fourth potential over a third transition period; and
biasing the substrate at the fourth potential for a fourth period to oxidize hydrogen on the substrate,
wherein the waveform is an arbitrary waveform, a sawtooth waveform, a square waveform, a triangular waveform, a sinusoidal waveform, a symmetric waveform, an asymmetric waveform, an amplitude modulated waveform, a frequency modulated waveform, or a combination comprising at least one of the foregoing waveforms.

22. A process for performing an electrochemical reaction, the process comprising:
providing an electrode that comprises a substrate and a plurality of layers of iridium disposed on the substrate and deposited according to the process of claim 1;
contacting the electrode with a second electrolyte composition comprising an electrochemically active reagent; and
biasing the electrode at a potential effective to catalyze:
an oxygen evolution reaction, wherein the second electrolyte composition is an acid environment;
a hydrogen evolution reaction, wherein the second electrolyte composition is an alkaline environment;
a hydrogen oxidation reaction wherein the second electrolyte composition is an alkaline environment; or
an organic fuel oxidation reaction wherein the second electrolyte composition is an acid or alkaline environment,
to perform the electrochemical reaction.
